(19) United States
(12) Patent Application Publication
(10) Pub. No.: US 2022/0106218 A1
(43) Pub. Date: Apr. 7, 2022

(54) METHODS OF FORMING A FOLDABLE APPARATUS

(71) Applicant: CORNING INCORPORATED, Corning, NY (US)

(72) Inventors: XINYU CAO, SHANGHAI (CN); LING CHEN, SHANGHAI (CN); WANGHUI CHEN, SHANGHAI (CN); JIANGWEI FENG, PAINTED POST, NY (US); WILLIAM JOSEPH HURLEY, CORNING, NY (US); WEIRONG JIANG, SARASOTA, FL (US); PETER JOSEPH LEZZI, CORNING, NY (US); SAMUEL ODEI OWUSU, HORSEHEADS, NY (US)

(21) Appl. No.: 17/491,930

(22) Filed: Oct. 1, 2021

Related U.S. Application Data
(60) Provisional application No. 63/087,481, filed on Oct. 5, 2020.

(51) Int. Cl. C03B 27/02; C03C 15/00; C03C 23/00

(52) U.S. Cl. CPC C03B 27/02; G02F 1/133354; C03C 23/007; C03C 15/00

(57) ABSTRACT

Methods of forming a foldable substrate comprise providing a glass-based substrate comprising a first compressive stress region extending to an existing first depth of compression from an existing first major surface. Methods comprise contacting the existing first major surface with a solution to remove an outer compressive layer of the first compressive stress region to form a new first major surface. The outer compressive layer ranges from about 0.05 micrometers to about 5 micrometers. The solution can comprise a first temperature in a range from about 60° C. to about 120° C. The solution can comprise an alkaline solution comprising about 10 wt % or more of a hydroxide-containing base. In aspects, the method can comprise one or more of: attaching an adhesive layer to the new first major surface, attaching a display device to the new first major surface, or disposing a coating over the new first major surface.

### CROSS-REFERENCE TO RELATED APPLICATION

This application claims the benefit of priority under 35 U.S.C. § 119 of U.S. Provisional Application Ser. No. 63/087,481 filed on Oct. 5, 2020, the content of which is relied upon and incorporated herein by reference in its entirety.

### FIELD

The present disclosure relates generally to methods of forming foldable apparatus and, more particularly, to methods of forming foldable apparatus comprising contacting an existing first major surface of a foldable substrate with a solution to form a new first major surface.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii, good impact resistance, and good puncture resistance.

### SUMMARY

There are set forth herein methods of forming a foldable apparatus that comprises contacting an existing first major surface of a glass-based substrate to remove an outer compressive layer of a compressive stress region to form a new first major surface. Removing the outer compressive layer can provide increased impact resistance and/or increased puncture resistance while simultaneously facilitating good folding performance, for example, by removing surface defects in the existing first major surface of the glass-based substrate. Also, providing a glass-based substrate can provide good dimensional stability, reduced incidence of mechanical instabilities, good impact resistance, and/or good puncture resistance. For example, methods of the aspects of the disclosure can increase a pen drop height that the glass-based substrate can withstand (e.g., from about 20% to about 150%). Methods of the aspects of the disclosure can improve properties of the glass-based substrate by removing the outer compressive layer without substantially reducing a substrate thickness of the glass-based substrate (e.g., removing from about 0.05 micrometers (μm or microns) or 0.1 micrometers to about 5 micrometers, removing from about 0.1 micrometers to about 0.4 micrometers, removing from about 0.05 micrometers to about 0.2 micrometers). In aspects, the entire existing first major surface can be contacted with the solution, and the depth of the outer compressive layer can be substantially uniform across the existing first major surface. Removal of a substantially uniform outer compressive layer while minimizing a treatment time can be facilitated through the choice of solution composition and concentrations therein.

Methods of the aspects of the disclosure can use a solution that does not involve HF in substantial amounts, which can reduce materials handling costs both during treatment and for disposal of the solution. Likewise, some solutions can be substantially fluoride-free. The solution can be easily applied and then removed (e.g., rinsed away), for example, when the solution is substantially free of rheology modifiers.

Methods of the aspects of the disclosure can comprise the glass-based substrate comprising the new first major surface in a foldable apparatus. For example, the new first major surface can be opposite a display device (e.g., facing a user). For example, a release liner, a display device, and/or a coating can be disposed over (e.g., attached using an adhesive, directly contacting) the new first major surface of the glass-based substrate. In aspects, methods can comprise no further treatment between the contacting and disposing a release liner, a display device, and/or a coating over the glass-based substrate, which can minimize complexity of the processing and associated costs.

Providing an acidic solution or an alkaline solution can substantially evenly remove a layer from the surface of the foldable substrate. Providing a fluoride-containing solution can produce consistent but low concentrations of HF in solution that can remove a surface of the foldable substrate without the issues (e.g., toxicity, materials handling, material disposal) associated with directly using HF. Providing H₂SiF₆-containing solution can both remove a layer from a surface of the foldable substrate and, in combination with B(OH)₃, can simultaneously deposit (e.g., redeposit) a silica (SiO₂) layer on the surface, which can fill defects (e.g., cracks) extending deeper into the foldable substrate than the height of the layer removed. Some example aspects of the disclosure are described below with the understanding that any of the features of the various aspects may be used alone or in combination with one another.

Aspect 1. A method of forming a foldable substrate comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface; and

contacting the existing first major surface with an acidic solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 60° C. to about 100° C., and the acidic solution comprises:
from about 0.1 molar (M) to about 30 M of an acid; and
from 0 molar (M) to about 5 M of a metal chloride,

wherein, after the contacting the existing first major surface with the acidic solution, the first compressive stress region extends to a new first depth of compression from the new first major surface.

Aspect 2. The method of aspect 1, wherein after the contacting the existing first major surface with the acidic solution, the method further comprises:

attaching an adhesive layer to the new first major surface; and

disposing a release liner over the adhesive layer.

Aspect 3. The method of aspect 2, wherein the new first major surface is not further treated between the contacting the existing first major surface with the acidic solution and the attaching the adhesive layer to the new first major surface.

Aspect 4. The method of aspect 1, wherein after the contacting the existing first major surface with the acidic solution, the method further comprises attaching a display device to the new first major surface.

Aspect 5. The method of aspect 4, wherein the new first major surface is not further treated between the contacting the existing first major surface with the acidic solution and the attaching the display device to the new first major surface.

Aspect 6. The method of aspect 1, wherein after the contacting the existing first major surface with the acidic solution, the method further comprises:

disposing a coating over the new first major surface; and

attaching a display device to the glass-based substrate opposite the coating.

Aspect 7. The method of aspect 6, wherein the new first major surface is not further treated between the contacting the existing first major surface with the acidic solution and the disposing the coating over the new first major surface.

Aspect 8. The method of any one of aspects 1-7, wherein providing the glass-based substrate comprises chemically strengthening the glass-based substrate with one or more alkali metal ions to form the first compressive stress region.

Aspect 9. The method of aspect 8, wherein the existing first major surface is not further treated between the chemically strengthening and the contacting the existing first major surface with the acidic solution.

Aspect 10. The method of any one of aspects 1-9, wherein the acid comprises a mineral acid.

Aspect 11. The method of aspect 10, wherein the mineral acid comprises one or more of nitric acid, hydrochloric acid, phosphoric acid, and/or sulfuric acid.

Aspect 12. The method of any one of aspects 1-9, wherein the acid comprises an organic acid.

Aspect 13. The method of aspect 12, wherein the organic acid comprises one or more of citric acid, formic acid, acetic acid, lactic acid, and tartaric acid.

Aspect 14. The method of any one of aspects 1-13, wherein the acidic solution comprises from about 1 M to about 5 M of the acid.

Aspect 15. The method of any one of aspects 1-14, wherein the acidic solution is fluoride-free.

Aspect 16. The method of any one of aspects 1-15, wherein the first temperature is in a range from about 70° C. to about 95° C.

Aspect 17. The method of any one of aspects 1-16, wherein the period of time is in a range from about 10 minutes to about 180 minutes.

Aspect 18. The method of aspect 17, wherein the period of time is in a range from about 20 minutes to about 90 minutes.

Aspect 19. The method of any one of aspects 1-18, wherein the metal chloride comprises one or more of aluminum chloride, iron chloride, calcium chloride, and/or magnesium chloride.

Aspect 20. The method of any one of aspects 1-19, wherein the acidic solution comprises from about 0.1 M to about 1.5 M of the metal chloride.

Aspect 21. The method of any one of aspects 1-20, wherein the thickness of the outer compressive layer removed by the contacting the existing first major surface with the acidic solution is in a range from about 0.3 micrometers to about 3 micrometers.

Aspect 22. The method of any one of aspects 1-21, wherein a first pen drop threshold height of the glass-based substrate after the contacting the existing first major surface with the acidic solution is from about 20% to about 150% more than a second pen drop threshold height of the glass-based substrate prior to the contacting the existing first major surface with the acidic solution.

Aspect 23. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an alkaline solution comprising a first temperature for a period of time to remove an outer compressive layer of the first compressive stress region to form a new first major surface, the outer compressive layer comprising a thickness ranging from about 0.05 micrometers to about 5 micrometers, the first temperature is in a range from about 60° C. to about 120° C., and the alkaline solution comprises from about 10 weight % (wt %) or more of a hydroxide-containing base;

attaching an adhesive layer to the new first major surface; and

disposing a release liner over the adhesive layer,

wherein, after the contacting the existing first major surface with the alkaline solution, the first compressive stress region extends to a new first depth of compression from the new first major surface.

Aspect 24. The method of aspect 23, wherein the new first major surface is not further treated between the contacting the existing first major surface with the alkaline solution and the attaching the adhesive layer to the new first major surface.

Aspect 25. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an alkaline solution comprising a first temperature for a period of time to remove an outer compressive layer of the first compressive stress region to form a new first major surface, the outer compressive layer comprising a thickness ranging from about 0.05 micrometers to about 5 micrometers, the first temperature is in a range from about 60° C. to about 120° C., and the alkaline solution comprises from about 10 weight % (wt %) or more of a hydroxide-containing base; and

attaching a display device to the new first major surface,

wherein, after the contacting the existing first major surface with the alkaline solution, the first compressive stress region extends to a new first depth of compression from the new first major surface.

Aspect 26. The method of aspect 25, wherein the new first major surface is not further treated between the contacting the existing first major surface with the alkaline solution and the attaching the display device to the new first major surface.

Aspect 27. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an alkaline solution comprising a first temperature for a period of time to remove an outer compressive layer of the first compressive stress region to form a new first major surface, the outer compressive layer comprising a thickness ranging from about 0.05 micrometers to about 5 micrometers, the first temperature is in a range from about 60° C. to about 120° C., and the alkaline solution comprises from about 10 weight % (wt %) or more of a hydroxide-containing base;

disposing a coating over the new first major surface; and

attaching a display device to the glass-based substrate opposite the coating,

wherein, after the contacting the existing first major surface with the alkaline solution, the first compressive stress region extends to a new first depth of compression from the new first major surface.

Aspect 28. The method of aspect 27, wherein the new first major surface is not further treated between the contacting the existing first major surface with the alkaline solution and the disposing the coating over the new first major surface.

Aspect 29. The method of any one of aspects 23-28, wherein providing the glass-based substrate comprises chemically strengthening the glass-based substrate with one or more alkali metal ions to form the first compressive stress region.

Aspect 30. The method of aspect 29, wherein the existing first major surface is not further treated between the chemically strengthening and the contacting the existing first major surface with the alkaline solution.

Aspect 31. The method of any one of aspects 23-30, wherein the hydroxide-containing base comprises one or more of sodium hydroxide, potassium hydroxide, and/or ammonium hydroxide.

Aspect 32. The method of any one of aspects 23-31, wherein the alkaline solution comprises from about 20 wt % to about 50 wt % of the hydroxide-containing base.

Aspect 33. The method of any one of aspects 23-31, wherein the alkaline solution comprises a pH of about 14 or more.

Aspect 34. The method of any one of aspects 23-31, wherein the alkaline solution comprises a concentration in a range from about 3.5 molar to about 9 molar.

Aspect 35. The method of any one of aspects 23-34, wherein the alkaline solution is fluoride-free.

Aspect 36. The method of any one of aspects 23-35, wherein the first temperature is in a range from about 70° C. to about 95° C.

Aspect 37. The method of any one of aspects 23-36, wherein the period of time is in a range from about 10 minutes to about 120 minutes.

Aspect 38. The method of aspect 37, wherein the period of time is in a range from about 30 minutes to about 60 minutes.

Aspect 39. The method of aspect 37, wherein the period of time is in a range from about 75 minutes to about 115 minutes.

Aspect 40. The method of any one of aspects 23-39, wherein the thickness of the outer compressive layer removed by the contacting the existing first major surface with the alkaline solution is in a range from about 0.05 micrometers to about 0.2 micrometers.

Aspect 41. The method of any one of aspects 23-39, wherein the thickness of the outer compressive layer removed the contacting the existing first major surface with the alkaline solution is in a range from about 0.1 micrometers to about 0.4 micrometers.

Aspect 42. The method of any one of aspects 23-39, wherein the thickness of the outer compressive layer removed by the contacting the existing first major surface with the alkaline solution is in a range from about 0.1 micrometers to about 1 micrometer.

Aspect 43. The method of any one of aspects 23-42, wherein a first pen drop threshold height of the glass-based substrate after the contacting the existing first major surface with the alkaline solution is from about 20% to about 150% more than a second pen drop threshold height of the glass-based substrate prior to the contacting the existing first major surface with the alkaline solution.

Aspect 44. The method of any one of aspects 23-43, wherein the new first depth of compression is less than the existing first depth of compression by from about 0.01 micrometers to about 0.20 micrometers.

Aspect 45. The method of any one of aspects 23-43, wherein a new first depth of layer of the one or more alkali metal ions associated with the first compressive stress region extending to the new first depth of compression is less than an existing first depth of layer of one or more alkali metal ions associated with the first compressive stress region extending to the existing first depth of compression by from about 0.01 micrometers to about 0.10 micrometers.

Aspect 46. The method of any one of aspects 23-43, wherein the first compressive stress region comprises an existing maximum compressive stress before the contacting, the first compressive stress region comprises a new maximum compressive stress after the contacting, and the new maximum compressive stress is less than the existing maximum compressive stress by 40 MegaPascals or less.

Aspect 47. The method of aspect 46, wherein the first compressive stress region comprises an existing maximum compressive stress before the contacting, the first compressive stress region comprises a new maximum compressive stress after the contacting, and the new maximum compressive stress minus the existing maximum compressive stress is in a range from about −10 MegaPascals to about 20 MegaPascals.

Aspect 48. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an H₂SiF₆-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 90° C., and the H₂SiF₆-containing solution comprises:
from about 0.1 molar (M) to about 3.3 molar (M) H₂SiF₆; and
from 0 molar (M) to about 3 molar (M) boric acid;

attaching an adhesive layer to the new first major surface; and

disposing a release liner over the adhesive layer,

wherein, after the contacting the existing first major surface with the H₂SiF₆-containing solution, the first compressive stress region extends to a new first depth of compression from the new first major surface.

Aspect 49. The method of aspect 48, wherein the new first major surface is not further treated between the contacting the existing first major surface with the H₂SiF₆-containing solution and the attaching the adhesive layer to the new first major surface.

Aspect 50. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an H₂SiF₆-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 90° C., and the H₂SiF₆-containing solution comprises:
from about 0.1 molar (M) to about 3.3 molar (M) H₂SiF₆; and
from 0 molar (M) to about 3 molar (M) boric acid;

attaching a display device to the new first major surface,

wherein, after the contacting the existing first major surface with the H₂SiF₆-containing solution, the first compressive stress region extends to a new first depth of compression from the new first major surface.

Aspect 51. The method of aspect 50, wherein the new first major surface is not further treated between the contacting the existing first major surface with the H₂SiF₆-containing solution and the attaching the display device to the new first major surface.

Aspect 52. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with an H₂SiF₆-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 90° C., and the H₂SiF₆-containing solution comprises:
from about 0.1 molar (M) to about 3.3 molar (M) H₂SiF₆; and
from 0 molar (M) to about 3 molar (M) boric acid;

disposing a coating over the new first major surface; and

attaching a display device to the glass-based substrate opposite the coating,

wherein, after the contacting the existing first major surface with the H₂SiF₆-containing solution, the first compressive stress region extends to a new first depth of compression from the new first major surface.

Aspect 53. The method of aspect 52, wherein the new first major surface is not further treated between the contacting the existing first major surface with the H₂SiF₆-containing solution and the attaching the display device to the new first major surface.

Aspect 54. The method of any one of aspects 48-53, wherein providing the glass-based substrate comprises chemically strengthening the glass-based substrate with one or more alkali metal ions to form the first compressive stress region.

Aspect 55. The method of aspect 54, wherein the existing first major surface is not further treated between the chemically strengthening and the contacting the existing first major surface with the H₂SiF₆-containing solution.

Aspect 56. The method of any one of aspects 48-55, wherein the H₂SiF₆-containing solution comprises from about 0.5 M to about 2 M H₂SiF₆.

Aspect 57. The method of any one of aspects 48-56, wherein the H₂SiF₆-containing solution comprises from about 0.001 M to about 1 M boric acid.

Aspect 58. The method of any one of aspects 48-57, wherein the first temperature is in a range from about 20° C. to about 70° C.

Aspect 59. The method of any one of aspects 48-58, wherein the first temperature is in a range from about 40° C. to about 60° C.

Aspect 60. The method of any one of aspects 48-59, wherein the period of time is in a range from about 30 seconds to about 60 minutes.

Aspect 61. The method of aspect 60, wherein the period of time is in a range from about 15 seconds to about 5 minutes.

Aspect 62. The method of aspect 60, wherein the period of time is in a range from about 1 minute to about 45 minutes.

Aspect 63. The method of any one of aspects 48-62, wherein the thickness of the first outer layer removed by the contacting is in a range from about 0.1 micrometers to about 2 micrometers.

Aspect 64. The method of any one of aspects 48-63, wherein the thickness of the first outer layer removed by the contacting is in a range from about 0.4 micrometers to about 0.7 micrometers.

Aspect 65. The method of any one of aspects 48-64, wherein a first pen drop threshold height of the glass-based substrate after the contacting the existing first major surface with the H₂SiF₆-containing solution is from about 20% to about 150% more than a second pen drop threshold height of the glass-based substrate prior to the contacting the existing first major surface with the H₂SiF₆-containing solution.

Aspect 66. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with a fluoride-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 70° C., and the fluoride-containing solution comprises:
from about 0.001 weight % (wt %) to about 25 wt % ammonium fluoride and/or ammonium bifluoride; and
from 0 molar (M) to about 10 M of an acid;

attaching an adhesive layer to the new first major surface; and

disposing a release liner over the adhesive layer,

wherein, after the contacting the existing first major surface with the fluoride-containing solution, the first compressive stress region extends to a new first depth of compression from the new first major surface.

Aspect 67. The method of aspect 66, wherein the new first major surface is not further treated between the contacting the existing first major surface with the fluoride-containing solution and the attaching the adhesive layer to the new first major surface.

Aspect 68. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with a fluoride-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 70° C., and the fluoride-containing solution comprises:
from about 0.001 weight % (wt %) to about 25 wt % ammonium fluoride and/or ammonium bifluoride; and
from 0 molar (M) to about 10 M of an acid;

attaching a display device to the new first major surface,

wherein, after the contacting the existing first major surface with the fluoride-containing solution, the first compressive stress region extends to a new first depth of compression from the new first major surface.

Aspect 69. The method of aspect 68, wherein the new first major surface is not further treated between the contacting the existing first major surface with the fluoride-containing solution and the attaching the display device to the new first major surface.

Aspect 70. A method of forming a foldable apparatus comprising:

providing a glass-based substrate comprising a first compressive stress region extending to an existing first depth of compression from an existing first major surface of the glass-based substrate, the glass-based substrate comprising a first thickness defined between the existing first major surface and an existing second major surface;

contacting the existing first major surface with a fluoride-containing solution comprising a first temperature for a period of time to remove an outer compressive layer of the first compressive stress region to form a new first major surface, the outer compressive layer comprising a thickness ranging from about 0.1 micrometers to about 5 micrometers, the first temperature is in a range from about 20° C. to about 70° C., and the fluoride-containing solution comprises:
from about 0.001 weight % (wt %) to about 25 wt % ammonium fluoride and/or ammonium bifluoride; and
from 0 molar (M) to about 10 M of an acid;

disposing a coating over the new first major surface; and

attaching a display device to the glass-based substrate opposite the coating,
wherein, after the contacting the existing first major surface with the fluoride-containing solution, the first compressive stress region extends to a new first depth of compression from the new first major surface.

Aspect 71. The method of aspect 70, wherein the new first major surface is not further treated between the contacting the existing first major surface with the fluoride-containing solution and the attaching the display device to the new first major surface.

Aspect 72. The method of any one of aspects 66-71, wherein providing the glass-based substrate comprises chemically strengthening the glass-based substrate with one or more alkali metal ions to form the first compressive stress region.

Aspect 73. The method of aspect 70, wherein the existing first major surface is not further treated between the chemically strengthening and the contacting the existing first major surface with the fluoride-containing solution.

Aspect 74. The method of any one of aspects 66-73, wherein the fluoride-containing solution comprises from about 1 weight % (wt %) to about 10 wt % ammonium fluoride and/or ammonium bifluoride.

Aspect 75. The method of any one of aspects 66-73, wherein the acid comprises a mineral acid and/or an organic acid.

Aspect 76. The method of aspect 75, wherein the mineral acid comprises one or more of nitric acid, hydrochloric acid, phosphoric acid, and/or sulfuric acid.

Aspect 77. The method of aspect 75, wherein the mineral acid comprises fluorosilicic acid.

Aspect 78. The method of aspect 75, wherein the organic acid comprises one or more of citric acid, formic acid, acetic acid, lactic acid, and tartaric acid.

Aspect 79. The method of any one of aspects 66-78, wherein the fluoride-containing solution comprises from about 1 M to about 5 M of the acid.

Aspect 80. The method of any one of aspects 66-79, wherein the first temperature is in a range from about 20° C. to about 30° C.

Aspect 81. The method of any one of aspects 66-80, wherein the period of time is in a range from about 15 seconds to about 15 minutes.

Aspect 82. The method of aspect 81, wherein the period of time is in a range from about 30 seconds to about 5 minutes.

Aspect 83. The method of any one of aspects 66-82, wherein the thickness of the outer compressive layer removed by the contacting is in a range from about 0.3 micrometers to about 3 micrometers.

Aspect 84. The method of any one of aspects 66-83, wherein a first pen drop threshold height of the glass-based substrate after the contacting the existing first major surface with the fluoride-containing solution is from about 20% to about 150% more than a second pen drop threshold height of the glass-based substrate prior to the contacting the existing first major surface with the fluoride-containing solution.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 8;

FIG. 2 is a cross-sectional view of the foldable apparatus along line 2-2 of FIG. 1 according to aspects;

FIGS. 3-7 are cross-sectional views of example foldable apparatus along line 2-2 of FIG. 1 according to aspects;

FIG. 8 is a schematic view of example foldable apparatus of aspects of the disclosure in a folded configuration wherein a schematic view of the flat configuration may appear as shown in FIG. 1;

FIG. 9 is a cross-sectional view of a testing apparatus to determine the effective minimum bend radius of an example modified foldable apparatus along line 9-9 of FIG. 8;

FIG. 10 is a flow chart illustrating example methods making a foldable substrate and/or foldable apparatus in accordance with aspects of the disclosure;

FIGS. 11-13 schematically illustrate steps in a method of making a foldable apparatus;

FIG. 14 is a cross-sectional view of a foldable apparatus after the step shown in FIG. 13 and/or before the step shown in FIG. 15;

FIG. 15 schematically illustrates a step in a method of making a foldable apparatus;

FIG. 16 is a cross-sectional view of a foldable apparatus shown in FIG. 15;

FIGS. 17-22 schematically illustrate steps in a method of making a foldable apparatus; and

FIGS. 23-26 illustrate concentrations measured using secondary ion mass spectrometry (SIMS).

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

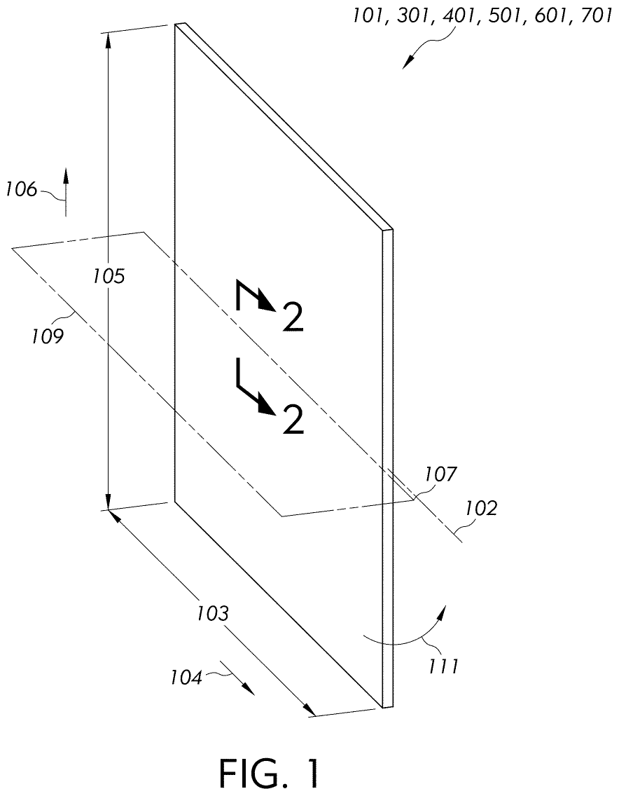

FIGS. 1-9 illustrate schematic views of foldable apparatus 101, 301, 401, 501, 601, and/or 701 or test foldable apparatus 902 comprising a foldable substrate 201 and/or 407 in accordance with aspects of the disclosure. Unless otherwise noted, a discussion of features of aspects of one foldable apparatus can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

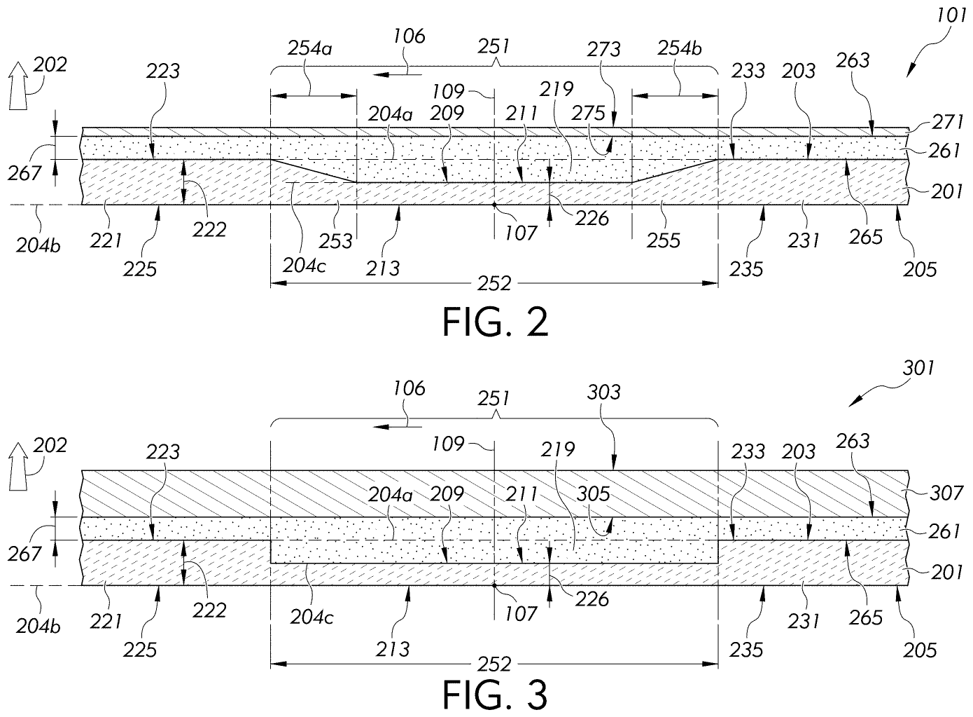

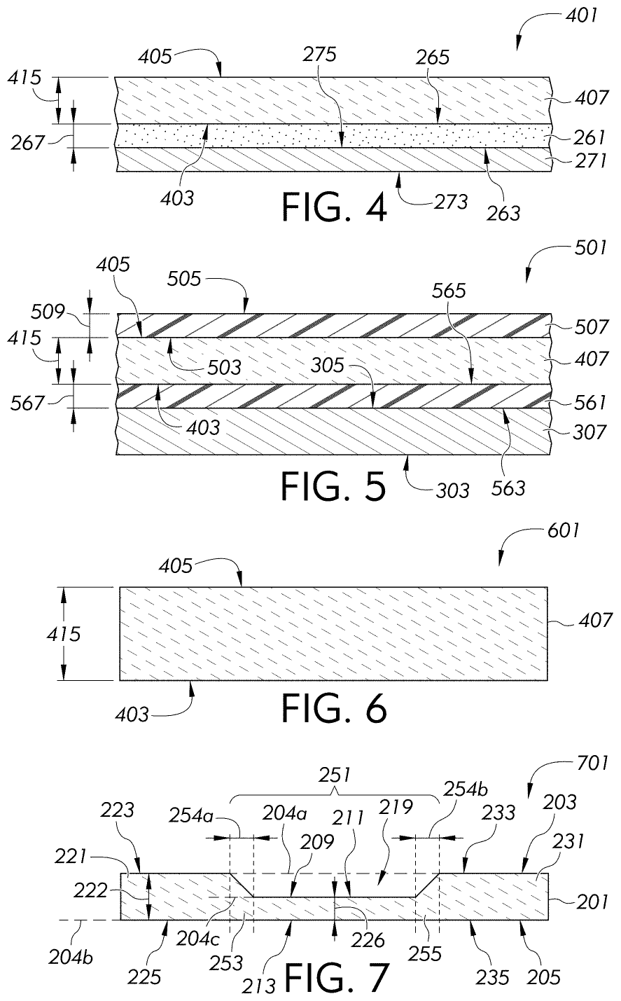

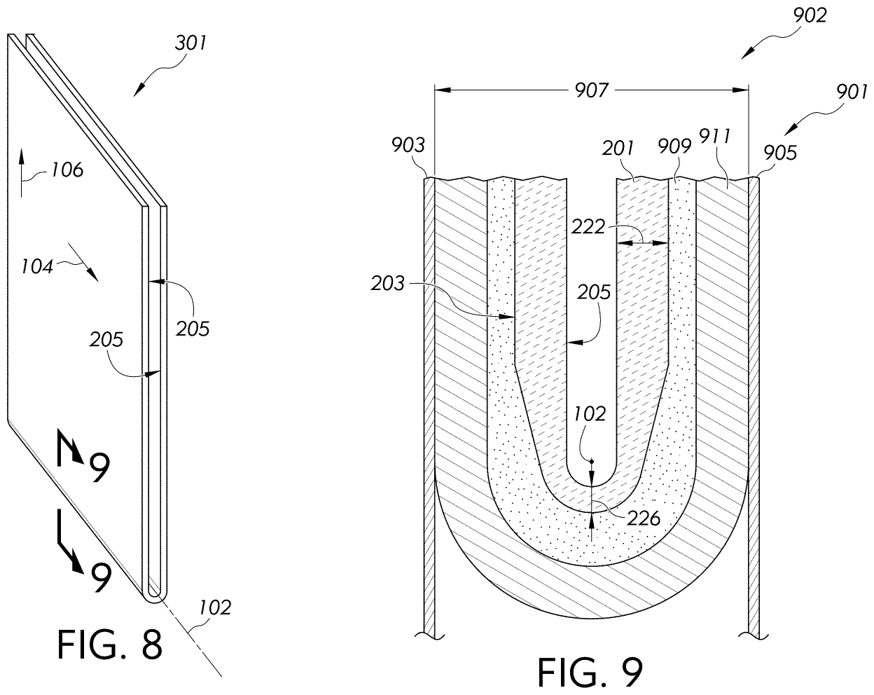

As shown in FIGS. 1-7, example aspects of foldable apparatus 101, 301, 401, 501, 601, and/or 701 can comprise the foldable substrate 201 and/or 407 in accordance with aspects of the disclosure in an unfolded (e.g., flat) configuration while FIGS. 8-9 demonstrate a foldable apparatus 301 or test foldable apparatus 902 comprising the foldable substrate 201 in accordance with aspects of the disclosure in a folded configuration. In aspects, for example, as shown in FIGS. 2-3 and 7, the foldable apparatus 101, 301, and 701 comprise a foldable substrate 201 comprising a first portion 221, a second portion 231, and a central portion 251 positioned between the first portion 221 and the second portion 231. In aspects, as shown in FIGS. 4-6, the foldable apparatus 401, 501, and 601 can comprise the foldable substrate 407. In aspects, as shown in FIGS. 2 and 4, the foldable apparatus 101 and 401 can comprise a release liner 271 although other substrates (e.g., a glass-based substrate discussed throughout the application) may be used in further aspects rather than the illustrated release liner 271. The release liner 271, or other substrates, can comprise a first major surface 273 and a second major surface 275 opposite the first major surface 273. In aspects, as shown in FIGS. 3 and 5, the foldable apparatus 301 and 501 can comprise a display device 307. The display device 307 can comprise a first major surface 303 and a second major surface 305 opposite the first major surface 303. It is to be understood that any of the foldable apparatus of the disclosure can comprise a second substrate (e.g., a glass-based substrate), the release liner 271, and/or the display device 307.

Throughout the disclosure, with reference to FIG. 1, the width 103 of the foldable apparatus 101, 301, 401, 501, 601, and/or 701 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus 101, 301, 401, 501, 601, and/or 701 is considered the dimension of the foldable apparatus 101, 301, 401, 501, 601, and/or 701 taken between opposed edges of the foldable apparatus 101, 301, 401, 501, 601, and/or 701 in a direction 106 perpendicular to the fold axis 102 of the foldable apparatus. In aspects, as shown in FIGS. 1-3, the foldable apparatus of any aspects of the disclosure can comprise a fold plane 109 that includes the fold axis 102 and the direction 202 of a substrate thickness 222 when the foldable apparatus is in the flat configuration (e.g., see FIG. 2). The plane 109 may comprise a central axis 107 of the foldable apparatus positioned, for example, at the second major surface 205 of the foldable apparatus 101 and 301 (see FIGS. 2-3). In aspects, the foldable apparatus can be folded in a direction 111 (e.g., see FIG. 1) about the fold axis 102 extending in the direction 104 of the width 103 to form a folded configuration (e.g., see FIGS. 8-9). In aspects, as shown in FIGS. 4-6, the foldable apparatus 401, 501, and 601 can comprise a substantially planar first major surface 403 and/or substantially planar second major surface 405, where a central portion of the foldable apparatus can be indistinguishable from adjacent portions. As shown in FIGS. 1 and 8-9, the foldable apparatus may include a single fold axis to allow the foldable apparatus to comprise a bifold wherein, for example, the foldable apparatus may be folded in half. In further aspects, the foldable apparatus may include two or more fold axes, for example, with each fold axis including a corresponding central portion similar or identical to the central portion 251 discussed herein. For example, providing two fold axes can allow the foldable apparatus to comprise a trifold wherein, for example, the foldable apparatus may be folded with the first portion 221, the second portion 231, and a third portion similar or identical to the first portion or second portion with the central portion 251 and another central portion similar to or identical to the central portion positioned between the first portion and the second portion and between the second portion and the third portion, respectively.

Foldable apparatus 101, 301, and 701 of the disclosure can comprise the foldable substrate 201. Foldable apparatus 401, 501, and 601 can comprise the foldable substrate 407. In aspects, the foldable substrate 201 and/or 407 can comprise a glass-based substrate having a pencil hardness of 8 H or more, for example, 9 H or more. In aspects, the foldable substrate 201 and/or 407 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In one or more aspects, a glass-based material may comprise, in mole percent (mol %): SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 23° C. and 50% relative humidity with a type I dogbone shaped sample. Throughout the disclosure, an elastic modulus (e.g., Young's modulus) and/or a Poisson's ratio is measured using ISO 527-1:2019. In aspects, the foldable substrate 201 and/or 407 can comprise an elastic modulus of about 1 GigaPascal (GPa) or more, about 3 GPa or more, about 5 GPa or more, about 10 GPa or more, about 100 GPa or less, about 80 GPa or less, about 60 GPa or less, or about 20 GPa or less. In aspects, the foldable substrate 201 201 and/or 407 can comprise an elastic modulus in a range from about 1 GPa to about 100 GPa, from about 1 GPa to about 80 GPa, from about 3 GPa to about 80 GPa, from about 3 GPa to about 60 GPa, from about 5 GPa to about 60 GPa, from about 5 GPa to about 20 GPa, from about 10 GPa to about 20 GPa, or any range or subrange therebetween. In further aspects, the foldable substrate 201 and/or 407 can comprise a glass-based portion comprising an elastic modulus in a range from about 10 GPa to about 100 GPa, from about 40 GPa to about 100 GPa, from about 60 GPa to about 100 GPa, from about 60 GPa to about 80 GPa, from about 80 GPa to about 100 GPa, or any range or subrange therebetween.

In aspects, the foldable substrate 201 and/or 407 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 2-3, 7, and 9, the foldable substrate 201 can comprise a first major surface 203 and a second major surface 205 opposite the first major surface 203. As shown in FIGS. 2-3, the first major surface 203 can extend along a first plane 204a. The second major surface 205 can extend along a second plane 204b. In aspects, as shown, the second plane 204b can be parallel to the first plane 204a. As used herein, a substrate thickness 222 of the foldable substrate 201 can be defined between the first major surface 203 and the second major surface 205 as a distance between the first plane 204a and the second plane 204b.

As shown in FIGS. 4-6, the foldable substrate 407 can comprise a first major surface 403 and a second major surface 405 opposite the first major surface 403. As shown, the first major surface 403 and/or the second major surface 405 can comprise a planar surface. In aspects, the first major surface 403 can be substantially parallel to the second major surface 405. As used herein, a substrate thickness 415 of the foldable substrate 407 can be defined between the first major surface 403 and the second major surface 405.

In aspects, the substrate thickness 222 and/or 415 can be about 10 micrometers (μm) or more, about 25 μm or more, about 40 μm or more, about 60 μm or more, about 80 μm or more, about 100 μm or more, about 125 μm or more, about 150 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 222 and/or 415 can be in a range from about 10 μm to about 2 mm, from about 25 μm to about 2 mm, from about 40 μm to about 2 mm, from about 60 μm to about 2 mm, from about 80 μm to about 2 mm, from about 100 μm to about 2 mm, from about 100 μm to about 1 mm, from about 100 μm to about 800 μm, from about 100 μm to about 500 μm, from about 125 μm to about 500 μm, from about 125 μm to about 300 μm, from about 125 μm to about 200 μm, from about 150 μm to about 200 μm, from about 150 μm to about 160 μm, or any range or subrange therebetween. In aspects, the substrate thickness 222 and/or 415 can be in a range from about 10 μm to about 800 mm, from about 10 μm to about 500 μm, from about 25 μm to about 500 μm, from about 25 μm to about 200 μm, from about 25 μm to about 180 μm, from about 40 μm to about 180 μm, from about 60 μm to about 180 μm, from about 60 μm to about 160 μm, from about 80 μm to about 160 mm, from about 100 μm to about 160 μm, from about 125 μm to about 160 μm, or any range or subrange therebetween.

In aspects, as shown in FIGS. 2-3 and 7, the foldable substrate can comprise the central portion 251 positioned between the first portion 221 and the second portion 231. The first portion 221 will now be described with reference to the foldable apparatus 101 of FIG. 2 with the understanding that such description of the first portion 221, unless otherwise stated, can also apply to any aspects of the disclosure, for example, the foldable apparatus 301 and/or 701 illustrated in FIGS. 3 and 7. As shown in FIG. 2, the first portion 221 can comprise a first surface area 223 and a second surface area 225 opposite the first surface area 223. In aspects, as shown, the second surface area 225 of the first portion 221 can comprise a planar surface. In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204a. In further aspects, the second surface area 225 can extend along the second plane 204b. A first thickness defined between the first surface area 223 of the first portion 221 and the second surface area 225 of the first portion 221 can comprise the substrate thickness 222. In aspects, the first thickness can be substantially uniform across the first surface area 223. In aspects, the first thickness can be within one or more of the ranges discussed above with regards to the substrate thickness. In aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus).

As shown in FIGS. 2-3 and 7, the foldable substrate 201 can also comprise a second portion 231 comprising a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspects of the disclosure, for example, the foldable apparatus 101, 301 and/or foldable substrate 201 illustrated in FIGS. 3 and 7. In aspects, as shown, the third surface area 233 of the second portion 231 can comprise a planar surface. In further aspects, the third surface area 233 of the second portion 231 can be in a common plane with the first surface area 223 of the first portion 221. In aspects, as shown, the fourth surface area 235 of the second portion 231 can comprise a planar surface. In further aspects, as shown, the fourth surface area 235 can be parallel to the third surface area 233. In further aspects, the fourth surface area 235 of the second portion 231 can be in a common plane with the second surface area 225 of the first portion 221. The second portion can comprise a second thickness between the third surface area 233 of the second portion 231 and the fourth surface area 235 of the second portion 231. In aspects, as shown in FIGS. 2-3 and 7, the second thickness can comprise the substrate thickness 222. In aspects, the second thickness can be substantially uniform across the third surface area 233. In aspects, the second thickness can be within one or more of the ranges discussed above with regards to the substrate thickness. In aspects, the second thickness of the second portion 231 may be substantially uniform between the third surface area 233 and the fourth surface area 235 across its corresponding length (i.e., in the direction 106 of the length 105 of the foldable apparatus) and/or its corresponding width (i.e., in the direction 104 of the width 103 of the foldable apparatus).

In aspects, as shown in FIGS. 2-3 and 7, the foldable substrate 201 can comprise the central portion 251 comprising a first central surface area 209 and a second central surface area 213 opposite the first central surface area 209. In further aspects, the central portion 251 can comprise the first central surface area 209 positioned between the first surface area 223 and the third surface area 233. In even further aspects, as shown, the first central surface area 209 can be recessed from the first major surface 203. In further aspects, the central portion 251 can comprise the second central surface area 213 positioned between the second surface area 225 and the fourth surface area 235. In even further aspects, as shown, the second major surface 205 can comprise the second central surface area 213. In even further aspects, although not shown, a portion of the second central surface area can be recessed from the second plane.

A central thickness 226 of the central portion 251 can be defined between the first central surface area 209 and the second central surface area 213. In aspects, the first central surface area 209 can comprise a central major surface 211 that may extend along a third plane 204c when the foldable apparatus 101, 301 is in a flat configuration, although the first central surface area 209 may be provided as a nonplanar area in further aspects. In further aspects, the third plane 204c can be substantially parallel to the first plane 204a and/or the second plane 204b. By providing the central major surface 211 of the central portion 251 extending along a third plane 204c parallel to the second plane 204b, a uniform central thickness 226 may extend across the central portion 251 that can provide enhanced folding performance at a predetermined thickness for the central thickness 226. A uniform central thickness 226 across the central portion 251 can improve folding performance by preventing stress concentrations that would occur if a portion of the central portion 251 was thinner than the rest of the central portion 251.

In aspects, as shown in FIGS. 2-3 and 7, the central thickness 226 can be less than the substrate thickness 222 (e.g., first thickness of the first portion 221, second thickness of the second portion 231). In aspects, the central thickness 226 can be about 0.5% or more, about 1% or more, about 2% or more, about 5% or more, about 13% or less, about 10% or less, or about 5% or less of the substrate thickness 222 (e.g., first thickness, second thickness). In aspects, the central thickness 226 as a percentage of the substrate thickness 222 (e.g., first thickness, second thickness) can be in a range from about 0.5% to about 13%, from about 0.5% to about 10%, from about 0.5% to about 5%, from about 1% to about 13%, from about 1% to about 10%, from about 1% to about 5%, from about 2% to about 13%, from about 2% to about 10%, from about 2% to about 5%, from about 5% to about 13%, from about 5% to about 10%, or any range or subrange therebetween. In further aspects, the central thickness 226 can be within one or more of the ranges for the substrate thickness 222 (e.g., first thickness, second thickness) while being less than the substrate thickness 222. In further aspects, the central thickness 226 can be about 10 μm or more, about 25 μm or more, about 50 μm or more, about 80 μm or more, about 220 μm or less, about 125 μm or less, about 100 μm or less, about 80 μm or less, about 60 μm or less, or about 40 μm or less. In even further aspects, the central thickness 226 can be in a range from about 10 μm to about 220 μm, from about 10 μm to about 125 μm, from about 10 μm to about 100 μm, from about 10 μm to about 80 μm, from about 25 μm to about 80 μm, from about 25 μm to about 60 μm, from about 50 μm to about 60 μm, or any range or subrange therebetween. In further aspects, the central thickness 226 can be greater than about 80 μm, for example, about 80 μm or more, about 100 μm or more, about 125 μm or more, about 220 μm or less, about 175 μm or less, or about 150 μm or less. In even further aspects, the central thickness 226 can be in a range from about 80 μm to about 220 μm, from about 80 μm to about 175 μm, from about 80 μm to about 150 μm, from about 100 μm to about 150 μm, from about 125 μm to about 150 μm, or any range or subrange therebetween. In further aspects, the central thickness 226 can be less than about 80 μm, for example, in a range from about 10 μm to about 80 μm, from about 25 μm to about 60 μm, from about 10 μm to about 50 μm, from about 25 μm to about 50 μm, from about 10 μm to about 40 μm, from about 25 μm to about 40 μm, or any range or subrange therebetween.

As shown in FIGS. 2 and 7, the central portion 251 can comprise a first transition region 253. The first transition region 253 can attach the first portion 221 to a region of the central portion 251 comprising the central thickness 226 (e.g., region comprising the central major surface 211). A thickness of the first transition region 253 can be defined between the second plane 204b and the first central surface area 209. As shown in FIGS. 2 and 7, the thickness of the first transition region 253 can continuously increase from the central major surface 211 (e.g., the central thickness 226) to the first portion 221 (e.g., the first thickness, substrate thickness 222). In aspects, as shown, the thickness of the first transition region 253 can increase at a constant rate from the central major surface 211 to the first portion 221. In aspects, although not shown, the thickness of the first transition region 253 may increase more slowly where the central major surface 211 meets the first transition region 253 than in the middle of the first transition region 253. In aspects, although not shown, the thickness of the first transition region 253 may increase more slowly where the first portion 221 meets the first transition region 253 than in the middle of the first transition region 253. In aspects, as shown in FIG. 3, the central portion 251 may not comprise a first transition region.

The central portion 251 can comprise a second transition region 255. As shown in FIGS. 2 and 7, the second transition region 255 can attach the second portion 231 to a region of the central portion 251 comprising the central thickness 226 (e.g., region comprising the central major surface 211). A thickness of the second transition region 255 can be defined between the second plane 204b and the first central surface area 209. As shown in FIGS. 2 and 7, the thickness of the second transition region 255 can continuously increase from the central major surface 211 (e.g., the central thickness 226) to the second portion 231 (e.g., the first thickness, substrate thickness 222). In aspects, as shown, the thickness of the second transition region 255 can increase at a constant rate from the central major surface 211 to the second portion 231. In aspects, although not shown, the thickness of the second transition region 255 may increase more slowly where the central major surface 211 meets the second transition region 255 than in the middle of the second transition region 255. In aspects, although not shown, the thickness of the second transition region 255 may increase more slowly where the second portion 231 meets the second transition region 255 than in the middle of the second transition region 255. In aspects, as shown in FIG. 3, the central portion 251 may not comprise a second transition region.

As shown in FIGS. 2 and 7, a width 254a of the first transition region 253 can be defined between the central major surface 211 and the first portion 221 in the direction 106 of the length 105 of the foldable apparatus 101. A width 254b of the second transition region 255 can be defined between the central major surface 211 and the second portion 231 in the direction 106 of the length 105 of the foldable apparatus 101. In aspects, the width 254a of the first transition region 253 and/or the width 254b of the second transition region 255 can be sufficiently large (e.g., 0.5 mm or more) to avoid optical distortions that may otherwise occur at a step transition or small transition width (e.g., less than 0.1 mm) between the substrate thickness and central thickness. In aspects, to enhance puncture resistance of the foldable substrate while also avoiding optical distortions, the width 254a of the first transition region 253 and/or the width 254b of the second transition region 255 can be about 0.5 mm or more, about 0.6 mm or more, about 0.7 mm or more, about 0.8 mm or more, about 0.9 mm or more, about 1 mm or more, about 2 mm or more, about 3 mm or more, about 5 mm or less, about 4 mm or less, about 3 mm or less, about 1 mm or less, or about 0.8 mm or less. In aspects, the width 254a of the first transition region 253 and/or the width 254b of the second transition region 255 can be in a range from 0.5 mm to about 5 mm, from about 0.7 mm to about 5 mm, from about 1 mm to about 5 mm, from about 1 mm to about 4 mm, from about 1 mm to about 3 mm, from about 2 mm to about 5 mm, from about 2 mm to about 4 mm, from about 2 mm to about 3 mm, from about 3 mm to about 5 mm, from about 3 mm to about 4 mm, or any range or subrange therebetween. In aspects, the width 254a of the first transition region 253 and/or the width 254b of the second transition region 255 can be in a range from 0.5 mm to about 5 mm, from about 0.5 mm to about 4 mm, from about 0.5 mm to about 3 mm, from about 0.5 mm to about 1 mm, from about 0.6 mm to about 1 mm, from about 0.6 mm to about 0.8 mm, from about 0.7 mm to about 0.8 mm, or any range or subrange therebetween.

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other.

As shown in FIGS. 2-4, the foldable apparatus 101, 301, and/or 401 can comprise an adhesive layer 261. As shown, the adhesive layer 261 can comprise a first contact surface 263 and a second contact surface 265 that can be opposite the first contact surface 263. In aspects, as shown, the second contact surface 265 of the adhesive layer 261 can comprise a planar surface. In aspects, as shown in FIG. 4, the first contact surface 263 of the adhesive layer 261 can comprise a planar surface. An adhesive thickness 267 of the adhesive layer 261 can be defined between the first contact surface 263 and the second contact surface 265. In aspects, the adhesive thickness 267 of the adhesive layer 261 can be about 1 μm or more, about 5 μm or more, about 10 μm or more, about 100 μm or less, about 60 μm or less, about 30 μm or less, or about 20 μm or less. In aspects, the adhesive thickness 267 of the adhesive layer 261 can be in a range from about 1 μm to about 100 μm, from about 5 μm to about 100 μm, from about 5 μm to about 60 μm, from about 5 μm to about 30 μm, from about 10 μm to about 30 μm, from about 10 μm to about 20 μm, or any range or subrange therebetween.

In aspects, as shown in FIGS. 2 and 4, the first contact surface 263 of the adhesive layer 261 can face the second major surface 275 of the release liner 271. In further aspects, as shown, the first contact surface 263 of the adhesive layer 261 can contact the second major surface 275 the release liner 271. In aspects, as shown in FIG. 3, the first contact surface 263 of the adhesive layer 261 can face the second major surface 305 of the display device 307. In further aspects, as shown, the first contact surface 263 of the adhesive layer 261 can contact the second major surface 305 of the display device 307.

In aspects, as shown in FIGS. 2-3, the second contact surface 265 of the adhesive layer 261 can face the first surface area 223 of the first portion 221. In further aspects, as shown, the second contact surface 265 of the adhesive layer 261 can contact the first surface area 223 of the first portion 221. In aspects, as shown, the second contact surface 265 of the adhesive layer 261 can face the third surface area 233 of the second portion 231. In further aspects, as shown, the second contact surface 265 of the adhesive layer 261 can contact the third surface area 233 of the second portion 231. In aspects, as shown in FIGS. 2-3, a recess 219 can be defined between the first central surface area 209 and the first plane 204a. In further aspects, the recess 219 can be defined between the third plane 204c and the first plane 204a. In further aspects, as shown, the adhesive layer 261 can be at least partially positioned in the recess 219. In further aspects, as shown, the adhesive layer 261 can fill the recess 219. In aspects, although not shown, the recess may not be totally filled, for example, to leave room for electronic devices and/or mechanical devices. In aspects, although not shown, the foldable substrate can be flipped 180 degrees such that the second contact surface of the adhesive layer contacts the second major surface of the foldable substrate.

In aspects, as shown in FIG. 4, the second contact surface 265 of the adhesive layer 261 can face the first major surface 403 of the foldable substrate 407. In further aspects, the second contact surface 265 of the adhesive layer 261 can contact the first major surface 403 of the foldable substrate 407. In aspects, although not shown, the foldable substrate can be flipped 180 degrees such that the second contact surface of the adhesive layer contacts the second major surface of the foldable substrate.

In aspects, the adhesive layer 261 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber), and block copolymers (e.g., styrene-butadiene, high-impact polystyrene, poly(dichlorophosphazene). In further aspects, the adhesive layer 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

As shown in FIG. 5, the foldable apparatus 501 can comprise a polymer-based portion 561. In aspects, as shown, the polymer-based portion 561 can comprise a first contact surface 563 opposite the second contact surface 565. In aspects, as shown, the first contact surface 563 and/or the second contact surface 565 can comprise a planar surface. In further aspects, the second contact surface 565 may be substantially coplanar (e.g., extend along a common plane) with the first major surface 403 of the foldable substrate 407. In aspects, in addition to the second contact surface 565 being substantially coplanar with the first major surface 403, the first contact surface 563 can be substantially parallel with the second major surface 405. In aspects, a polymer thickness 567 defined between the first contact surface 563 and the second contact surface 565 can be within one or more of the ranges discussed above for the adhesive thickness 267.

In aspects, the polymer-based portion 561 comprises a polymer (e.g., optically transparent polymer). In further aspects, the polymer-based portion 561 can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the polymer-based portion 561 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber), and block copolymers (e.g., styrene-butadiene, high-impact polystyrene, poly(dichlorophosphazene), for example, comprising one or more of polystyrene, polydichlorophosphazene, and poly(5-ethylidene-2-norbornene). In aspects, the polymer-based portion can comprise a sol-gel material. Example aspects of polyurethanes comprise thermoset polyurethanes, for example Dispurez 102 available from Incorez, and thermoplastic polyurethanes, for example, KrystalFlex PE505 available from Huntsman. In even further aspects, the second portion can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the second portion comprises Eleglass w802-GL044 available from Axalta with from 1 wt % to 2 wt % cross-linker. In aspects, the polymer-based portion 561 can further comprise nanoparticles, for example, carbon black, carbon nanotubes, silica nanoparticles, or nanoparticles comprising a polymer. In aspects, the polymer-based portion can further comprise fibers to form a polymer-fiber composite.

In aspects, the polymer-based portion 561 can comprise an elastic modulus of about 0.01 MegaPascals (MPa) or more, about 1 MPa or more, about 10 MPa or more, about 20 MPa or more, about 100 MPa or more, about 200 MPa or more, about 1,000 MPa or more, about 5,000 MPa or less, about 3,000 MPa or less, about 1,000 MPa or less, about 500 MPa or less, or about 200 MPa or less. In aspects, the polymer-based portion 561 can comprise an elastic modulus in a range from about 0.001 MPa to about 5,000 MPa, from about 0.01 MPa to about 3,000 MPa, from about 0.01 MPa to about 1,000 MPa, from about 0.01 MPa to about 500 MPa, from about 0.01 MPa to about 200 MPa, from about 1 MPa to about 5,000 MPa, from about 1 MPa to about 1,000 MPa, from about 1 MPa to about 1,000 MPa, from about 1 MPa to about 200 MPa, from about 10 MPa to about 5,000 MPa, from about 10 MPa to about 1,000 MPa, from about 10 MPa to about 200 MPa, from about 20 MPa to about 3,000 MPa, from about 20 MPa to about 1,000 MPa, from about 20 MPa to about 200 MPa, from about 100 MPa to about 3,000 MPa, from about 100 MPa to about 1,000 MPa, from about 100 MPa to about 200 MPa, from about 200 MPa to about 5,000 MPa, from about 200 MPa to about 3,000 MPa, from about 200 MPa to about 1,000 MPa, or any range or subrange therebetween. In aspects, the elastic modulus of the polymer-based portion 561 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween. By providing a polymer-based portion 561 with an elastic modulus in a range from about 0.01 MPa to about 3,000 MPa (e.g., in a range from about 20 MPa to about 3 GPa), folding of the foldable apparatus without failure can be facilitated. In aspects, the elastic modulus of the polymer-based portion 561 can be less than the elastic modulus of the foldable substrate 407. In aspects, the adhesive layer 261 may comprise an elastic modulus within the ranges listed above in this paragraph. In further aspects, the adhesive layer 261 may comprise substantially the same elastic modulus as the elastic modulus of the polymer-based portion 561. In further aspects, the elastic modulus of the adhesive layer 261 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween.

In aspects, the adhesive layer 261 can comprise an elastic modulus of about 0.001 MegaPascals (MPa) or more, about 0.01 MPa or more, about 0.1 MPa or more, about 1 MPa or less, about 0.5 MPa or less, about 0.1 MPa or less, or about 0.05 MPa or less. In aspects, the adhesive layer 261 can comprise an elastic modulus in a range from about 0.001 MPa to about 1 MPa, from about 0.01 MPa to about 1 MPa, from about 0.01 MPa to about 0.5 MPa, from about 0.05 MPa to about 0.5 MPa, from about 0.1 MPa to about 0.5 MPa, from about 0.001 MPa to about 0.5 MPa, from about 0.001 MPa to about 0.01 MPa, or any range or subrange therebetween. In aspects, the adhesive layer can comprise an elastic modulus within one or more of the ranges discussed above for the elastic modulus of the polymer-based portion 561.

In aspects, as shown in FIG. 5, a coating 507 can be disposed over the first major surface 403 of the foldable substrate 407. In aspects, although not shown, the coating can be disposed over the second major surface 205 of the foldable substrate 201. In further aspects, the coating can be disposed over the first portion 221, the second portion 231, and the central portion 251. In further aspects, as shown in FIG. 5, the coating 507 can contact the foldable substrate 407 (e.g., first major surface 403). In further aspects, as shown, the coating 507 can comprise a coating thickness 509 defined between a third major surface 503 and a fourth major surface 505 opposite the third major surface 503. In even further aspects, the coating thickness 509 of the coating 507 can be about 0.1 μm or more, about 1 μm or more, about 5 μm or more, about 10 μm or more, about 15 μm or more, about 20 μm or more, about 25 μm or more, about 40 μm or more, about 50 μm or more, about 60 μm or more, about 70 μm or more, about 80 μm or more, about 90 μm or more, about 200 μm or less, about 100 μm or less, or about 50 μm or less, about 30 μm or less, about 25 μm or less, about 20 μm or less, about 20 μm or less, about 15 μm or less, or about 10 μm or less. In even further aspects, the coating thickness 509 of the coating 507 can be in a range from about 0.1 μm to about 200 μm, from about 1 μm to about 200 μm, from about 10 μm to about 200 μm, from about 50 μm to about 200 μm, from about 0.1 μm to about 100 μm, from about 1 μm to about 100 μm, from about 10 μm to about 100 μm, from about 20 μm to about 100 μm, from about 30 μm to about 100 μm, from about 40 μm to about 100 μm, from about 50 μm to about 100 μm, from about 60 μm to about 100 μm, from about 70 μm to about 100 μm, from about 80 μm to about 100 μm, from about 90 μm to about 100 μm, from about 0.1 μm to about 50 μm, from about 1 μm to about 50 μm, from about 10 μm to about 50 μm, or any range or subrange therebetween. In still further aspects, the coating thickness 509 can be in a range from about 0.1 μm to about 50 μm, from about 0.1 μm to about 30 μm, from about 0.1 μm to about 25 μm, from about 0.1 μm to about 20 μm, from about 0.1 μm to about 15 μm, from about 0.1 μm to about 10 μm, from about 1 μm to about 30 μm, from about 1 μm to about 25 μm, from about 1 μm to about 20 μm, from about 1 μm to about 15 μm, from about 1 μm to about 10 μm, from about 5 μm to about 30 μm, from about 5 μm to about 25 μm, from about 5 μm to about 20 μm, from about 5 μm to about 15 μm, from about 5 μm to about 10 μm, from about 10 μm to about 30 μm, from about 10 μm to about 25 μm, from about 10 μm to about 20 μm, from about 10 μm to about 15 μm, from about 15 μm to about 30 μm, from about 15 μm to about 25 μm, from about 15 μm to about 20 μm, from about 20 μm to about 30 μm, from about 20 μm to about 25 μm, or any range or subrange therebetween.

In aspects, the coating 507 can comprise a polymeric coating. In further aspects, the polymeric coating can comprise one or more of an ethylene-acid copolymer, a polyurethane-based polymer, an acrylate resin, and a mercapto-ester resin. Example aspects of ethylene-acid copolymers include ethylene-acrylic acid copolymers, ethylene-methacrylic acid copolymers, and ethylene-acrylic-methacrylic acid terpolymers (e.g., Nucrel, manufactured by DuPont), ionomers of ethylene acid copolymers (e.g., Surlyn, manufactured by DuPont), and ethylene-acrylic acid copolymer amine dispersions (e.g., Aquacer, manufactured by BYK). Example aspects of polyurethane-based polymers include aqueous modified polyurethane dispersions (e.g., Eleglas®, manufactured by Axalta). Example aspects of acrylate resins which can be UV curable include acrylate resins (e.g., Uvekol® resin, manufactured by Allinex), cyanoacrylate adhesives (e.g., Permabond® UV620, manufactured by Krayden), and UV radical acrylic resins (e.g., Ultrabond windshield repair resin, for example, Ultrabond (45CPS)). Example aspects of mercapto-ester resins include mercapto-ester triallyl isocyanurates (e.g., Norland optical adhesive NOA 61). In further aspects, the polymeric coating can comprise ethylene-acrylic acid copolymers and ethylene-methacrylic acid copolymers, which may be ionomerized to form ionomer resins through neutralization of the carboxylic acid residue with typically alkali metal ions, for example sodium, and potassium and also zinc. Such ethylene-acrylic acid and ethylene-methacrylic acid ionomers may be dispersed within water and coated onto the substrate to form an ionomer coating. Alternatively, such acid copolymers may be neutralized with ammonia which, after coating and drying liberates the ammonia to reform the acid copolymer as the coating. By providing a coating comprising a polymeric coating, the foldable apparatus can comprise low energy fracture.

In aspects, the coating 507 can comprise a polymeric coating comprising an optically transparent polymeric coating layer. Suitable materials for an optically transparent polymeric coating layer include, but are not limited to: a cured acrylate resin material, an inorganic-organic hybrid polymeric material, an aliphatic or aromatic hexafunctional urethane acrylate, a siloxane-based hybrid material, and a nanocomposite material, for example an epoxy and urethane material with nanosilicate. In aspects, an optically transparent polymeric coating layer may consist essentially of one or more of these materials. In aspects, an optically transparent polymeric coating layer may consist of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example inorganic particulate dispersed within an organic matrix. More specifically, suitable materials for an optically transparent polymeric (OTP) coating layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP coating layer may consist essentially of an organic polymer material, an inorganic-organic hybrid polymeric material, or aliphatic or aromatic hexafunctional urethane acrylate. In aspects, an OTP coating layer may consist of a polyimide, an organic polymer material, an inorganic-organic hybrid polymeric material, or aliphatic or aromatic hexafunctional urethane acrylate. In aspects, an OTP coating layer may include a nanocomposite material. In aspects, an OTP coating layer may include a nano-silicate at least one of epoxy and urethane materials. Suitable compositions for such an OTP coating layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP coating layer may comprise an organic polymer material manufactured by Gunze Limited and having a hardness of 9 H, for example Gunze's “Highly Durable Transparent Film.” As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example inorganic particulate dispersed within an organic matrix. In aspects, the inorganic-organic hybrid polymeric material may include polymerized monomers comprising an inorganic silicon-based group, for example, a silsesquioxane polymer. A silsesquioxane polymer may be, for example, an alky-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP coating layer may comprise a silsesquioxane polymer combined with an organic matrix, for example, SILPLUS manufactured by Nippon Steel Chemical Co., Ltd. In aspects, an OTP coating layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by Ciba Specialty Chemicals Corporation) with a hardness of 8 H or more. In aspects, an OTP coating layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. An OTP coating layer may have a coating thickness in a range of 1 μm to 150 μm, including subranges. For example from 10 μm to 140 μm, from 20 μm to 130 μm, 30 μm to 120 μm, from 40 μm to 110 μm, from 50 μm to 100 μm, from 60 μm to 90 μm, 70 μm, 80 μm, 2 μm to 140 μm, from 4 μm to 130 μm, 6 μm to 120 μm, from 8 μm to 110 μm, from 10 μm to 100 μm, from 10 μm to 90 μm, 10 μm, 80 μm, 10 μm, 70 μm, 10 μm, 60 μm, 10 μm, 50 μm, or within a range having any two of these values as endpoints. In aspects, an OTP coating layer may be a single monolithic layer. In aspects, an OTP coating layer may be an inorganic-organic hybrid polymeric material layer or an organic polymer material layer having a thickness in the range of 80 μm to 120 μm, including subranges. For example, an OTP coating layer comprising an inorganic-organic hybrid polymeric material or an organic polymer material may have a thickness of from 80 μm to 110 μm, 90 μm to 100 μm, or within a range having any two of these values as endpoints. In aspects, an OTP coating layer may be an aliphatic or aromatic hexafunctional urethane acrylate material layer having a thickness within one or more of the thickness ranges discussed above in this paragraph or for the coating thickness 509.

In aspects, the coating 507, if provided, may also comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of about 500 micrometers or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example an amine, for example, an alkyl aminosilane with oxymethyl groups pendant on the silicon atom. In such aspects, the oleophobic coating may comprise the same material as the easy-to-clean coating. In aspects, a diamond-like coating comprises carbon and may be created by applying a high voltage potential in the presence of a hydrocarbon plasma.

In aspects, as shown in FIGS. 2 and 4, the foldable apparatus 101 and 401 can comprise the release liner 271 although other substrates (e.g., a glass-based substrate discussed throughout the application) may be used in further aspects rather than the illustrated release liner 271. In further aspects, as shown, the release liner 271, or other substrates, can be disposed over the adhesive layer 261. In even further aspects, as shown, the release liner 271, or other substrates, can directly contact the first contact surface 263 of the adhesive layer 261. As shown, the release liner 271, or other substrates, can be disposed on the adhesive layer 261 by attaching the first contact surface 263 of the adhesive layer 261 to the second major surface 275 of the release liner 271, or other substrates. In aspects, as shown, the first major surface 273 of the release liner 271, or other substrates, can comprise a planar surface. In aspects, as shown, the second major surface 275 of the release liner 271, or other substrates, can comprise a planar surface. A substrate comprising the release liner 271 can comprise a paper and/or a polymer. Exemplary aspects of paper comprise kraft paper, machine-finished paper, poly-coated paper (e.g., polymer coated, glassine paper, siliconized paper), or clay-coated paper. Exemplary aspects of polymers comprise polyesters (e.g., polyethylene terephthalate (PET)) and polyolefins (e.g., low-density polyethylene (LDPE), high-density polyethylene (HDPE), polypropylene (PP)).

In aspects, as shown in FIGS. 3 and 5, the foldable apparatus 301 and 501 can comprise the display device 307. In further aspects, as shown in FIG. 3, the display device 307 can be disposed over the adhesive layer 261. In even further aspects, as shown, the display device 307 can contact the first contact surface 263 of the adhesive layer 261. In further aspects, as shown in FIG. 5, the display device 307 can be disposed over the polymer-based portion 561. In even further aspects, as shown, the display device 307 can contact the first contact surface 563 of the polymer-based portion 561. In aspects, producing the foldable apparatus 301 may be achieved by removing the release liner 271 of the foldable apparatus 101 of FIG. 2 and attaching the display device 307 to the first contact surface 263 of the adhesive layer 261. Alternatively, the foldable apparatus 301 may be produced without the extra step of removing a release liner 271 before attaching the display device 307 to the first contact surface 263 of the adhesive layer 261 or the first contact surface 563 of the polymer-based portion 561, for example, when a release liner 271 is not applied to the first contact surface 263 of the adhesive layer 261. The display device 307 can comprise a first major surface 303 and a second major surface 305 opposite the first major surface 303. As shown in FIG. 3, the display device 307 can be disposed on the adhesive layer 261 by attaching the first contact surface 263 of the adhesive layer 261 to the second major surface 305 of the display device 307. As shown in FIG. 5, the display device 307 can be disposed on the polymer-based portion 561 by attaching the first contact surface 563 of the polymer-based portion 561 to the second major surface 305 of the display device 307. In aspects, as shown, the first major surface 303 of the display device 307 can comprise a planar surface. In aspects, as shown, the second major surface 305 of the display device 307 can comprise a planar surface. The display device 307 can comprise a liquid crystal display (LCD), an electrophoretic display (EPD), an organic light-emitting diode (OLED) display, or a plasma display panel (PDP). In aspects, the display device 307 can be part of a portable electronic device, for example, a consumer electronic product, a smartphone, a tablet, a wearable device, or a laptop. A consumer electronic product may include a housing comprising a front surface, a back surface, and side surfaces; electrical components at least partially within the housing, the electrical components comprising a controller, a memory, and a display, the display at or adjacent to the front surface of the housing; and a cover substrate disposed over the display, wherein at least one of a portion of the housing or the cover substrate comprises the foldable apparatus described herein.

In aspects, the foldable substrate 201 and/or 407 can comprise a glass-based substrate, and the first major surface 203 or 403 and/or second major surface 205 and/or 405 can comprise one or more compressive stress regions. In aspects, a compressive stress region may be created by chemically strengthening. In further aspects, the foldable substrate 201 can comprise a compressive stress region in the first portion 221, second portion 231, and/or central portion 251. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the foldable substrate 201 and/or 407 can enable good impact and/or puncture resistance (e.g., resists failure for a pen drop height of 20 centimeters). Without wishing to be bound by theory, chemically strengthening the foldable substrate 201 and/or 407 can enable small (e.g., smaller than about 10 mm or less) bend radii because the compressive stress from the chemical strengthening can counteract the bend-induced tensile stress on the outermost surface of the substrate. A compressive stress region may extend into a portion of the first portion and/or second portion for a depth called the depth of compression. As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first major surface 203 or 403 of the foldable substrate 201 or 407 can comprise a first compressive stress region extending to a first depth of compression from the first major surface 203 or 403. In further aspects, the first portion 221 and/or second portion 231 can comprise the first compressive stress region extending from the first surface area 223 and/or third surface area 233. In further aspects, the first compressive stress region of the first portion 221 can be substantially the same as the first compressive stress region of the second portion 231.

In aspects, the second major surface 205 or 405 of the foldable substrate 201 or 407 can comprise a second compressive stress region extending to a second depth of compression from the second major surface 205 or 405. In further aspects, the first portion 221 and/or second portion 231 can comprise the second compressive stress region extending from the second surface area 225 and/or fourth surface area 235. In further aspects, the second compressive stress region of the first portion 221 can be substantially the same as the second compressive stress region of the second portion 231.

In aspects, the first depth of compression and/or the second depth of compression as a percentage of the substrate thickness 222 (e.g., first thickness, second thickness) can be about 1% or more, about 5% or more, about 10% or more, about 30% or less, about 25% or less, or about 20% or less. In aspects, the first depth of compression and/or the second depth of compression as a percentage of the substrate thickness 222 (e.g., first thickness, second thickness) can be in a range from about 1% to about 30%, from about 5% to about 30%, from about 5% to about 25%, from about 5% to about 20%, from about 10% to about 30%, from about 10% to about 25%, from about 10% to about 20%, or any range or subrange therebetween. In further aspects, the first depth of compression and/or the second depth of compression as a percentage of the substrate thickness 222 (e.g., first thickness, second thickness) can be about 10% or less, for example, from about 1% to about 10%, from about 1% to about 8%, from about 3% to about 8%, from about 5% to about 8%, or any range or subrange therebetween. In aspects, the first depth of compression and/or the second depth of compression can be about 1 μm or more, about 10 μm or more, about 30 μm or more, about 50 μm or more, about 200 μm or less, about 150 μm or less, about 100 μm or less, or about 60 μm or less. In aspects, the first depth of compression and/or the second depth of compression can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween. By providing a glass-based substrate comprising a first depth of compression and/or the second depth of compression in a range from about 1% to about 30% of the substrate thickness, good impact and/or puncture resistance can be enabled. In aspects, the first depth of compression can be substantially equal to the second depth of compression.

In aspects, the first compressive stress region can comprise a first maximum compressive stress and/or the second compressive stress region can comprise a second maximum compressive stress. In further aspects, the first maximum compressive stress can be substantially equal to the second maximum compressive stress. In further aspects, the first maximum compressive stress and/or second maximum compressive stress can be about 100 MegaPascals (MPa) or more, about 300 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the first maximum compressive stress and/or second maximum compressive stress can be in a range from about 100 MPa to about 1,500 MPa, from about 100 MPa to about 1,200 MPa, from about 300 MPa to about 1,200 MPa, from about 300 MPa to about 1,000 MPa, from about 500 MPa to about 1,000 MPa, from about 600 MPa to about 1,000 MPa, from about 600 MPa to about 1,000 MPa, from about 700 MPa to about 1,000 MPa, from about 700 MPa to about 800 MPa, or any range or subrange therebetween. By providing a first maximum compressive stress and/or second maximum compressive stress in a range from about 100 MPa to about 1,500 MPa, good impact and/or puncture resistance can be enabled.

In aspects, a first depth of layer of one or more alkali metal ions can be associated with the first compressive stress region and the first depth of compression. As used herein, the one or more alkali metal ions of a depth of layer of one or more alkali metal ions can include sodium, potassium, rubidium, cesium, and/or francium. In aspects, a second depth of layer of one or more alkali metal ions can be associated with the second compressive stress region and the second depth of compression. In aspects, the one or more alkali ions of the first depth of layer of the one or more alkali ions and/or the second depth of layer of the one or more alkali ions comprises potassium. In aspects, the first depth of layer can be substantially equal to the second depth of layer. In aspects, the first depth of layer and/or the second depth of layer as a percentage of the substrate thickness 222 (e.g., first thickness, second thickness) can be about 1% or more, about 5% or more, about 10% or more, about 40% or less, about 35% or less, about 30% or less, about 25% or less, or about 20% or less. In aspects, the first depth of layer and/or the second depth of layer as a percentage of the substrate thickness 222 (e.g., first thickness, second thickness) can be in a range from about 1% to about 40%, from about 1% to about 35%, from about 1% to about 30%, from about 1% to about 25%, from about 1% to about 20%, from about 5% to about 30%, from about 5% to about 25%, from about 5% to about 20%, from about 10% to about 30%, from about 10% to about 25%, from about 10% to about 20%, or any range or subrange therebetween. In further aspects, the first depth of layer and/or the second depth of layer of the one or more alkali metal ions as a percentage of the substrate thickness 222 (e.g., first thickness, second thickness) can be about 10% or less, for example, from about 1% to about 10%, from about 1% to about 8%, from about 3% to about 8%, from about 5% to about 8%, or any range or subrange therebetween. In aspects, the first depth of layer and/or the second depth of layer of the one or more alkali metal ions can be about 1 μm or more, about 10 μm or more, about 30 μm or more, about 50 μm or more, about 200 μm or less, about 150 μm or less, about 100 μm or less, or about 60 μm or less. In aspects, the first depth of layer of the one or more alkali metal ions can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween.

In aspects, the central portion 251 of the foldable substrate 201 can comprise a first central compressive stress region at the first central surface area 209 that can extend to first central depth of compression from the first central surface area 209. In aspects, the central portion 251 of the foldable substrate 201 can comprise a second central compressive stress region at the second central surface area 213 that can extend to a second central depth of the compression from the second central surface area 213. In aspects, the first central depth of compression can be substantially equal to the second central depth of compression. In aspects, the first central depth of compression and/or the second central depth of compression as a percentage of the central thickness 226 can be about 1% or more, about 5% or more, about 10% or more, about 30% or less, about 25% or less, or about 20% or less. In aspects, the first central depth of compression and/or the second central depth of compression as a percentage of the central thickness 226 can be in a range from about 1% to about 30%, from about 5% to about 30%, from about 5% to about 25%, from about 5% to about 20%, from about 10% to about 30%, from about 10% to about 25%, from about 10% to about 20%, or any range or subrange therebetween. In further aspects, the first central depth of compression and/or the second central depth of compression as a percentage of the central thickness 226 can be about 10% or more, for example, from about 10% to about 30%, from about 10% to about 25%, from about 15% to about 25%, from about 15% to about 20%, or any range or subrange therebetween. In aspects, the first central depth of compression and/or the second central depth of compression can be about 1 μm or more, about 10 μm or more, about 30 μm or more, about 50 μm or more, about 200 μm or less, about 150 μm or less, about 100 μm or less, or about 60 μm or less. In aspects, the first central depth of compression and/or the second central depth of compression can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween. By providing a central portion comprising the first central depth of compression and/or the second central depth of compression in a range from about 1% to about 30% of the central thickness, good impact and/or puncture resistance can be enabled.

In aspects, the first central compressive stress region can comprise a first central maximum compressive stress. In aspects, the second central compressive stress region can comprise a second central maximum compressive stress. In aspects, the first central maximum compressive stress can be substantially equal to the second central maximum compressive stress. In aspects, the first central maximum compressive stress and/or the second central maximum compressive stress can be about 100 MegaPascals (MPa) or more, about 300 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the first central maximum compressive stress and/or the second central maximum compressive stress can be in a range from about 100 MPa to about 1,500 MPa, from about 100 MPa to about 1,200 MPa, from about 300 MPa to about 1,200 MPa, from about 300 MPa to about 1,000 MPa, from about 500 MPa to about 1,000 MPa, from about 600 MPa to about 1,000 MPa, from about 600 MPa to about 1,000 MPa, from about 700 MPa to about 1,000 MPa, from about 700 MPa to about 800 MPa, or any range or subrange therebetween. By providing a first central maximum compressive stress and/or a second central maximum compressive stress in a range from about 100 MPa to about 1,500 MPa, good impact and/or puncture resistance can be enabled.

In aspects, the central portion 251 can comprise a first central depth of layer of one or more alkali metal ions associated with the first central compressive stress region and first central depth of compression. In aspects, the central portion 251 can comprise a second central depth of layer of one or more alkali metal ions associated with the second central compressive stress region and the second central depth of compression. In aspects, the one or more alkali ions of the first central depth of layer of the one or more alkali ions and/or the second central depth of layer of the one or more alkali ions comprises potassium. In aspects, the first central depth of layer can be substantially equal to the second central depth of layer. In aspects, the first central depth of layer and/or the second central depth of layer as a percentage of the central thickness 226 can be about 1% or more, about 5% or more, about 10% or more, about 40% or less, about 35% or less, about 30% or less, about 25% or less, or about 20% or less. In aspects, the first central depth of layer and/or the second central depth of layer as a percentage of the central thickness 226 can be in a range from about 1% to about 40%, from about 1% to about 35%, from about 1% to about 30%, from about 1% to about 25%, from about 1% to about 20%, from about 5% to about 30%, from about 5% to about 25%, from about 5% to about 20%, from about 10% to about 30%, from about 10% to about 25%, from about 10% to about 20%, or any range or subrange therebetween. In further aspects, the first central depth of layer and/or the second central depth of layer as a percentage of the central thickness 226 can be about 10% or less, for example, from about 1% to about 10%, from about 1% to about 8%, from about 3% to about 8%, from about 5% to about 8%, or any range or subrange therebetween. In aspects, the first central depth of layer and/or the second central depth of layer can be about 1 μm or more, about 10 μm or more, about 30 μm or more, about 50 μm or more, about 200 μm or less, about 150 μm or less, about 100 μm or less, or about 60 μm or less. In aspects, the first central depth of layer and/or the second central depth of layer can be in a range from about 1 μm to about 200 μm, from about 1 μm to about 150 μm, from about 10 μm to about 150 μm, from about 10 μm to about 100 μm, from about 30 μm to about 100 μm, from about 30 μm to about 60 μm, from about 50 μm to about 60 μm, or any range or subrange therebetween.

In aspects, the foldable substrate 201 and/or 407 can comprise a first index of refraction. The first refractive index may be a function of a wavelength of light passing through the optically clear adhesive. For light of a first wavelength, a refractive index of a material is defined as the ratio between the speed of light in a vacuum and the speed of light in the corresponding material. Without wishing to be bound by theory, a refractive index of the optically clear adhesive can be determined using a ratio of a sine of a first angle to a sine of a second angle, where light of the first wavelength is incident from air on a surface of the optically clear adhesive at the first angle and refracts at the surface of the optically clear adhesive to propagate light within the optically clear adhesive at a second angle. The first angle and the second angle are both measured relative to a direction normal to a surface of the optically clear adhesive. As used herein, the refractive index is measured in accordance with ASTM E1967-19, where the first wavelength comprises 589 nm. In aspects, the first refractive index of the foldable substrate 201 and/or 407 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the first refractive index of the foldable substrate 201 and/or 407 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween.

In aspects, the polymer-based portion 561, if present, can be optically clear. The polymer-based portion 561 can comprise a second index of refraction. In aspects, the second refractive index of the polymer-based portion 561 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the second refractive index of the polymer-based portion 561 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween. In aspects, a differential equal to the absolute value of the difference between the second index of refraction of the polymer-based portion 561 and the first index of refraction of the foldable substrate 201 and/or 407 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the second index of refraction of the polymer-based portion 561 may be greater than the first index of refraction of the foldable substrate 201 and/or 407. In aspects, the second index of refraction of the polymer-based portion 561 may be less than the first index of refraction of the foldable substrate 201 and/or 407.

In aspects, the adhesive layer 261 can comprise a third index of refraction. In aspects, the third index of refraction of the adhesive layer 261 can be within one or more of the ranges discussed above with regards to the second index of refraction of the polymer-based portion 561. In aspects, a differential equal to the absolute value of the difference between the third index of refraction of the adhesive layer 261 and the first index of refraction of the foldable substrate 201 and/or 407 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the first index of refraction of the foldable substrate 201 and/or 407. In aspects, the third index of refraction of the adhesive layer 261 may be less than the first index of refraction of the foldable substrate 201 and/or 407.

In aspects, a differential equal to the absolute value of the difference between the third index of refraction of the adhesive layer 261 and the second index of refraction of the polymer-based portion 561 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the second index of refraction of the polymer-based portion 561. In aspects, the third index of refraction of the adhesive layer 261 may be less than the second index of refraction of the polymer-based portion 561.

FIGS. 8-9 schematically illustrates aspects of a test foldable apparatus 902 and/or foldable apparatus 301 in accordance with aspects of the disclosure in a folded configuration. As shown in FIG. 9, the test foldable apparatus 902 is folded such that the second major surface 205 of the foldable substrate 201 is on the inside of the folded test foldable apparatus 902. In the folded configuration shown in FIG. 9, a user would view the display device 307 in place of a PET sheet 911 through the foldable substrate 201 and, thus, would be positioned on the side of the second major surface 205. Although not shown, the foldable apparatus can be folded such that the second major surface of the foldable substrate is on the outside of the folded foldable apparatus, where a user would view the display device through the foldable substrate and, thus, would be positioned on the side of the second major surface. In aspects, although not shown in a folded configuration, a foldable apparatus can comprise a coating disposed over the foldable substrate, where a user would view the display device through the coating.

As used herein, “foldable” includes complete folding, partial folding, bending, flexing, or multiple capabilities. As used herein, the terms “fail,” “failure,” and the like refer to breakage, destruction, delamination, or crack propagation. A foldable apparatus achieves an effective bend radius of “X,” or has an effective bend radius of “X,” or comprises an effective bend radius of “X” if it resists failure when the foldable apparatus is held at “X” radius for 24 hours at about 85° C. and about 85% relative humidity. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

As used herein, the “effective minimum bend radius” and “parallel plate distance” of a foldable apparatus is measured with the following test configuration and process using a parallel plate apparatus 901 (see FIG. 9) that comprises a pair of parallel rigid stainless-steel plates 903, 905 comprising a first rigid stainless-steel plate 903 and a second rigid stainless-steel plate 905. When measuring the “effective minimum bend radius” or the “parallel plate distance”, a test adhesive layer 909 comprises a thickness of 50 μm. For the foldable apparatus 101, 301, or 401 shown in FIGS. 2-4, the test adhesive layer 909 is used instead of the adhesive layer 261. For the foldable apparatus 501 shown in FIG. 5, the test adhesive layer 909 is used instead of the polymer-based portion 561. For the foldable apparatus 601 or 701 shown in FIGS. 6-7, the test adhesive layer 909 is used similar to how the adhesive layer 261 is used in FIG. 4 and FIG. 3, respectively. When measuring the “effective minimum bend radius” or the “parallel plate distance”, the test is conducted with a 100 μm thick sheet 911 of polyethylene terephthalate (PET) rather than with the release liner 271 of FIGS. 2 and 4 or the display device 307 shown in FIGS. 3 and 5. For the foldable apparatus 601 or 701 shown in FIGS. 6-7, the sheet 911 of PET is disposed over the test adhesive layer 909 so that the test adhesive layer 909 is positioned between the foldable substrate 201 or 407 and the sheet 911. Thus, during the test to determine the “effective minimum bend radius” or the “parallel plate distance” of a configuration of a foldable apparatus, the test foldable apparatus 902 is produced by using the 100 μm thick sheet 911 of polyethylene terephthalate (PET) rather than with the release liner 271 of FIGS. 2 and 4 or the display device 307 shown in FIGS. 3 and 5. When preparing the test foldable apparatus 902, the 100 μm thick sheet 911 of polyethylene terephthalate (PET) is attached to the test adhesive layer 909 in an identical manner that the release liner 271 is attached to the first contact surface 263 of the adhesive layer 261 as shown in FIGS. 2 and 4, the display device 307 is attached to the first contact surface 263 of the adhesive layer 261 as shown in FIG. 3, or the display device 307 is attached to the first contact surface 563 of the polymer-based portion 561 as shown in FIG. 5. To the foldable apparatus 601 and/or 701 of FIGS. 6-7, the test adhesive layer 909 and the sheet 911 can likewise be installed as shown in the configuration of FIG. 9 to conduct the test on the test foldable apparatus 902. The test foldable apparatus 902 is placed between the pair of parallel rigid stainless-steel plates 903, 905 such that the foldable substrate 201 and/or 407 will be on the inside of the bend, similar to the configuration shown in FIGS. 9. For determining a “parallel plate distance”, the distance between the parallel plates is reduced at a rate of 50 μm/second until the parallel plate distance 907 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above. For determining the “effective minimum bend radius”, the distance between the parallel plates is reduced at a rate of 50 μm/second until the parallel plate distance 907 is equal to twice the “effective minimum bend radius” to be tested. Then, the parallel plates are held at twice the effective minimum bend radius to be tested for 24 hours at about 85° C. and about 85% relative humidity. As used herein, the “effective minimum bend radius” is the smallest effective bend radius that the foldable apparatus can withstand without failure under the conditions and configuration described above.

In aspects, the foldable apparatus 101, 301, 401, 501, 601, and/or 701 and/or test foldable apparatus 902 can achieve a parallel plate distance of 100 mm or less, 50 mm or less, 20 mm or less, 10 mm or less, 5 mm or less, or 3 mm or less. In further aspects, the foldable apparatus 101, 301, 401, 501, 601, and/or 701 and/or test foldable apparatus 902 can achieve a parallel plate distance of 50 millimeters (mm), or 20 mm, or 10 mm, of 5 mm, or 3 mm. In aspects, the foldable apparatus 101, 301, 401, 501, 601, and/or 701 and/or test foldable apparatus 902 can comprise a minimum parallel plate distance of about 40 mm or less, about 20 mm or less, about 10 mm or less, about 5 mm or less, about 3 mm or less, about 1 mm or more, about 1 mm or more, about 3 mm or more, about 5 mm or more, or about 10 mm or more. In aspects, the foldable apparatus 101, 301, 401, 501, 601, and/or 701 and/or test foldable apparatus 902 can comprise a minimum parallel plate distance in a range from about 1 mm to about 40 mm, from about 1 mm to about 20 mm, from about 1 mm to about 10 mm, from about 1 mm to about 5 mm, from about 1 mm to about 3 mm, from about 3 mm to about 40 mm, from about 3 mm to about 40 mm, from about 3 mm to about 20 mm, from about 3 mm to about 10 mm, from about 3 mm to about 5 mm, from about 5 mm to about 10 mm, or any range or subrange therebetween. In aspects, the foldable apparatus 101, 301, 401, 501, 601, and/or 701 and/or test foldable apparatus 902 can comprise an effective minimum bend radius in a range from about 1 mm to about 40 mm, from about 1 mm to about 20 mm, from about 1 mm to about 10 mm, from about 1 mm to about 5 mm, from about 1 mm to about 3 mm, from about 3 mm to about 40 mm, from about 3 mm to about 40 mm, from about 3 mm to about 20 mm, from about 3 mm to about 10 mm, from about 3 mm to about 5 mm, from about 5 mm to about 10 mm, or any range or subrange therebetween.

In aspects, as shown in FIGS. 2-3 and 7, a width 252 of the central portion 251 of the foldable substrate 201 defined between the first portion 221 and the second portion 231 in the direction 106 of the length 105. In aspects, the width 252 of the central portion 251 of the foldable substrate 201 can extend from the first portion 221 to the second portion 231. In aspects, the width 252 of the central portion 251 of the foldable substrate 201 defined between the first portion 221 and the second portion 231 in the direction 106 of the length 105 can be about 2.8 times or more, about 3 times or more, about 4 times or more, about 6 times or less, about 5 times or less, or about 4 times or less the effective minimum bend radius. In aspects, the width 252 of the central portion 251 as a multiple of the effective minimum bend radius can be in a range from about 2.8 times to about 6 times, from about 2.8 times to about 5 times, from about 2.8 times to about 4 times, from about 3 times to about 6 times, from about 3 times to about 5 times, from about 3 times to about 4 times, from about 4 times to about 6 times, from about 4 times to about 5 times, or any range or subrange therebetween. Without wishing to be bound by theory, the length of a bent portion in a circular configuration between parallel plates can be about 1.6 times the parallel plate distance 907 (e.g., about 3 times the effective minimum bend radius, about 3.2 times the effective minimum bend radius). In aspects, the width 252 of the central portion 251 of the foldable substrate 201 can be about 2.8 mm or more, about 6 mm or more, about 9 mm or more, about 60 mm or less, about 40 mm, or less, or about 24 mm or less. In aspects, the width 252 of the central portion 251 of the foldable substrate 201 can be in a range from about 2.8 mm to about 60 mm, from about 2.8 mm to about 40 mm, from about 2.8 mm to about 24 mm, from about 6 mm to about 60 mm, from about 6 mm to about 40 mm, from about 6 mm to about 24 mm, from about 9 mm to about 60 mm, from about 9 mm to about 40 mm, from about 9 mm to about 24 mm, or any range of subrange therebetween. By providing a width of the central portion between the first portion and the second portion, folding of the foldable apparatus without failure can be facilitated.

The foldable apparatus may have an impact resistance defined by the capability of a region of the foldable apparatus (e.g., a region comprising the first portion 221, a region comprising the second portion 231, a region comprising the central portion 251) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to a major surface (e.g., second major surface 205 of the foldable substrate 201, second major surface 405 of the foldable substrate 407, fourth major surface 505 of the coating 507) configured as in the parallel plate test with 100 μm thick sheet 911 of PET attached to the test adhesive layer 909 having a thickness of 50 μm instead of the display device 307 shown in FIGS. 3 and 5. As such, the PET layer in the Pen Drop Test is meant to simulate a foldable electronic display device (e.g., an OLED device). During testing, the foldable apparatus bonded to the PET layer is placed on an aluminum plate (6063 aluminum alloy, as polished to a surface roughness with 400 grit paper) with the PET layer in contact with the aluminum plate. No tape is used on the side of the sample resting on the aluminum plate.

A tube is used for the Pen Drop Test to guide a pen to an outer surface of the foldable apparatus. For the foldable apparatus 101, 301, and/or 701 and/or test foldable apparatus 902 shown in FIGS. 2-4, 7, and 9, the pen is guided to the second major surface 205 of the foldable substrate 201, and the tube is placed in contact with the second major surface 205 of the foldable substrate 201 so that the longitudinal axis of the tube is substantially perpendicular to the second major surface 205 with the longitudinal axis of the tube extending in the direction of gravity. For the foldable apparatus 401, 501, and/or 601 shown in FIGS. 4-6, the pen is guided to the second major surface 405 of the foldable substrate 407 or the fourth major surface 505 of the coating 507, if present, and the tube is placed in contact with the second major surface 205 of the foldable substrate 201 or the fourth major surface 505 of the coating 507, if present, so that the longitudinal axis of the tube is substantially perpendicular to the second major surface 405 or the fourth major surface 505, if present, with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap (4.68 g without the cap).

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or 407 and/or coating 507. A visible mechanical defect has a minimum dimension of 0.2 mm or more.

In aspects, the foldable apparatus can resist failure for a pen drop in a region comprising the first portion 221 or the second portion 231 of the foldable substrate 201, the second major surface 405 of the foldable substrate 407, and/or the fourth major surface 505 of the coating at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 of the foldable substrate 201, the second major surface 405 of the foldable substrate 407, and/or the fourth major surface 505 of the coating may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 of the foldable substrate 201, the second major surface 405 of the foldable substrate 407, and/or the fourth major surface 505 of the coating be in a range from about 10 cm to about 40 cm, from about 12 cm to about 40 cm, from about 12 cm to about 30 cm, from about 14 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in a central portion 251 between the first portion 221 and the second portion 231 at a pen drop height of 1 cm, 2 cm, 3 cm, 4 cm, 5 cm, or more. In aspects, a maximum pen drop height that the foldable apparatus can withstand without failure over the central portion 251 between the first portion 221 and the second portion 231 may be about 1 cm or more, about 2 cm or more, about 3 cm or more, about 4 cm or more, about 20 cm or less, about 10 cm or less, about 8 cm or less, or about 6 cm or less. In aspects, a maximum pen drop height that the foldable apparatus can withstand without failure over the central portion 251 between the first portion 221 and the second portion 231 can be in a range from about 1 cm to about 20 cm, from about 2 cm to about 20 cm, from about 2 cm to about 10 cm, from about 3 cm to about 10 cm, from about 3 cm to about 8 cm, from about 4 cm to about 8 cm, from about 4 cm to about 6 cm, or any range or subrange therebetween. In aspects, a maximum pen drop height that the foldable apparatus can withstand without failure of the central region between the first portion 221 and the second portion 231 can be in a range from about 1 cm to about 10 cm, from about 1 cm to about 8 cm, from about 1 cm to about 5 cm, from about 2 cm to about 5 cm, from about 3 cm to about 5 cm, from about 4 cm to about 5 cm, or any range or subrange therebetween.

In aspects, contacting the first major surface 203 or 403 of the foldable substrate 201 or 407 with any of the solutions described below in step 1007 can increase a first pen drop threshold height that the foldable apparatus comprising the foldable substrate 201 or 407 can withstand relative to a second pen drop threshold height a foldable apparatus without the contacting the first major surface 203 or 403 of the foldable substrate 201 or 407 with any of the solutions described below in step 1007. In further aspects, the first pen drop threshold height can be greater than the second pen drop threshold height as a percentage of the second pen drop threshold height by about 20% or more, about 30% or more, about 50% or more, about 150% or less, about 120% or less, about 100% or less, or about 80% or less. In further aspects, the first pen drop threshold height can be greater than the second pen drop threshold height as a percentage of the second pen drop threshold height in a range from about 20% to about 150%, from about 20% to about 130%, from about 30% to about 120%, from about 30% to about 100%, from about 50% to about 100%, from about 50% to about 80%, or any range or subrange therebetween.

A minimum force may be used to achieve a predetermined parallel plate distance with the foldable apparatus. The parallel plate apparatus 901 of FIG. 6, described above, is used to measure the “closing force” of a foldable apparatus of aspects of the disclosure. The force to go from a flat configuration (e.g., see FIG. 1) to a bent (e.g., folded) configuration (e.g., see FIGS. 6-7) comprising the predetermined parallel plate distance is measured. In aspects, the force to fold the foldable apparatus from a flat configuration to a parallel plate distance of 10 mm can be about 20 Newtons (N) or less, 15 N or less, about 12 N or less, about 10 N or less, about 0.1 N or more, about 0.5 N or more, about 1 N or more, about 2 N or more, about 5 N or more. In aspects, the force to fold the foldable apparatus from a flat configuration to a parallel plate distance of 10 mm can be in a range from about 0.1 N to about 20 N, from about 0.5 N to about 20 N, from about 0.5 N to about 15 N, from about 1 N to about 15 N, from about 1 N to about 12 N, from about 2 N to about 12 N, from about 2 N to about 10 N, from about 5 N to about 10 N, or any range or subrange therebetween. In aspects, the force to fold the foldable apparatus from a flat configuration to a parallel plate distance of 3 mm can be about 10 N or less, about 8 N or less, about 6 N or less, about 4 N or less, about 3 N or less, about 0.05 N or more about 0.1 N or more, about 0.5 N or more, about 1 N or more, about 2 N or more, about 3 N or more. In aspects, the force to fold the foldable apparatus from a flat configuration to a parallel plate distance of 3 mm can be in a range from about 0.05 N to about 10 N, from about 0.1 N to about 10 N, from about 0.1 N to about 8 N, from about 0.5 N to about 8 N, from about 0.5 N to about 6 N, from about 1 N to about 6 N, from about 1 N to about 4 N, from about 2 N to about 4 N, from about 2 N to about 3 N, or any range or subrange therebetween.

In aspects, the force per width 103 of the foldable apparatus to fold the foldable apparatus from a flat configuration to a parallel plate distance of 10 mm can be about 20 Newtons per millimeter (N/mm) or less, 0.15 N/mm or less, about 0.12 N/mm or less, about 0.10 N/mm or less, about 0.001 N/mm or more, about 0.005 N/mm or more, about 0.01 N/mm or more, about 0.02 N/mm or more, about 0.05 N/mm or more. In aspects, the force per width 103 of the foldable apparatus to fold the foldable apparatus from a flat configuration to a parallel plate distance of 0.10/mm can be in a range from about 0.001 N/mm to about 0.20 N/mm, from about 0.005 N/mm to about 0.20 N/mm, from about 0.005 N/mm to about 0.15 N/mm, from about 0.01 N/mm to about 0.15 N/mm, from about 0.01 N/mm to about 0.12 N/mm, from about 0.02 N/mm to about 0.12 N/mm, from about 0.02 N/mm to about 0.10 N/mm, from about 0.05 N/mm to about 0.10 N/mm, or any range or subrange therebetween. In aspects, the force per width 103 of the foldable apparatus to fold the foldable apparatus from a flat configuration to a parallel plate distance of 3 mm can be about 0.10 N/mm or less, about 0.08 N/mm or less, about 0.06 N/mm or less, about 0.04 N/mm or less, about 0.03 N/mm or less, about 0.0005 N/mm or more about 0.001 N/mm or more, about 0.005 N/mm or more, about 0.01 N/mm or more, about 0.02 N/mm or more, about 0.03 N/mm or more. In aspects, the force per width 103 of the foldable apparatus to fold the foldable apparatus from a flat configuration to a parallel plate distance of 3 mm can be in a range from about 0.0005 N/mm to about 0.10 N/mm, from about 0.001 N/mm to about 0.10 N/mm, from about 0.001 N/mm to about 0.08 N/mm, from about 0.005 N/mm to about 0.08 N/mm, from about 0.005 N/mm to about 0.06 N/mm, from about 0.01 N/mm to about 0.06 N/mm, from about 0.01 N/mm to about 0.04 N/mm, from about 0.02 N/mm to about 0.04 N/mm, from about 0.02 N/mm to about 0.03 N/mm, or any range or subrange therebetween.

Providing a coating can enable low forces to achieve small parallel plate distances. Without wishing to be bound by theory, a coating comprising a modulus less than a modulus of a glass-based substrate can result in a neutral axis of the polymer-based portion that is shifted away from the coating (e.g., surface facing the user) than if a glass-based substrate was used. Without wishing to be bound by theory, providing a coating with a thickness of about 200 μm or less can result in a neutral axis of the polymer-based portion that is shifted away from the coating (e.g., surface facing the user) than if a thicker substrate was used.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The consumer electronic product can comprise a cover substrate disposed over the display. In aspects, at least one of a portion of the housing or the cover substrate comprises the foldable apparatus discussed throughout the disclosure. The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof.

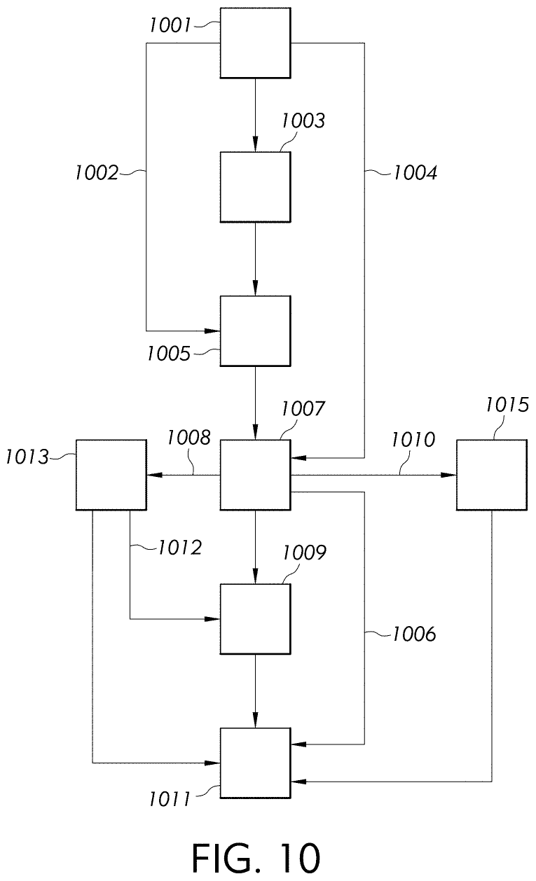

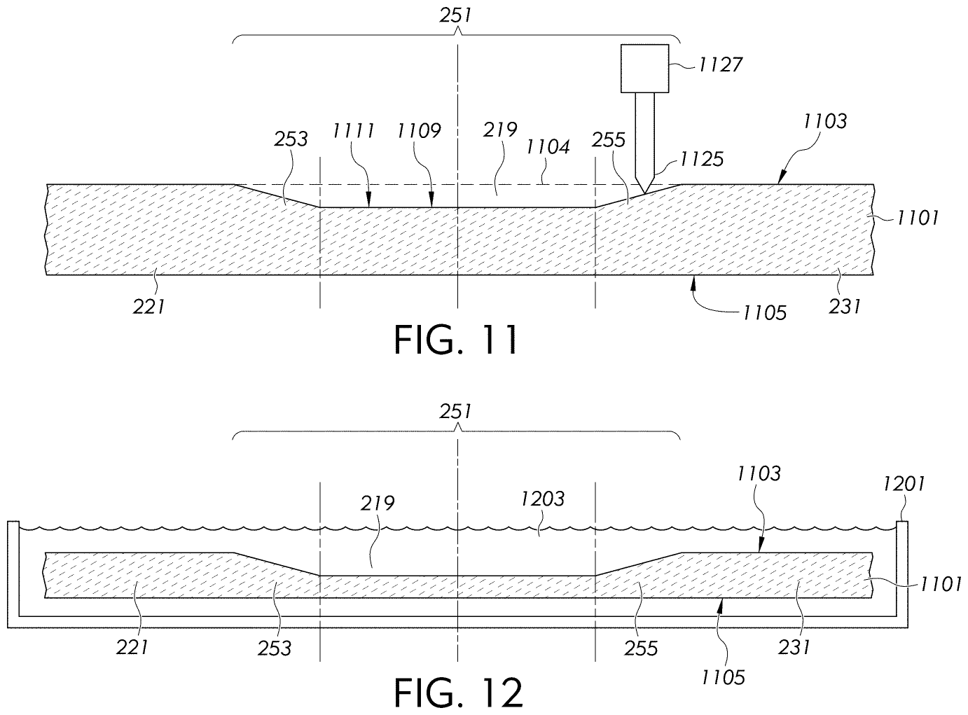

Aspects of methods of making the foldable apparatus 101, 301, 401, 501, 601, and/or 701 and/or test foldable apparatus 902 illustrated in FIGS. 2-7 and 9, in accordance with aspects of the disclosure, will be discussed with reference to the flow chart in FIG. 10 and example method steps illustrated in FIGS. 11-20.

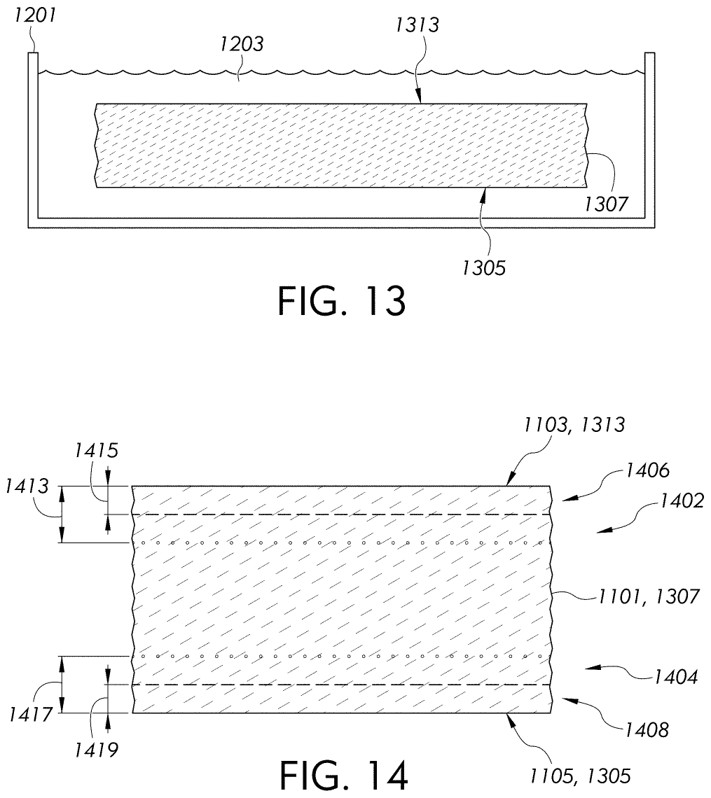

In a first step 1001 of methods of the disclosure, as shown in FIGS. 11 and 13, methods can start with providing a foldable substrate 1101 or 1307. In aspects, the foldable substrate 1101 or 1307 may be provided by purchase or otherwise obtaining a substrate or by forming the foldable substrate. In aspects, the foldable substrate 1101 or 1307 can comprise a glass-based substrate. In further aspects, glass-based substrates can be provided by forming them with a variety of ribbon forming processes, for example, slot draw, down-draw, fusion down-draw, up-draw, press roll, redraw, or float. In further aspects, glass-based substrates comprising ceramic crystals can be provided by heating a glass-based substrate to crystallize one or more ceramic crystals. The foldable substrate 1101 or 1307 may comprise an existing second major surface 1105 or 1305 (see FIGS. 11 and 13) that can extend along a plane. The existing second major surface 1105 or 1305 can be opposite an existing first major surface 1103 or 1313, and the existing first major surface 1103 or 1313 (see FIGS. 11 and 13) can extend along a plane. In aspects, the foldable substrate 1101 can comprise a recess 219 in the existing first major surface 1103 of the foldable substrate 201 exposing an existing first central surface area 1109. In further aspects, although not shown, the foldable substrate can comprise an another recess in the second major surface of the foldable substrate exposing an existing second central surface area.

After step 1001, as shown in FIG. 11, methods can comprise step 1003 comprising forming a recess 219 in the existing first major surface 1103. In further aspects, the recess 219 may be formed by etching, laser ablation or mechanically working the existing first major surface 1103. For example, the existing first major surface 1103 may be mechanically worked by diamond engraving to produce very precise patterns in glass-based substrates. As shown in FIG. 11, diamond engraving can be used to create the recess 219 in the existing first major surface 1103 of the foldable substrate 201 where a diamond-tip probe 1125 can be controlled using a computer numerical control (CNC) machine 1127. Materials other than diamond can be used for engraving with a CNC machine. Furthermore, other methods of forming the recess include lithography, etching, and laser ablation. For example, etching can comprise disposing a mask over portions of the existing first major surface 1103 not to be etched before exposing the existing first major surface 1103 of the foldable substrate 201 to an etchant to form the recess 219, and then removing the mask. Forming the recess 219 in the existing first major surface 1103 can provide a central portion 251 between a first portion 221 and a second portion 231 of the foldable substrate 1101. The central portion 251 can comprise a first central surface area 209 wherein the recess 219 can be defined between the existing first central surface area 1109 and the first plane 1104 along which the existing first major surface 1103 extends in the flat configuration shown in FIG. 11. The existing first central surface area 1109 can attach the first portion 221 to the second portion 231. The central portion 251 can optionally comprise a first transition region 253 attaching the first portion 221 to a central major surface 211 and a second transition region 255 attaching the second portion 231 to the central major surface 211. In aspects, a thickness of the first transition region 253 can continuously increase from the central major surface 211 to the first portion 221. In further aspects, a thickness of the second transition region 255 can continuously increase from the central major surface 211 to the second portion 231. As shown in FIG. 11, the existing first central surface area 1109 can comprise the central major surface 1111 of the central portion 251 that, as shown, may be planar although nonplanar configurations may be provided in further aspects. Furthermore, the central major surface 1111 can be parallel with respect to the first plane 1104 and/or the existing second major surface 1105 as shown in FIG. 11.

In aspects, although not shown, step 1003 can further comprise reducing a thickness of the foldable substrate 1101. In further aspects, the thickness of the foldable substrate 1101 can be reduced by mechanically working (e.g., grinding). In further aspects, the thickness of the foldable substrate 1101 can be reduced using chemical etching. In even further aspects, chemical etching can comprise contacting the foldable substrate 1101 with an etching solution contained in an etching bath. In even further aspects, the etching solution can comprise one or more mineral acids (e.g., HCl, HF, H₂SO₄, HNO₃). In aspects, the thickness of the foldable substrate 1101 can be reduced by removing a layer from the existing first major surface 1103 of the foldable substrate 1101 to expose a new existing first major surface. In addition, or alternatively, the thickness of the foldable substrate 1101 can be reduced by removing a layer from the existing second major surface 1105 of the foldable substrate 1101 to expose a new existing second major surface. Reducing the thickness of the foldable substrate 1101 by removing a layer from the existing second major surface 1105, for example, to remove the skin layer to expose a central layer with more consistent optical properties across the length of foldable substrate 1101 (e.g., glass-based material), as discussed above. Removing the layers from both the existing first major surface and the existing second major surface can remove the outer layers of the foldable substrate 1101 (e.g., glass-based material) that may have inconsistent optical properties than the underlying interior portions of the foldable substrate 1101 (e.g., glass-based material). Consequently, the entire thickness throughout the length and the width of the foldable substrate 1101 may have more consistent optical properties to provide consistent optical performance with little or no distortions across the entire foldable substrate 1101 (e.g., glass-based substrate).

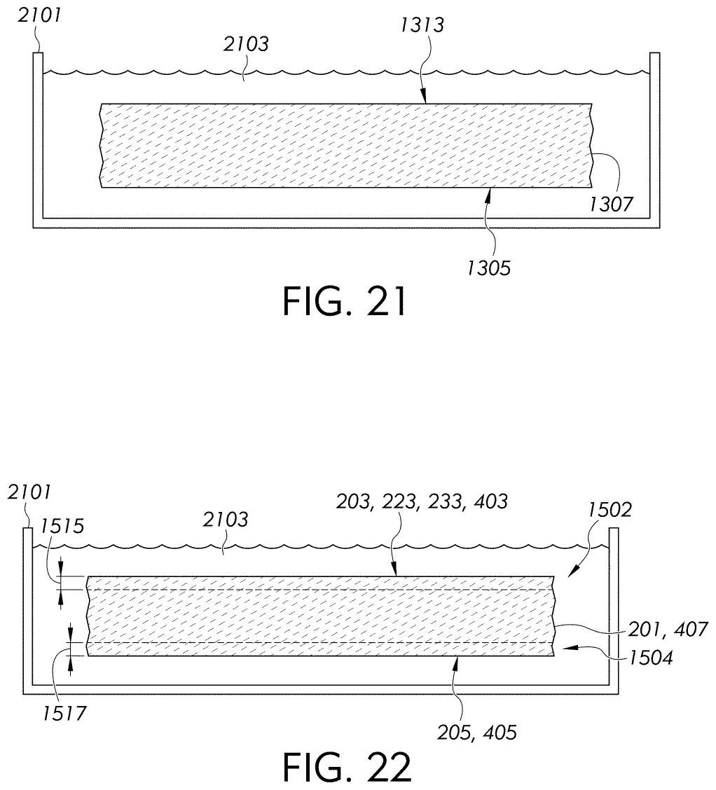

In aspects, as shown in FIG. 21, step 1003 can optionally further comprise rinsing the foldable substrate with a rinsing agent after reducing the thickness of the foldable substrate. In further aspects, as shown, the foldable substrate 1307 can be immersed in a bath 2101 comprising a rinsing agent 2103. In further aspects, the rinsing agent can comprise water (e.g., purified, filtered, deionized, distilled) and/or a detergent solution (e.g., neutral detergent, alkaline detergent). In even further aspects, an alkaline detergent can comprise from about 1 wt % to about 4 wt % of a rinse solution. An exemplary aspect of alkaline detergents include SemiClean KG (Yokohama Oils & Fats Industry Co.). In further aspects, the rinsing can further comprise sonication (e.g., ultrasonication).

After step 1003 or 1001, as shown in FIGS. 12-13, the method can proceed to step 1005 comprising chemically strengthening the foldable substrate 1101 or 1307. Chemically strengthening the foldable substrate 1101 or 1307 (e.g., glass-based material) by ion exchange can occur when a first cation within a depth of a surface of a foldable substrate 1101 or 1307 is exchanged with a second cation within a molten salt or salt solution 1203 that has a larger radius than the first cation. For example, a lithium cation within the depth of the surface of the foldable substrate 1101 or 1307 can be exchanged with a sodium cation or potassium cation within a salt solution 1203. Consequently, the surface of the foldable substrate 1101 or 1307 is placed in compression and thereby chemically strengthened by the ion exchange process since the lithium cation has a smaller radius than the radius of the exchanged sodium cation or potassium cation within the salt solution 1203. Chemically strengthening the foldable substrate 1101 or 1307 can comprise contacting at least a portion of a foldable substrate 1101 or 1307 comprising lithium cations and/or sodium cations with a salt bath 1201 comprising the salt solution 1203 comprising potassium nitrate, potassium phosphate, potassium chloride, potassium sulfate, sodium chloride, sodium sulfate, and/or sodium nitrate, whereby lithium cations and/or sodium cations diffuse from the foldable substrate 1101 or 1307 to the salt solution 1203 contained in the salt bath 1201. In aspects, the temperature of the salt solution 1203 can be about 300° C. or more, about 360° C. or more, about 400° C. or more, about 500° C. or less, about 460° C. or less, or about 400° C. or less. In aspects, the temperature of the salt solution 1203 can be in a range from about 300° C. to about 500° C., from about 360° C. to about 500° C., from about 400° C. to about 500° C., from about 300° C. to about 460° C., from about 360° C. to about 460° C., from about 400° C. to about 460° C., from about 300° C. to about 400° C., from about 360° C. to about 400° C., or any range or subrange therebetween. In aspects, the foldable substrate 1101 or 1307 can be in contact with the salt solution 1203 for about 15 minutes or more, about 1 hour or more, about 3 hours or more, about 48 hours or less, about 24 hours or less, or about 8 hours or less. In aspects, the foldable substrate 1101 or 1307 can be in contact with the salt solution 1203 for a time in a range from about 15 minutes to about 48 hours, from about 1 hour to about 48 hours, from about 3 hours to about 48 hours, from about 15 minutes to about 24 hours, from about 1 hour to about 24 hours, from about 3 hours to about 48 hours, from about 3 hours to about 24 hours, from about 3 hours to about 8 hours, or any range or subrange therebetween.

As shown in FIG. 14, chemically strengthening the foldable substrate 1101 or 1307 can comprise chemically strengthening the existing first major surface 1103 or 1313 to form an existing first compressive stress region 1402 extending to an existing first depth of compression 1413 from the first major surface and an existing first depth of layer of one or more alkali metal ions associated with the existing first compressive stress region 1402. In aspects, first portion 221 of the foldable substrate 1101 can comprise the existing first compressive stress region 1402 extending to the existing first depth of compression 1413 from the first surface area 223 and/or the second portion 231 of the foldable substrate 1101 can comprise the existing first compressive stress region 1402 extending to the existing first depth of compression 1413 from the third surface area 233. In aspects, the chemically strengthening comprises chemically strengthening the existing second major surface 1105 or 1305 the foldable substrate 1101 or 1307 to form an existing second compressive stress region 1404 extending to an existing second depth of compression 1417 from the existing second major surface 1105 or 1305 and an existing second depth of layer of one or more alkali metal ions associated with the existing second compressive stress region 1404. In aspects, the first portion 221 of the foldable substrate 1101 can comprise the existing second compressive stress region 1404 extending to the existing second depth of compression 1417 from the second surface area 225 and/or the second portion 231 of the foldable substrate 1101 can comprise the existing second compressive stress region 1404 extending to the existing second depth of compression 1417 from the fourth surface area 235. In aspects, the chemically strengthening the foldable substrate 1101 can comprise chemically strengthening the existing first central surface area 1109 or 209 to form an existing first central compressive stress region extending to an existing first central depth of compression and an existing first central depth of layer of one or more alkali metal ions associated with the existing first depth of compression. In aspects, the chemically strengthening the foldable substrate 1101 can comprise chemically strengthening the second central surface area 213 to form an existing second central compressive stress region extending to an existing second central depth of compression and an existing second central depth of layer of one or more alkali metal ions associated with the existing second depth of compression. In aspects, the existing first compressive stress region can comprise an existing first maximum compressive stress, and/or the existing second compressive stress region can comprise an existing second maximum compressive stress. In further aspects, the existing first maximum compressive stress and/or the existing second maximum compressive stress can be within one or more of the ranges discussed above for the first maximum compressive stress and/or second maximum compressive stress.

In aspects, as shown in FIG. 22, step 1005 can optionally further comprise rinsing the foldable substrate with a rinsing agent after reducing the thickness of the foldable substrate. In further aspects, as shown, the foldable substrate 1502 can be immersed in a bath 2101 comprising a rinsing agent 2103. In further aspects, the rinsing agent can comprise water (e.g., purified, filtered, deionized, distilled) and/or a detergent solution (e.g., neutral detergent, alkaline detergent). In even further aspects, an alkaline detergent can comprise from about 1 wt % to about 4 wt % of a rinse solution. An exemplary aspect of alkaline detergents include SemiClean KG (Yokohama Oils & Fats Industry Co.). In further aspects, the rinsing can further comprise sonication (e.g., ultrasonication).

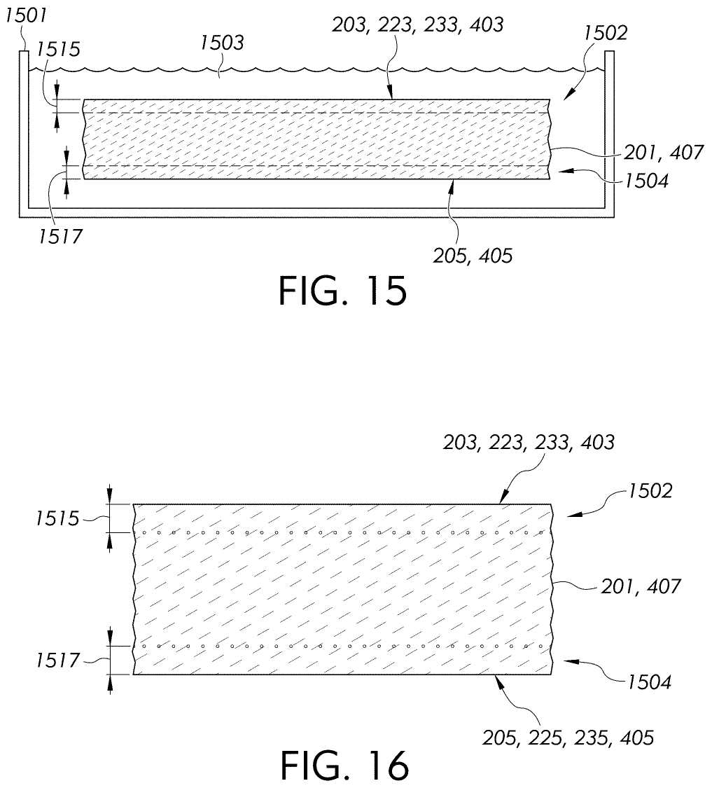

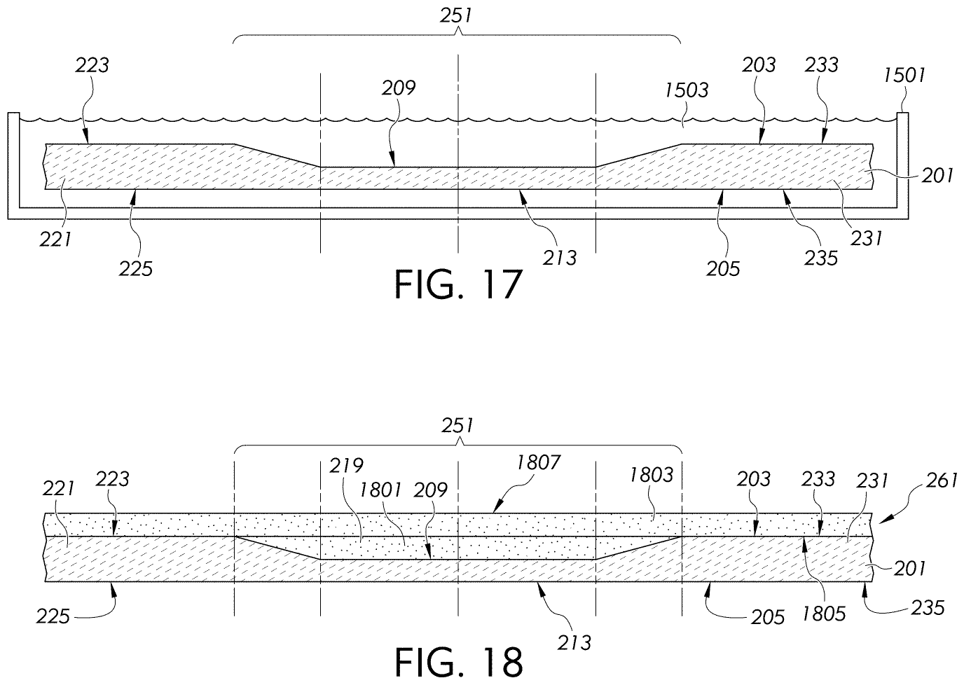

After step 1005, as shown in FIGS. 15 and 17, methods can proceed to step 1007 comprising contacting the existing first major surface 1103 or 1313 with a solution 1503 comprising a first temperature for a period of time remove a first outer compressive layer 1406 of the existing first compressive stress region 1402 to form a new first major surface 203. As shown in FIG. 14, a first outer compressive layer 1406 comprising a first thickness 1415 can be removed in step 1007. As shown, the first thickness 1415 of the first outer compressive layer 1406 is less than the existing first depth of compression 1413.

As shown in FIGS. 15-16, after removing the first outer compressive layer 1406, the foldable substrate 201 or 407 can comprise a new first compressive stress region 1502 extending to a new first depth of compression 1515 from the new first major surface 203 or 403. In further aspects, the new first depth of compression 1515 can be less than the existing first depth of compression 1413, for example, by about the first thickness 1415 of the first outer compressive layer 1406 removed in step 1007. In further aspects, as shown, the new first compressive stress region 1502 can extend to the first depth of compression 1515 from the first surface area 223 and/or the third surface area 233.

In aspects, as shown in FIGS. 15 and 17, step 1007 can further comprise contacting the existing second major surface 1105 or 1305 with the solution comprising the first temperature for the period of time remove a second outer compressive layer 1408 of the existing second compressive stress region 1404 to form a new second major surface 205. As shown in FIG. 14, a second outer compressive layer 1408 comprising a second thickness 1419 can be removed in step 1007. As shown, the second thickness 1419 of the second outer compressive layer 1408 is less than the existing second depth of compression 1417.

In aspects, the first thickness 1415 of the first outer compressive layer 1406 and/or the second thickness 1419 of the second outer compressive layer 1408 can be about 0.05 μm or more, about 0.1 μm or more, about 0.2 μm or more, about 0.3 μm or more, about 0.5 μm or more, about 0.8 μm or more about 5 μm or less, about 4 μm or less, about 3 μm or less, about 2 μm or less, about 1 μm or less, about 0.2 μm or less, or about 0.4 μm or less. In aspects, the first thickness 1415 of the first outer compressive layer 1406 and/or the second thickness 1419 of the second outer compressive layer 1408 can be in a range from about 0.05 μm to about 5 μm, from about 0.1 μm to about 5 μm, from about 0.1 μm to about 4 μm, from about 0.2 μm to about 4 μm, from about 0.2 μm to about 4 μm, from about 0.3 μm to about 3 μm, from about 0.3 μm to about 2 μm, from about 0.5 μm to about 2 μm, from about 0.5 μm to about 1 μm, from about 0.8 μm to about 1 μm, or any range or subrange therebetween. In aspects, the first thickness 1415 of the first outer compressive layer 1406 and/or the second thickness 1419 of the second outer compressive layer 1408 can be in a range from about 0.05 μm to about 4 μm, from about 0.05 μm to about 3 μm, from about 0.1 μm to about 3 μm, from about 0.1 μm to about 2 μm, from about 0.1 μm to about 1 μm, from about 0.2 μm to about 1 μm, from about 0.3 μm to about 1 μm, from about 0.3 μm to about 0.4 μm, or any range or subrange therebetween. In aspects, the first thickness 1415 of the first outer compressive layer 1406 and/or the second thickness 1419 of the second outer compressive layer 1408 can be in a range from about 0.05 μm to about 1 μm, from about 0.05 μm to about 0.4 μm, from about 0.05 μm to about 0.2 μm, from about 0.1 μm to about 0.2 μm, or any rang range or subrange therebetween. In aspects, the first thickness 1415 of the first outer compressive layer 1406 and/or the second thickness 1419 of the second outer compressive layer 1408 can be in a range from about 0.1 μm to about 0.4 μm, from about 0.2 μm to about 0.4 μm, or any range or subrange therebetween. In aspects, the first thickness 1415 of the first outer compressive layer 1406 can be about equal to the second thickness 1419 of the second outer compressive layer 1408 although different thicknesses may be provided in further aspects.

As shown in FIGS. 15-16, after removing the second outer compressive layer 1408, the foldable substrate 201 or 407 can comprise a new second compressive stress region 1504 extending to a new second depth of compression 1517 from the new second major surface 205 or 405. In further aspects, the new second depth of compression 1517 can be less than the existing first depth of compression 1417, for example, by about the second thickness 1419 of the second outer compressive layer 1408 removed in step 1007. In further aspects, as shown, the new second compressive stress region 1504 can extend to the second depth of compression 1517 from the second surface area 225 and/or the fourth surface area 235.

In aspects, although not shown, step 1007 can further comprise contacting the existing first central surface area and/or second central surface area with the solution comprising the first temperature for the period of time remove a first central outer compressive layer and/or a second central outer compressive layer to form a new first central surface area 209 and/or new second central surface area 213. In further aspects, a first central thickness of the first central outer compressive layer and/or the second central thickness of the second central outer compressive layer can be within one or more of the ranges discussed above with regards to the first thickness 1415 and/or second thickness 1419. In further aspects, the new first central surface area 209 can comprise a new first compressive stress region extending to a new first central depth of compression and/or the new second central surface area 213 can comprise a new second compressive stress region extending to a new second central depth of compression. In even further aspects, the new first central depth of compression and/or the new central second depth of compression can be less than the existing first central depth of compression and/or the existing second central depth of compression, respectively.

Removing an outer compressive stress layer (e.g., first outer compressive layer, second outer compressive layer, first central outer compressive layer, second central outer compressive layer) can be beneficial to remove surface imperfections generated during forming the foldable substrate, prior processing of the foldable substrate including chemically strengthening the foldable substrate, and/or may be exacerbated by the compressive stress region(s) created by the chemically strengthening the foldable substrate. Indeed, chemically strengthening may result in surface imperfections that can affect the strength and/or optical quality of the foldable substrate. By removing an outer compressive stress layer, surface imperfections generated during chemically strengthening can be removed. Such imperfections (e.g., defects, flaws, inclusions) may generate cracks or other imperfections that can present points of weakness where catastrophic failure of the foldable substrate may occur upon folding. As fewer surface imperfections are present, a smaller bend radius may be achieved without failure of the foldable substrate and/or the foldable substrate may be able to withstand greater pen drop heights, as discussed above. Removal of a small thickness (e.g., 5 micrometers or less) may avoid substantially changing the thickness of the foldable substrate or the surface compression achieved during chemically strengthening.

As used herein, the solution is “at a first temperature” if the source (e.g., reservoir, tank, bath) of the solution is maintained at that temperature and the solution is at substantially the first temperature when it contacts the foldable substrate. In aspects, as shown in FIGS. 15 and 17, contacting the foldable substrate (e.g., first major surface, second major surface) with the solution 1503 can comprise immersing the foldable substrate 1101 and/or 1307 in a bath 1501 comprising the solution 1503. In aspects, although not shown, contacting the foldable substrate with the solution can comprise spraying the solution on the foldable substrate and/or applying the solution with a roller (e.g., porous roller, sponge roller).

In aspects, the solution 1503 can comprise an acidic solution. In further aspects, the acidic solution can comprise an acid, for example, one or more mineral and/or organic acid. Exemplary aspects of mineral acids include nitric acid, hydrochloric acid, phosphoric acid, and/or sulfuric acid. Exemplary aspects of an organic acid include citric acid, formic acid, acetic acid, lactic acid, and/or tartaric acid. In further aspects, the acidic solution can comprise a concentration of the acid of about 0.1 molar (M) or more, about 0.5 M or more, about 1 M or more, about 1.5 M or more, about 3 M or more, about 30 M or less, about 20 M or less, about 10 M or less, or about 8 M or less, about 5 M or less, or about 4 M or less. In further aspects, the acidic solution can comprise a concentration of the acid in a range from about 0.1 M to about 30M, from about 0.1 M to about 20 M, from about 0.1 M to about 10 M, from about 0.5 M to about 10 M, from about 0.5 M to about 8 M, from about 1 M to about 8 M, from about 1 M to about 5 M, from about 1.5 M to about 5 M, from about 1.5 M to about 4 M, from about 3 M to about 4 M, from about 3 M to about 5 M, or any range or subrange therebetween. In further aspects, the acidic solution can further comprise a metal chloride. Exemplary aspects of metal chloride include one or more of aluminum chloride, iron chloride, calcium chloride, and/or magnesium chloride. In even further aspects, a concentration of the metal chloride can be 0 molar (M) or more, about 0.001 M or more, about 0.01 M or more, about 0.1 M or more, about 0.2 M or more, about 0.5 M or more, about 0.8 M or more, about 5 M or less, about 3 M or less, about 2 M or less, about 1.5 M or less, about 1.2 M or less, or about 1 M or less. In further aspects, a concentration of the metal chloride can be 0 M to about 5 M, from about 0.001 M to about 5 M, from about 0.001 to about 3 M, from about 0.01 M to about 3 M, from about 0.01 M to about 2 M, from about 0.01 M to about 1.5 M, from about 0.1 M to about 1.5 M, from about 0.2 M to about 1.5 M, from about 0.2 M to about 1.2 M, from about 0.5 M to about 1.2 M, from about, from about 0.8 M to about 1.2 M, from about 0.8 M to about 1 M, or any range or subrange therebetween. In further aspects, the acidic solution can be substantially fluoride-free. In further aspects, the acidic solution can be free of HF. In further aspects, the acidic solution can comprise the first temperature of about 60° C. or more, about 70° C. or more, about 75° C. or more, about 100° C. or less, about 90° C. or less, or about 80° C. or less. In aspects, the acidic solution can comprise the first temperature in a range from about 60° C. to about 100° C., from about 70° C. to about 100° C., from about 70° C. to about 90° C., from about 75° C. to about 90° C., from about 75° C. to about 80° C., or any range or subrange therebetween. In further aspects, the period of time that the acidic solution is in contact with the foldable substrate (e.g., first major surface, second major surface) can be about 10 minutes or more, about 15 minutes or more, about 20 minutes or more, about 30 minutes or more, about 45 minutes or more, about 180 minutes or less, about 120 minutes or less, about 90 minutes or less, about 75 minutes or less, or about 60 minutes or less. In further aspects, the period of time that the acidic solution is in contact with the foldable substrate (e.g., first major surface, second major surface) can be in a range from about 10 minutes to about 180 minutes, from about 10 minutes to about 120 minutes, from about 15 minutes to about 120 minutes, from about 15 minutes to about 90 minutes, from about 20 minutes to about 90 minutes, from about 20 minutes to about 75 minutes, from about 30 minutes to about 75 minutes, from about 30 minutes to about 60 minutes, from about 45 minutes to about 60 minutes, or any range or subrange therebetween. For example, a thickness of the outer compressive layer removed by the acidic solution can be from about 0.1 μm to about 5 μm, from about 0.3 μm to about 3 μm, or any of the ranges discussed above for the thickness of the outer compressive layer.

Without wishing to be bound by theory, initially contacting an existing surface of the foldable substrate with the acidic solution can preferentially remove non-silica components of the surface of the foldable substrate to produce a porous leached layer comprising a higher concentration of silica than the remainder of the foldable substrate. Continued treatment with the acidic solution can remove the remainder of the existing surface of the foldable substrate. Without wishing to be bound by theory, a metal chloride can catalyze the process of the acid solution removing at least a portion of a surface of the foldable substrate. Providing an acidic concentration of at least 0.1 M acid can enable removable of the existing first major surface in a reasonable time. Providing an acidic concentration of not more than 30 M (e.g., not more than 5 M) can enable substantially uniform removal of the existing surface. Providing a metal chloride can increase an etching rate of the solution.

In aspects, the solution can comprise an alkaline solution. In further aspects, the alkaline solution can comprise a hydroxide-containing base. As used herein, alkaline refers to solutions having a pH of 11 or more while a base refers to a compound comprising a pKa of 9 or more. In even further aspects, the alkaline solution can comprise a pH of 14 or more, 14.2 or more, 14.5 or more, 14.7 or more, about 14.8 or more. In even further aspects, the alkaline solution can comprise a pH in a range from 14 to 15, 14.2 to 15, 14.5 to 15, from 14.7 to 15, from 14.8 to 15, or any range or subrange therebetween. In even further aspects, the alkaline solution can comprise a concentration of the hydroxide-containing base of about 10 weight % (wt %) or more, about 15 wt % or more, about 20 wt % or more, about 25 wt % or more, about 60 wt % or less, about 50 wt % or less, about 40 wt % or less, or about 30 wt % or less. In even further aspects, the alkaline solution can comprise a concentration of the hydroxide-containing base in a range from about 10 wt % to about 60 wt %, from about 15 wt % to about 60 wt %, from about 15 wt % to about 50 wt %, from about 20 wt % to about 50 wt %, from about 20 wt % to about 40 wt %, from about 25 wt % to about 40 wt %, from about 25 wt % to about 30 wt %, or any range or subrange therebetween. In even further aspects, the alkaline solution can comprise a concentration of the hydroxide-containing base of about 1.7 molar (M) or more, about 2.5 M or more, about 3.5 M or more, about 5 M or more, about 6 M or more, about 7 M or more, about 8 M or more, about 10 M or less, about 9 M or less, about 8.5 M or less, or about 8 M or less. In even further aspects, the alkaline solution can comprise a concentration of the hydroxide-containing base in a range from about 1.7 M to about 10 M, from about 2.5 M to about 10 M, from about 2.5 M to about 9.5 M, from about 3.5 M to about 9.5 M, from about 3.5 M to about 9 M, from about 5 M to about 9 M, from about 6 M to about 9 M, from about 7 M to about 9 M, from about 8 M to about 9 M, or any range or subrange therebetween. In even further aspects, the alkaline solution can comprise a concentration of the hydroxide-containing base in a range from about 3.5 M to about 8 M, from about 5 M to about 8 M, from about 6 M to about 8 M, from about 7 M to about 8 M, or any range or subrange therebetween. Exemplary aspects of a hydroxide-containing base include one or more of sodium hydroxide, potassium hydroxide, tetramethylammonium hydroxide, and/or ammonium hydroxide. In even further aspects, the alkaline solution can be substantially fluoride-free.

In even further aspects, the alkaline solution can comprise the first temperature of about 60° C. or more, about 65° C. or more, about 70° C. or more, about 75° C. or more, about 80° C. or more, about 120° C. or less, about 110° C. or less, about 100° C. or less, about 95° C. or less, about 90° C. or less, or about 85° C. or less. In even further aspects, the alkaline solution can comprise the first temperature in a range from about 60° C. to about 120° C., from about 60° C. to about 110° C., from about 65° C. to about 110° C., from about 65° C. to about 100° C., from about 70° C. to about 100° C., from about 70° C. to about 95° C., from about 75° C. to about 95° C., from about 75° C. to about 90° C., from about 80° C. to about 90° C., from about 80° C. to about 85° C., or any range or subrange therebetween. In further aspects, the period of time that the alkaline solution is in contact with the foldable substrate (e.g., first major surface, second major surface) can be about 10 minutes or more, about 15 minutes or more, about 20 minutes or more, about 30 minutes or more, about 35 minutes or more, about 40 minutes or more, about 60 minutes or more, about 75 minutes or more, about 90 minutes or more, about 120 minutes or less, about 115 minutes or less, about 105 minutes or less, about 90 minutes or less, about 75 minutes or less, about 60 minutes or less, about 50 minutes or less, or about 45 minutes or less. In further aspects, the period of time that the alkaline solution is in contact with the foldable substrate (e.g., first major surface, second major surface) can be in a range from about 10 minutes to about 120 minutes, from about 10 minutes to about 90 minutes, from about 15 minutes to about 90 minutes, from about 15 minutes to about 75 minutes, from about 20 minutes to about 75 minutes, from about 20 minutes to about 60 minutes, from about 30 minutes to about 60 minutes, from about 30 minutes to about 50 minutes, from about 35 minutes to about 50 minutes, from about 35 minutes to about 45 minutes, from about 40 minutes to about 45 minutes, or any range or subrange therebetween. In further aspects, the period of time that the alkaline solution is in contact with the foldable substrate (e.g., first major surface, second major surface) can be in a range from 30 minutes to about 120 minutes, from about 40 minutes to about 120 minutes, from about 60 minutes to about 120 minutes, from about 75 minutes to about 120 minutes, from about 75 minutes to about 115 minutes, from about 90 minutes to about 115 minutes, from about 90 minutes to about 105 minutes, or any range or subrange therebetween. Without wishing to be bound by theory, the alkaline solution can substantially evenly remove a layer from the surface of the foldable substrate. For example, a thickness of the outer compressive layer removed by the hydroxide-containing solution can be from about 0.05 μm to about 5 μm, from about 0.05 μm to about 0.2 μm, from about 0.1 μm to about 0.4 μm, or any of the ranges discussed above for the thickness of the outer compressive layer.

In even further aspects, contacting the existing first major surface with the alkaline solution can result in a new first depth of compression of the first compressive stress region. As used herein, a difference between a first value and second value is equal the first value minus the second value. In still further aspects, a difference between the existing first depth of compression and the new first depth of compression can be (i.e., the new first depth of compression can be less than the existing first depth of compression by) about 0.01 μm or more, about 0.05 μm or more, about 0.40 μm or less, about 0.20 μm or less, or about 0.10 μm or less. In still further aspects, a difference between the existing first depth of compression and the new first depth of compression can be in a range from about 0.01 μm to about 0.40 μm, from about 0.01 μm to about 0.20 μm, from about 0.01 μm to about 0.10 μm, from about 0.05 μm to about 0.10 μm, from about 0.05 μm to about 0.20 μm, or any range or subrange therebetween. In still further aspects, a difference between the existing first depth of compression and the new first depth of compression can be less than the thickness of the outer compressive layer. In even further aspects, contacting the existing first major surface with the alkaline solution can result in a new first depth of layer associated with the first compressive stress region. In still further aspects, a difference between an existing first depth of layer of one or more alkali metal ions associated with the first compressive stress region extending to the existing first depth of compression and the new first depth of compression of the one or more alkali metal ions associated with the first compressive stress region extending to the new first depth of compression can be about 0.01 μm or more, about 0.02 μm or more, about 0.05 μm or more, about 0.20 μm or less, about 0.10 μm or less, or about 0.08 μm or less. In still further aspects, a difference between an existing first depth of layer of one or more alkali metal ions associated with the first compressive stress region extending to the existing first depth of compression and the new first depth of compression of the one or more alkali metal ions associated with the first compressive stress region extending to the new first depth of compression can be in a range from about 0.01 μm to about 0.20 μm, from about 0.01 μm to about 0.10 μm, from about 0.02 μm to about 0.10 μm, from about 0.02 μm to about 0.08 μm, from about 0.05 μm to about 0.08 μm, or any range or subrange therebetween. In even further aspects, contacting the existing first major surface with the alkaline solution can result in a new maximum compressive stress (e.g., first maximum compressive stress). In still further aspects, a difference between the existing maximum compressive stress (e.g., existing first maximum compressive stress) and the new maximum compressive stress (e.g., first maximum compressive stress) can be about −10 MPa or more, about 0 MPa or more, about 5 MPa or more, about 10 MPa or more, about 40 MPa or less, about 30MPa or less, or about 20 MPa or less. For example, the new maximum compressive stress can be less than the existing maximum compressive stress by 40 MegaPascals or less. In still further aspects, a difference between the existing maximum compressive stress (e.g., existing first maximum compressive stress) and the new maximum compressive stress (e.g., first maximum compressive stress) can be in a range from (i.e., the new maximum compressive stress minus the existing maximum compressive stress by) about −10 MPa to about 40 MPa, from about −10 MPa to about 30 MPa, from about −10 MPa to about 20 MPa, from about 0 MPa to about 20 MPa, from about 0 MPa to about 10 MPa, from about 5 MPa to about 10 MPa, or any range or subrange therebetween.

In aspects, the solution can comprise an H₂SiF₆-containing solution. In further aspects, a concentration of H₂SiF₆ in the H₂SiF₆-containing solution can be about 0.1 molar (M) or more, about 0.3 M or more, about 0.5 M or more, about 0.8 M or more, about 1 M or more, about 1.2 M or more, about 3.3 M or less, about 3 M or less, about 2.5 M or less, about 2 M or less, about 1.8 M or less, or about 1.5 M or less. In further aspects, a concentration of H₂SiF₆ in the H₂SiF₆-containing solution can be in a range from about 0.1 M to about 3.3 M, from about 0.1 M to about 3 M, from about 0.3 M to about 3 M, from about 0.3 M to about 2.5 M, from about 0.5 M to about 2.5, from about 0.5 M to about 2 M, from about 0.8 M from about 2 M, from about 0.8 M to about 1.8 M, from about 1 M to about 1.8 M, from about 1 M to about 1.5 M, from about 1.2 M to about 1.5 M, or any range or subrange therebetween. In further aspects, the H₂SiF₆-containing solution can further comprise boric acid (H₃BO₃). In even further aspects, a concentration of boric acid in the H₂SiF₆-containing solution can be about 0 molar (M) or more, about 0.001 M or more, about 0.01 or more, about 0.1 M or more, about 0.2 M or more, about 3 M or less, about 1 M or less, about 0.5 M or less, or about 3 M or less. In even further aspects, a concentration of boric acid in the H₂SiF₆-containing solution can be in a range from about 0 M to about 3 M, from about 0.001 M to about 3 M, from about 0.001 M to about 1 M, from about 0.01 M to about 1 M, from about 0.01 M to about 0.5 M, from about 0.1 M to about 0.5 M, from about 0.2 M to about 0.5 M, from about 0.2 M to about 0.3 M, or any range or subrange therebetween. In even further aspects, the H₂SiF₆-containing solution can comprise the first temperature of about 20° C. or more, about 25° C. or more, about 30° C. or more, about 35° C. or more, about 40° C. or more, about 90° C. or less, about 70° C. or less, about 60° C. or less, about 50° C. or less, or about 45° C. or less. In even further aspects, the H₂SiF₆-containing solution can comprise the first temperature in a range from about 20° C. to about 90° C., from about 20° C. to about 70° C., from about 25° C. to about 70° C., from about 30° C. to about 70° C., from about 30° C. to about 60° C., from about 35° C. to about 60° C., from about 35° C. to about 50° C., from about 40° C. to about 50° C., from about 40° C. to about 45° C., or any range or subrange therebetween. In even further aspects, the H₂SiF₆-containing solution can comprise the first temperature in a range from about 40° C. to about 90° C., from about 40° C. to about 70° C., from about 40° C. to about 60° C., from about 40° C. to about 50° C., from about 40° C. to about 45° C., or any range or subrange therebetween. In further aspects, the period of time that the H₂SiF₆-containing is in contact with the foldable substrate (e.g., first major surface, second major surface) can be about 15 seconds or more, about 20 seconds or more, about 30 seconds or more, about 45 seconds or more, about 1 minute or more, about 2 minutes or more, about 5 minutes or more, about 10 minutes or more, about 15 minutes or more, about 20 minutes or more, about 25 minutes or more, about 30 minutes or more, about 75 minutes or less, about 60 minutes or less, about 50 minutes or less, about 45 minutes or less, about 40 minutes or less, about 35 minutes or less, about 15 minutes or less, about 10 minutes or less, or about 5 minutes or less. In further aspects, the period of time that the H₂SiF₆-containing is in contact with the foldable substrate (e.g., first major surface, second major surface) can be in a range from about 15 seconds to about 75 minutes, from about 15 seconds to about 75 minutes, from about 20 seconds to about 60 minutes, from about 30 seconds to about 60 minutes, from about 45 seconds to about 60 minutes, from about 45 seconds to about 50 minutes, from about 1 minute to about 50 minutes, from about 1 minute to about 45 minutes, from about 2 minutes to about 45 minutes, from about 2 minutes to about 40 minutes, from about 5 minutes to about 40 minutes, from about 10 minutes to about 40 minutes, from about 10 minutes to about 35 minutes, from about 15 minutes to about 35 minutes, from about 15 minutes to about 30 minutes, from about 20 minutes to about 30 minutes, from about 25 minutes to about 30 minutes, or any range or subrange therebetween. In further aspects, the period of time that the H₂SiF₆-containing is in contact with the foldable substrate (e.g., first major surface, second major surface) can be in a range from about 15 seconds to about 60 minutes, from about 15 seconds, to about 45 minutes, from about 15 seconds to about 35 minutes, from about 15 seconds to about 15 minutes, from about 15 seconds to about 10 minutes, from about 15 seconds to about 5 minutes, from about 20 seconds to about 5 minutes, from about 30 seconds to about 5 minutes, from about 45 seconds to about 5 minutes, from about 1 minute to about 5 minutes, from about 2 minutes to about 5 minutes, or any range or subrange therebetween. For example, a thickness of the outer compressive layer removed by the H₂SiF₆-containing solution can be from about 0.1 μm to about 5 μm, from about 0.1 μm to about 2 μm, from about 0.4 μm to about 0.7 μm, or any of the ranges discussed above for the thickness of the outer compressive layer.

Without wishing to be bound by theory, treatment with the H₂SiF₆-containing solution can both remove a layer from a surface of the foldable substrate and, in combination with B(OH)3, can simultaneously deposit (e.g., redeposit) a silica (SiO₂) layer on the surface. Providing boric acid in combination with H₂SiF₆ can increase the rate of deposition of the silica layer. Further, deposition of the silica layer can fill defects (e.g., cracks) extending deeper into the foldable substrate than the height of the layer removed. Providing a concentration of boric acid of no more than 3 M (e.g., 1 M) can enable a net removal of sufficient material (e.g., about 100 nm or more, about 200 nm or more) from the surface of the foldable substrate.

In aspects, the solution can comprise a fluoride-containing solution. In further aspects, the fluoride-containing solution can comprise one or both of ammonium fluoride (NH₄F) and/or ammonium bifluoride (NH₄FHF). In even further aspects, a total concentration of ammonium fluoride and/or ammonium bifluoride can be about 0.001 wt % or more, about 0.01 wt % or more, about 0.1 wt % or more, about 1 wt % or more, about 2 wt % or more, about 3 wt % or more, about 25 wt % or less, about 15 wt % or less, about 10 wt % or less, about 8 wt % or less, about 6 wt % or less, or about 5 wt % or less. In even further aspects, a total concentration of ammonium fluoride and/or ammonium bifluoride can be in a range from about 0.001 wt % to about 25 wt %, from about 0.01 wt % to about 25 wt %, from about 0.01 wt % to about 15 wt %, from about 0.1 wt % to about 15 wt %, from about 0.1 wt % to about 10 wt %, from about 1 wt % to about 10 wt %, from about 1 wt % to about 8 wt %, from about 2 wt % to about 8 wt %, from about 2 wt % to about 6 wt %, from about 3 wt % to about 6 wt %, from about 3 wt % to about 5 wt %, or any range or subrange therebetween. In further aspects, the fluoride-containing solution can further comprise an acid. In even further aspects, a concentration of the acid in the fluoride-containing solution can be 0 M or more, about 0.1 M or more, about 0.5 M or more, about 1 M or more, about 2 M or more, about 10 M or less, about 8 M or less, about 5 M or less, or about 3 M or less. In even further aspects, a concentration of the acid in the fluoride-containing solution can be in a range from 0 M to about 10 M, from about 0.1 M to about 10 M, from about 0.1 M to about 8M, from about 0.5 M to about 8 M, from about 0.5 M to about 5 M, from about 1 M to about 5 M, from about 2 M to about 5 M, from about 2 M to about 3 M, or any range or subrange therebetween. In even further aspects, the acid can comprise a mineral acid and/or an organic acid. In addition to the exemplary aspects discussed above for the acid in the acidic solution, the acid in the fluoride-containing solution can comprise fluorosilicic acid. In further aspects, the fluoride-containing solution can comprise the first temperature of about 20° C. or more, about 23° C. or more, about 25° C. or more, about 70° C. or less, about 50° C. or less, about 40° C. or less, about 35° C. or less, or about 30° C. or less. In further aspects, the fluoride-containing solution can comprise the first temperature in a range from about 20° C. to about 70° C., from about 20° C. to about 50° C., from about 20° C. to about 40° C., from about 20° C. to about 35° C., from about 20° C. to about 30° C., from about 23° C. to about 30° C., from about 25° C. to about 30° C., or any range or subrange therebetween. In further aspects, the period of time that the H₂SiF₆-containing is in contact with the foldable substrate (e.g., first major surface, second major surface) can be about 15 seconds or more, about 30 seconds or more, about 45 seconds or more, about 1 minute or more, about 15 minutes or less, about 10 minutes or less, about 5 minutes or less, about 3 minutes or less, or about 2 minutes or less. In further aspects, the period of time that the H₂SiF₆-containing is in contact with the foldable substrate (e.g., first major surface, second major surface) can be in a range from about 15 seconds to about 15 minutes, from about 15 seconds to about 10 minutes, from about 30 seconds to about 10 minutes, from about 30 seconds to about 5 minutes, from about 45 seconds to about 5 minutes, from about 45 seconds to about 3 minutes, from about 1 minute to about 3 minutes, from about 2 minutes to about 3 minutes, or any range or subrange therebetween. Without wishing to be bound by theory, the fluoride-containing solution can produce consistent but low concentrations of HF in solution that can remove a surface of the foldable substrate without the issues (e.g., toxicity, materials handling, material disposal) associated with directly using HF. For example, a thickness of the outer compressive layer removed by the fluoride-containing solution can be from about 0.1 μm to about 5 μm, from about 0.3 μm to about 3 μm, or any of the ranges discussed above for the thickness of the outer compressive layer.

In aspects, the solution can be substantially free of a rheology modifier. As used herein, a rheology modifier is a component other than a solvent or a listed component (e.g., acid, hydroxide-containing base, H₂SiF₆, fluoride-containing compound) that modifies the viscosity of the solution or the shear-dependent behavior (e.g., dilatant, thixotropic). Example aspects of rheology modifiers that the solution can be substantially free of include one or more of cellulose, a cellulose derivative (e.g., ethyl cellulose, methyl cellulose, and AQUAZOL (poly 2 ethyl-2 oxazine)), a hydrophobically modified ethylene oxide urethane modifier (HOER), and an ethylene acrylic acid. Exemplary aspects of solvents comprise a polar solvent (e.g., water, an alcohol, an acetate, acetone, formic acid, dimethylformamide, acetonitrile, dimethyl sulfoxone, nitromethane, propylene carbonate, poly(ether ether ketone)) and/or a non-polar solvent (e.g., pentane, 1,4-dioxane, chloroform, dichloromethane, diethyl ether, hexane, heptane, benzene, toluene, xylene).

After step 1007, as shown in FIGS. 18-20, methods can proceed to step 1009 or 1013 comprising disposing the adhesive layer 261, 1801, or 1803 or the polymer-based portion 561 over the foldable substrate 201 or 407. Step 1009 further comprises disposing a display device 307 over the adhesive layer 261 (see FIG. 3) or the polymer-based portion 561 (see FIG. 5) disposed earlier in step 1009. Step 1013 further comprises disposing a release liner 271 over the adhesive layer 261 (see FIG. 2 or 4) or the polymer-based portion 561 disposed earlier in step 1013.

Disposing the adhesive layer 261 over the foldable substrate 201 or 407 will be discussed below with reference to FIGS. 18-20 with the understanding that the polymer-based portion 561 could be disposed similar to but in place of the adhesive layer 261 and that this discussion is applicable to both steps 1009 and 1013. As shown in FIGS. 18 and 20, disposing the adhesive layer 261 can comprise applying a cured adhesive layer 1803 to contact the first major surface 203 (e.g., first surface area 223 and the third surface area 233) of the foldable substrate 201 or the first major surface 403 of the foldable substrate 407. In aspects, although not shown, the cured adhesive layer can be disposed over and/or contact the first major surface 403 of the foldable substrate 407. In aspects, although not shown, the cured adhesive layer can be disposed over the second major surface 205 or 405 instead of or in addition to the first major surface 203 or 403 of the foldable substrate 201 or 407. In aspects, as shown in FIGS. 18 and 20, the cured adhesive layer 1803 can comprise a first contact surface 1807 and a second contact surface 1805 opposite the first contact surface 1807. In further aspects, as shown, second contact surface 1805 of the cured adhesive layer 1803 can contact the first major surface 203 (e.g., first surface area 223 and the third surface area 233) of the foldable substrate 201 or the first major surface 403 of the foldable substrate 407. In aspects, as shown in FIG. 18, the adhesive layer 261 can comprise one or more sheets of an adhesive material (e.g., a cured adhesive layer 1803 and a first adhesive layer 1801). For example, as shown, there can be an integral interface between the one or more sheets comprising the adhesive layer 261, which can reduce (e.g., avoid) optical diffraction and/or optical discontinuities as light travels between the sheets since the one or more sheets can include substantially the same index of refraction. In aspects, as shown in FIG. 18, the adhesive layer 261 can further fill the recess 219. In further aspects, as shown in FIG. 18, the first adhesive layer 1801 can contact the first central surface area 209.

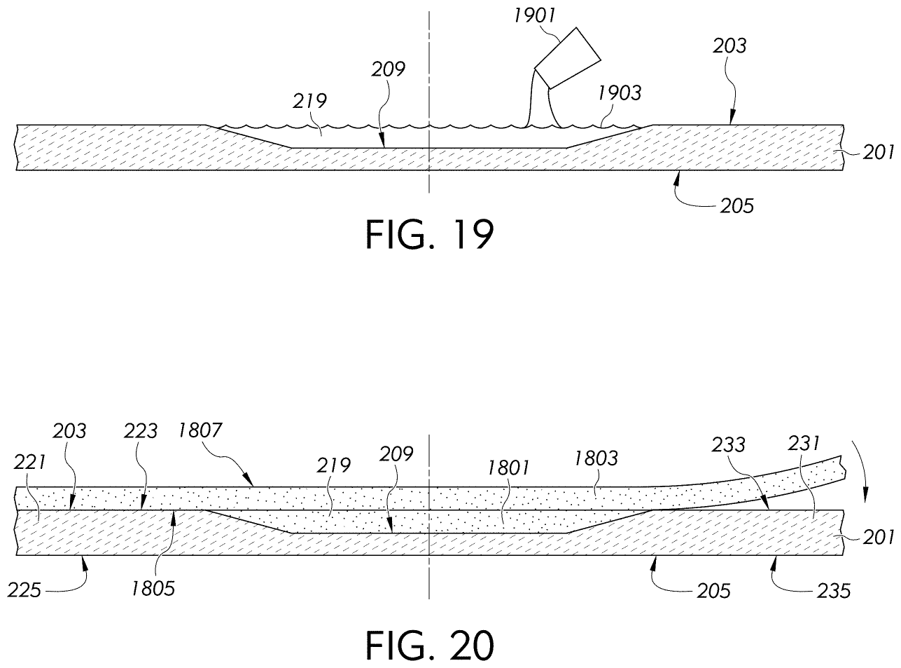

In aspects, as shown in FIG. 19, disposing the adhesive layer can comprise depositing an adhesive liquid 1903 in the recess 219. In further aspects, a conduit (e.g., flexible tube, micropipette, or syringe) may be used to deposit the adhesive liquid 1903 into the recess 219. In further aspects, as shown in FIG. 19, the adhesive liquid 1903 may be deposited in the recess 219 by pouring the adhesive liquid 1903 from a container 1901 into the recess 219. In aspects, depositing the adhesive liquid 1903 into the recess 219 may at least partially (e.g., substantially fully) fill the recess 219. In aspects, the adhesive liquid 1903 may comprise an adhesive precursor, a solvent, particles, nanoparticles, and/or fibers. In aspects, the adhesive precursor that can comprise, without limitation, one or more of a monomer, an accelerator, a curing agent, an epoxy, and/or an acrylate. In aspects, the solvent for the adhesive precursor may comprise a polar solvent (e.g., water, an alcohol, an acetate, acetone, formic acid, dimethylformamide, acetonitrile, dimethyl sulfoxone, nitromethane, propylene carbonate, poly(ether ether ketone)) and/or a non-polar solvent (e.g., pentane, 1,4-dioxane, chloroform, dichloromethane, diethyl ether, hexane, heptane, benzene, toluene, xylene). The adhesive liquid 1903 can be cured to form a first layer of the adhesive layer 261 as shown in FIG. 20 or the polymer-based portion 561 (see FIG. 5). In further aspects, the curing the adhesive liquid 1903 may comprise heating the adhesive liquid 1903. In further aspects, curing the adhesive liquid 1903 may comprise irradiating the adhesive liquid 1903 with ultraviolet (UV) radiation. In further aspects, the curing the adhesive liquid 1903 to form at least a portion of the adhesive layer 261 and/or polymer-based portion 561 can comprise waiting a predetermined amount of time (e.g., from about 30 minutes to 24 hours, from about 1 hour to about 8 hours).

After step 1007, methods can proceed to step 1015 comprising disposing the coating 507 over the foldable substrate 201 or 407, for example, to form the foldable apparatus 501 shown in FIG. 5. In aspects, the third major surface 503 of the coating 507 can be disposed over the second major surface 205 or 405 of the foldable substrate 201 or 407. In further aspects, the third major surface 503 of the coating 507 can contact the second major surface 205 or 405 of the foldable substrate 201 or 407. In aspects, although not shown, the third major surface 503 of the coating 507 can be disposed over (e.g., contact) the first major surface 203 or 403 of the foldable substrate 201 or 407. In aspects, the coating 507 can be formed similar to the adhesive layer 261, for example, by disposing a liquid (e.g., adhesive liquid) and curing the liquid.

After steps 1007, 1009, 1013, and/or 1015, the method can be complete at step 1011. In aspects, step 1011 can comprise further assembling the foldable apparatus, for example, by disposing a coating opposite a release liner or display device, or by disposing a release liner or display device opposite a coating.

Throughout the disclosure, the phrase “not further treated” or “not be further treated” excludes treatments of the first major surface other than the stated contacting with a solution and rinsing with water (e.g., purified, filtered, deionized, distilled). Exemplary aspects of treatments that can be excluded under “not further treated” or “not be further treated” include treatment with additional acidic solutions, basic solutions, fluorine-containing solutions, detergents, and mechanical polishing of the foldable substrate. In aspects, the foldable substrate may not be further treated between the contacting the foldable substrate with the solution (e.g., acidic, hydroxide-containing base, H₂SiF₆, fluoride-containing compound) in step 1007 and assembly of the foldable apparatus (e.g., attaching an adhesive layer to the new first major surface and disposing a release liner over the adhesive layer, attaching the display device to the new first major surface, disposing a coating over the new first major surface) in step 1009, 1011, 1013, or 1015. In aspects where the method comprises step 1005 comprising chemically strengthening the foldable substrate, the foldable substrate may not be further treated between the chemically strengthening in step 1005 and the contacting the foldable substrate with the solution (e.g., acidic, hydroxide-containing base, H₂SiF₆, fluoride-containing compound) in step 1007. In aspects, the foldable substrate can be not further treated excluding the optional rinsing steps as part of step 1003 and/or step 1005 discussed above, which can involve a detergent solution.

In aspects, methods of making a foldable apparatus in accordance with aspects of the disclosure can proceed along steps 1001, 1003, 1005, 1007, 1009, and 1011 of the flow chart in FIG. 10 sequentially, as discussed above. In aspects, as shown in FIG. 10, arrow 1002 can be followed from step 1001 to step 1005, omitting step 1003, for example, when the foldable substrate 1101 or 1307 will not comprise a recess 219 or the foldable substrate 1101 or 1307 provided in step 1001 already comprises a recess 219. In aspects, arrow 1004 can be followed from step 1001 to step 1007, omitting steps 1003 and 1005, for example, if the foldable substrate 1101 or 1307 already comprises a recess 219 or will not include a recess 219 and the foldable substrate 1101 or 1307 is already chemically strengthened. In aspects, arrow 1006 can be followed from step 1007 to step 1011, for example if the method produces the foldable substrate 201 or 407 (see FIGS. 6-7) without the coating 507, without the polymer-based portion 561, without the release liner 271, and/or without the display device 307. In aspects, arrow 1008 can be followed from step 1007 to step 1013, for example if the method applies a release liner 271 after which the method may proceed to be complete at step 1011 or may include removing the release liner and then applying the display device 307 as indicated by arrow 1012. Furthermore, after step 1007, as indicated by arrow 1010, the method can proceed from step 1007 to step 1015 of applying the coating 507 disposed over the foldable substrate 201 or 407. Although step 1015 is indicated as occurring immediately after step 1007, in further aspects, although not shown, step 1015 may be carried out any time after step 1007 (e.g., before or after step(s) 1013, 1009). Any of the above options may be combined to make a foldable apparatus in accordance with aspects of the disclosure.

### EXAMPLES

Various aspects will be further clarified by the following examples. Examples A-X, AA-FF, and AAA-NNN all comprise a glass-based substrate (having a Composition 1 of, nominally, in mol % of: 69.1 SiO₂; 10.2 Al₂O₃; 15.1 Na₂O; 0.01 K₂O; 5.5 MgO; 0.09 SnO₂) comprising a thickness of 100 μm. Examples GG-KK and the data presented in Tables 10-14 comprised a glass-based substrate comprising Composition 1 and a thickness of 30 μm. Tables 1-4 present treatment conditions and properties of Examples A-X and AA-LL demonstrate the effect of solution composition and treatment conditions on the thickness removed and/or the etch rate (e.g., rate of thickness removed). As used herein, the thickness removed refers to the thickness removed from one major surface (e.g., first major surface) by the treatment with the solution. Tables 5-6 present the thickness removed during the treatment and pen drop height of Examples MM-WW. Tables 7-8 present the thickness removed during the treatment and pen drop height of Examples AAA-M. Table 9 presents the thickness removed and changes to the compressive stress region as a result of the treatment for Examples BBB-CCC, EEE, and KKK-OOO. Tables 10-14 present pen drop results for different treatment times and concentrations.

Examples A-H comprised glass-based substrates comprising Composition 1 that were treated by contacting the first major surface with an alkaline solution comprising 45 wt % KOH at the temperature and time presented in Table 1. Table 1 also presents the thickness removed from the first major surface and the etch rate. As shown, the thickness removed increased as the time was increased at the same concentration. Likewise, the thickness removed increased as the temperature was increased at the same concentration. At 75° C., the etching rate was between 1.3 nm/min and 1.6 nm/min and the thickness removed ranged from 40 nm to 190 nm. At 90° C., the etching rate was between 4.7 nm/min and 5.5 nm/min and the thickness removed ranged from 142 nm to 648 nm.

TABLE 1
Treatment Conditions and Properties of Examples A-H

| | Temperature | Time | Thickness | Etch Rate |
|---|---|---|---|---|
| Example | (° C.) | (min) | Removed (nm) | (nm/min) |
| A | 75 | 30 | 40 | 1.34 |
| B | 75 | 60 | 93 | 1.55 |
| C | 75 | 90 | 131 | 1.46 |
| D | 75 | 120 | 190 | 1.58 |
| E | 90 | 30 | 142 | 4.74 |
| F | 90 | 60 | 329 | 5.48 |
| G | 90 | 90 | 446 | 4.96 |
| H | 90 | 120 | 648 | 5.40 |

Examples I-N comprised glass-based substrates comprising Composition 1 that were treated by contacting the first major surface with an acid solution with compositions presented in Table 2 at 65° C. for 30 minutes. Table 2 also presents the thickness removed from the first major surface, the etch rate, and the thickness of a leached layer at the first major surface. With 0 M FeCl₃, the etch height, the thickness of the leached layer, and etch rate increased as the concentration of HCl increased. With 1 M FeCl₃, the thickness of the leached layer increased with increasing HCl concentration, but the etch height and etch rate were the lowest for 3.2 M HCl and the highest for 4.9 M HCl. Increasing the concentration of FeCl₃ increased the etch height and etch rate. For 0 M FeCl₃, the etch height ranged from about 60 nm to about 350 nm and the etch rate ranged from about 2 nm/min to about 5 nm/min. For 1 M FeCl₃, the etch height ranged from about 300 nm to about 400 nm and the etch rate ranged from about 10 nm/min to about 13.5 nm/min.

TABLE 2
Treatment Conditions and Properties of Examples I-N

| | HCl | FeCl₃ | Etch Height | Leached | Etch Rate |
|---|---|---|---|---|---|
| Example | (M) | (M) | (nm) | Layer (nm) | (nm/min) |
| I | 1.6 | 0 | 63 | 0 | 2.10 |
| J | 3.2 | 0 | 121 | 28 | 4.03 |
| K | 4.9 | 0 | 149 | 144 | 4.97 |
| L | 1.6 | 1 | 328 | 0 | 10.93 |
| M | 3.2 | 1 | 307 | 14 | 10.23 |
| N | 4.9 | 1 | 402 | 155 | 13.40 |

Examples O-X comprised glass-based substrates comprising Composition 1 that were treated by contacting the first major surface with an H₂SiF₆-containing solution with compositions presented in Table 3 at 40° C. for 30 minutes. Table 3 also presents the thickness removed from the first major surface, the etch rate, and the thickness of an SiO₂ layer redeposited on the first major surface. Increasing the concentration of H₂SiF₆ with a constant concentration of B(OH)₃ of 0.1 or 0.2 M increases the thickness removed, and the etch rate increases with increasing H₂SiF_{6 for} 0.2 M B(OH)₃. However, the etch rate and thickness removed for 3 M H₂SiF₆ is lower than the other H₂SiF₆ concentrations at 0 M B(OH)₃. Increasing the concentration of B(OH)₃ at the same concentration of H₂SiF₆ decreases the thickness removed and etch rate but increases the SiO₂ thickness. With 0 M B(OH)₃, the etch height was between 450 nm and 900 nm and the etch rate was from 15 nm/min to about 30 nm/min. With 0.1 M B(OH)₃, the etch height was between 175 nm and 425 nm and the etch rate was from 5 nm/min to about 15 nm/min. With 0.2 M B(OH)₃, the etch height was between 10 nm and 40 nm and the etch rate was from 0.5 nm/min to about 1.5 nm/min.

TABLE 3
Treatment Conditions and Properties of Examples O-X

| | | | Thickness | SIO₂ | Etch |
|---|---|---|---|---|---|
| | H₂SiF₆ | B(OH)₃ | Removed | thickness | Rate |
| Example | (M) | (M) | (nm) | (nm) | (nm/min) |
| O | 0.5 | 0 | 573 | 0 | 19.1 |
| P | 1 | 0 | 885 | 0 | 29.5 |
| Q | 2 | 0 | 714 | 0 | 23.8 |
| R | 3 | 0 | 462 | 0 | 15.4 |
| S | 1 | 0.1 | 178 | 4 | 8 |
| T | 2 | 0.1 | 239 | 13 | 7 |
| U | 3 | 0.1 | 420 | 31 | 14 |
| V | 1 | 0.2 | 15 | 26 | 0.5 |
| W | 2 | 0.2 | 28 | 62 | 0.9 |
| X | 3 | 0.2 | 37 | 83 | 1.2 |

Examples AA-LL comprised glass-based substrates comprising Composition 1 that were treated by contacting the first major surface with an NH₄F-containing solution with compositions presented in Table 4 at the temperature presented in Table 4 for 30 minutes. Table 4 also presents the etch rate. Increasing H₂SiF₆ concentration increases the etch rate for all of the Examples in Table 4 with consistent NH₄F concentration and temperature. Increasing temperature increases the etch rate for all of the Examples in Table 4 with consistent NH₄F-containing solution composition. Comparing Examples P-Q in Table 3 with Examples AA and CC in Table 4, increasing the NH₄F concentration from 0 M to 0.02 M increases the etching rate by more than 10 times (e.g., 11.3 times from Example P to Example AA, 26.8 times from Example Q to Example CC). Further increasing the concentration of NH₄F from 0.02 M to 0.04 M decreased the etching rate when the concentration of H₂SiF_{6 was} 1 M. Further increasing the concentration of NH₄F from 0.02 M to 0.04 M when the concentration of H₂SiF₆ was 1.5 M slightly increased the etching rate at 40° C. but slightly decreased the etching rate at 60° C. Further increasing the concentration of NH₄F from 0.02 M to 0.04 M when the concentration of H₂SiF₆ was 2 M increased the etching rate.

TABLE 4
Treatment Conditions and Properties of Examples AA-LL

| | H₂SiF₆ | NH₄F | Temperature | Etch Rate |
|---|---|---|---|---|
| Example | (M) | (M) | (° C.) | (nm/min) |
| AA | 1 | 0.02 | 40 | 333.6 |
| BB | 1.5 | 0.02 | 40 | 334.5 |
| CC | 2 | 0.02 | 40 | 637.6 |
| DD | 1 | 0.04 | 40 | 221.3 |
| EE | 1.5 | 0.04 | 40 | 388.7 |
| FF | 2 | 0.04 | 40 | 457.3 |
| GG | 1 | 0.02 | 60 | 618.6 |
| HH | 1.5 | 0.02 | 60 | 1176.8 |
| II | 2 | 0.02 | 60 | 1145.2 |
| JJ | 1 | 0.04 | 60 | 693.2 |
| KK | 1.5 | 0.04 | 60 | 1145.8 |
| LL | 2 | 0.04 | 60 | 1344.2 |

Examples MM-RR comprised 100 μm thick glass-based substrates comprising Composition 1 with different treatments and the pen drop heights are presented in Table 5. Examples NN-RR were chemically strengthened (“IOX”) in a bath comprising 100% molten KNO₃ at 410° C. for 60 minutes while Example AA was not. Example NN was not further treated. Example OO was treated with an alkaline solution comprising 45 wt % KOH at 90° C. for 60 minutes. Example PP was treated with an H₂SiF₆-containing solution comprising 0.5 M H₂SiF₆ at 40° C. for 7.75 minutes. Example QQ comprised a fluoride-containing solution comprising 10 wt % ammonium fluoride (NH₄F) and 3 M sulfuric acid (H₂SO₄) at 25° C. for 10 minutes. Example RR comprised a fluoride-containing solution comprising 10 wt % ammonium fluoride (NH₄F) without an acid at 25° C. for 10 minutes.

As shown in Table 5, the pen drop height decreased from 19.75 cm in Example MM to 13.75 cm in Example NN by chemically strengthening the foldable substrate. Example PP comprising treatment with a fluoride-containing solution comprising ammonium fluoride and sulfuric acid did not substantially change the pen drop height relative to Example NN. However, Example QQ comprising treatment with a fluoride-containing solution comprising ammonium fluoride without an acid increased the pen drop height by 0.5 cm (3.6%) relative to Example NN. Further, Example PP comprising treatment with the H₂SiF₆-containing solution increased the pen drop height by 3.5 cm (25.5%) relative to Example NN. Moreover, Example OO comprising treatment with the alkaline solution increased the pen drop height by 5.75 cm (41.8%) relative to Example NN.

TABLE 5
Pen Drop Results for Examples MM-RR

| | | Thickness | Pen Drop |
|---|---|---|---|
| Example | Treatment Condition | Removed (nm) | Height (cm) |
| MM | No IOX | 0 | 19.75 |
| NN | IOX (only) | 0 | 13.75 |
| 00 | IOX → KOH | 329 | 19.50 |
| PP | IOX → H₂SiF₆ | 239 | 17.25 |
| QQ | IOX → NHF₄ + H₂SO₄ | 500 | 13.50 |
| RR | IOX → NH₄F | 250 | 14.25 |

Examples SS-WW comprised 30 μm thick glass-based substrates comprising Composition 1 with different treatments and the pen drop heights are presented in Table 6. Examples SS-WW were chemically strengthened (“IOX”) in a bath comprising 100% molten KNO₃ at 410° C. for 60 minutes. Example TT was further treated with an alkaline solution comprising 30 wt % NaOH at 90° C. for 60 minutes while Example UU was further treated with an alkaline solution comprising 45 wt % NaOH at 90° C. for 60 minutes. Examples VV was further treated with an H₂SiF₆-containing solution comprising H₂SiF₆-containing solution comprising 2.5 M H₂SiF₆ and 0.2 M B(OH)₃ at 40° C. for 30 minutes while Example WW was further treated with an H₂SiF₆-containing solution comprising H₂SiF₆-containing solution comprising 2.5 M H₂SiF₆ without boric acid at 40° C. for 30 minutes.

As shown in Table 6, the pen drop height for Example SS was substantially the same as Examples TT and WW. In contrast, the pen drop height increased by 1 cm (25%) for Examples UU and VV relative to Example SS. Consequently, increasing the thickness removed from 200 nm to 400 nm by the alkaline solution from Example TT to Example UU increased the pen drop height. However, increasing the thickness removed from 500 nm to 1,000 nm by the H₂SiF₆-containing solution from Example VV to Example WW decreased the pen drop height from 4 cm to 3 cm, which is the same as Example SS.

TABLE 6
Pen Drop Results for Examples SS-WW

| | Treatment | Thickness | Pen Drop |
|---|---|---|---|
| Example | Condition | Removed (nm) | Height (cm) |
| SS | IOX (only) | 0 | 3 |
| TT | IOX → NaOH | 200 | 3 |
| UU | IOX → NaOH | 400 | 4 |
| VV | IOX → H₂SiF₆ | 500 | 4 |
| WW | IOX → H₂SiF₆ | 1,000 | 3 |

Examples AAA-JJJ comprised 100 μm thick glass-based substrates comprising Composition 1 with different treatments and the pen drop heights are presented in Tables 7-8. Examples AAA-EEE were formed by redrawing an existing glass-based substrate comprising a substrate thickness of 400 μm while Examples FFF-JJJ were formed by etching an existing glass-based substrate comprising a substrate thickness of 400 μm using an HF solution. Examples BBB-EEE and GGG-JJJ were chemically strengthened (“IOX”) in a bath comprising 100% molten KNO₃ at 410° C. for 12 hours. Examples CCC and HHH was further treated with an H₂SiF₆-containing solution comprising 0.5 M H₂SiF₆ and a temperature of 40° C. for 97 seconds. Example DDD was further treated with a 45 wt % KOH solution comprising 90° C. for 90 minutes. Example EEE was further treated with a solution comprising 0.58 M HF and 0.8 M HNO₃ and a temperature of 24° C. for 117 seconds. Example III was further treated with the KOH solution as in Example DDD followed by the H₂SiF₆-containing solution as in Examples CCC and HHH. Example JJJ was further treated with the H₂SiF₆-containing solution as in Examples CCC and HHH followed by the KOH solution as in Example DDD.

TABLE 7
Pen Drop Results for Examples AAA-EEE

| | Treatment | Thickness | Pen Drop |
|---|---|---|---|
| Example | Condition | Removed (nm) | Height (cm) |
| AAA | None | 0 | 19.7 |
| BBB | IOX (only) | 0 | 13.9 |
| CCC | IOX → H₂SiF₆ | 770 | 17.1 |
| DDD | IOX → KOH | 160 | 19.4 |
| EEE | IOX → HF/HNO₃ | 860 | 11.2 |

TABLE 8
Pen Drop Results for Examples FFF-JJJ

| | | Thickness | Pen Drop |
|---|---|---|---|
| Example | Treatment Condition | Removed (nm) | Height (cm) |
| FFF | IOX (only) | 0 | 8.1 |
| GGG | IOX → H₂SiF₆ | 1,000 | 11.8 |
| HHH | IOX → KOH | 150 | 12.4 |
| III | IOX → KOH → H₂SiF₆ | 1,150 | 10.3 |
| JJJ | IOX → H₂SiF₆ → KOH | 1,150 | 12.4 |

As shown in Table 7, chemically strengthening the glass-based substrate (Example BBB) decreases the pen drop height compared to the non-chemically strengthened glass-based substrate (Example AAA). The treatment solutions of Examples CCC-DDD increased the pen drop height compared to Example BBB. The KOH treatment (alkaline solution) of Example DDD produced the greatest increased in pen drop height (5.5 cm increase; 39% increase) of Examples CCC-EEE relative to Example BBB. The H₂SiF₆-containing treatment solution of Example CCC increased the pen drop height (3.2 cm increase; 23% increase).

As shown in Table 8, Examples GGG-JJJ increased the pen drop height relative to Example FFF. Examples HHH and JJJ produced the greatest increase in pen drop height (4.3 cm; 53% increase) of Examples GGG-JJJ relative to Example FFF. Example GGG increased the pen drop height by 3.7 cm (45% increase) relative to Example FFF. Example III increased by the pen drop height by 2.2 cm (27% increase) relative to Example FFF. Comparing Examples III and JJJ, Example JJJ has a greater pen drop height than Example III, suggesting that contacting the glass-based substrate with the H₂SiF₆-containing solution followed by the alkaline solution strengthened the glass-based substrate more than contacting the glass-based substrate with the alkaline solution followed by the H₂SiF₆-containing solution. Both Examples HHH and JJJ comprise the same pen drop height, suggesting that the H₂SiF₆-containing solution did not further improve the glass-based substrate when it is also contacted by the alkaline solution. Comparing Examples HHH and III, Example HHH comprises a greater pen drop height than Example III, suggesting that subsequent treatment or subsequent processing after contacting the glass-based substrate with the alkaline solution does not further improve the pen drop height.

Table 9 presents properties of Examples BBB-EEE, and KKK-NNN. The maximum compressive stress (CS), depth of layer (DOL), depth of compression (DOC), and maximum central tension (CT) for Examples CCC-EEE, and KKK-NNN were measured after the stated treatment was performed and changes (A) in these properties were calculated relative to the initial values of the corresponding properties for that sample. The CS, DOL, and CT values before and after the treatment were measured at three locations for each Example. Since the properties measured before treatment varied between the Examples, the differences (ΔCS, ΔDOL, ΔDOC, ΔCT) of an Example reported in Table 9 do not correspond exactly to the difference between the corresponding property of Example BBB and the corresponding property of the corresponding Example. Example KKK comprised Example BBB that was further treated with an H₂SiF₆-containing solution comprising 1.0 M H₂SiF₆ and a temperature of 40° C. for 134 seconds. Example LLL comprised Example BBB that was further treated with an H₂SiF₆-containing solution comprising 1.5 M H₂SiF₆ and a temperature of 40° C. for 64 seconds. Example MMM comprised Example BBB that was further treated with an alkaline solution comprising 45 wt % KOH and a temperature of 90° C. for 10 minutes. Example NNN comprised Example BBB that was further treated with an alkaline solution comprising 45 wt % KOH and a temperature of 90° C. for 45 minutes.

TABLE 9
Properties of Treated, Chemically Strengthened Examples

| | | Thickness | CS | DOL | DOC | CT |
|---|---|---|---|---|---|---|
| Example | Treatment Condition | removed (nm) | (MPa) | (μm) | (μm) | (MPa) |
| BBB | IOX (only) | 0 | 890.4 | 18.2 | 17.94 | 243.4 |
| EEE | IOX → HF/HNO₃ | 860 | 821.3 | 17.9 | 17.53 | 221.7 |
| CCC | IOX → 0.5M H₂SiF₆ | 770 | 837.4 | 18.0 | 17.68 | 229.1 |
| KKK | IOX → 1.0M H₂SiF₆ | 920 | 823.2 | 17.8 | 17.41 | 219.9 |
| LLL | IOX → 1.5M H₂SiF₆ | 910 | 833.4 | 17.7 | 17.38 | 222.0 |
| MMM | IOX → KOH (10 mm) | 85 | 889.7 | 17.8 | 17.49 | 239.2 |
| NNN | IOX → KOH (45 mm) | 150 | 888.9 | 17.7 | 17.40 | 237.2 |
| DDD | IOX → KOH (90 mm) | 160 | 887.1 | 17.8 | 17.27 | 237.3 |

| | | ΔCS | ΔDOL | ΔDOC | ΔCT |
|---|---|---|---|---|---|
| Example | Treatment Condition | (MPa) | (μm) | (μm) | (MPa) |
| BBB | IOX (only) | 0 | 0 | 0 | 0 |
| EEE | IOX → HF/HNO₃ | 59.9 | 0.28 | 0.27 | 21.9 |
| CCC | IOX → 0.5M H₂SiF₆ | 41.2 | 0.29 | 0.29 | 17.4 |
| KKK | IOX → 1.0M H₂SiF₆ | 62.3 | 0.54 | 0.53 | 27.9 |
| LLL | IOX → 1.5M H₂SiF₆ | 44.0 | 0.48 | 0.47 | 21.6 |
| MMM | IOX → KOH (10 mm) | −8.0 | 0.06 | 0.06 | −0.9 |
| NNN | IOX → KOH (45 mm) | 5.2 | 0.16 | 0.16 | 4.7 |
| DDD | IOX → KOH (90 mm) | 14.2 | 0.02 | 0.02 | 4.3 |

As shown in Table 9, the average thickness removed varied from 85 nm (Example MMM) to 920 nm (Example KKK). The change in maximum compressive stress (ΔCS) was the greatest for the HF/HNO₃ treated Example EEE and the H₂SiF₆ treated Examples CCC and KKK-LLL. Within the H₂SiF₆ treatments, the 1.0 M H₂SiF₆ treatment of Example KKK had a greater ΔCS than Examples CCC (0.5 M H₂SiF₆) and LLL (1.5 M H₂SiF₆) by about 20 MPa even though Example LLL had a comparable thickness removed to Example KKK. Changes in the depth of layer (ΔDOL) and changes in the depth of compression (ΔDOC) for Examples CCC and KKK-LLL ranged from about 0.29 μm to about 0.55 μm, which is less than about 3% of the corresponding DOL or DOC value of Example BBB. Changes in maximum central tension (ΔCT) for Examples CCC and KKK-LLL ranged from about 17 MPa to about 30 MPa, which is less than about 12% of the CT value of Example BBB. As discussed above for Example CCC, removing less than 1 micrometer of thickness (770 nm) with the H₂SiF₆-containing solution can improve the pen drop by more than 20% (3.2 cm increase; 23% increase). This increase in pen drop performance is more significant in view of a similar thickness removed and similar ΔCS for Examples CCC (0.5 M H₂SiF₆) and EEE (HF/HNO₃), where the pen drop height of Example EEE is worse than both Example CCC and Example BBB. It is to be noted that the ΔCS value for MMM is within the margin of error of 0 MPa for the CS measurement.

The ΔCS for Examples DDD and MMM-NNN ranged from −8.0 MPa to about 15 MPa, which is less than 2% (1.7%) of the CS value of Example BBB. The ΔDOL and ΔDOC for Examples DDD and MMM-NNN ranged from about 0 μm (0.02 μm) to about 0.2 μm (0.16 μm), which is less than 1% of the corresponding DOL or DOC value for Example BBB. The ΔCT value for Examples DDD and MMM-NNN ranged from −0.9 MPa to about 5 MPa, which is less than about 2% of the CT value of Example BBB. As discussed above, Example DDD has the best pen drop performance of Examples BBB-EEE. Given that Examples DDD and MMM-NNN remove less than 200 nm of thickness (e.g., from about 50 nm to about 200 nm), it is unexpected to have better pen drop performance than other treatments that remove a greater thickness, for example the about 1 μm of thickness removed by Examples CCC And EEE. Also, it is noted that the CS value of Example MMM increased despite a net removal of thickness. Without wishing to be bound by theory, the alkaline solution (KOH) may selectively etch flaws in the surface of the glass-based substrate before etching the rest of the surface, which could increase the strength of the glass-based substrate and corresponding pen drop performance without removing a substantial portion of the compressive stress region.

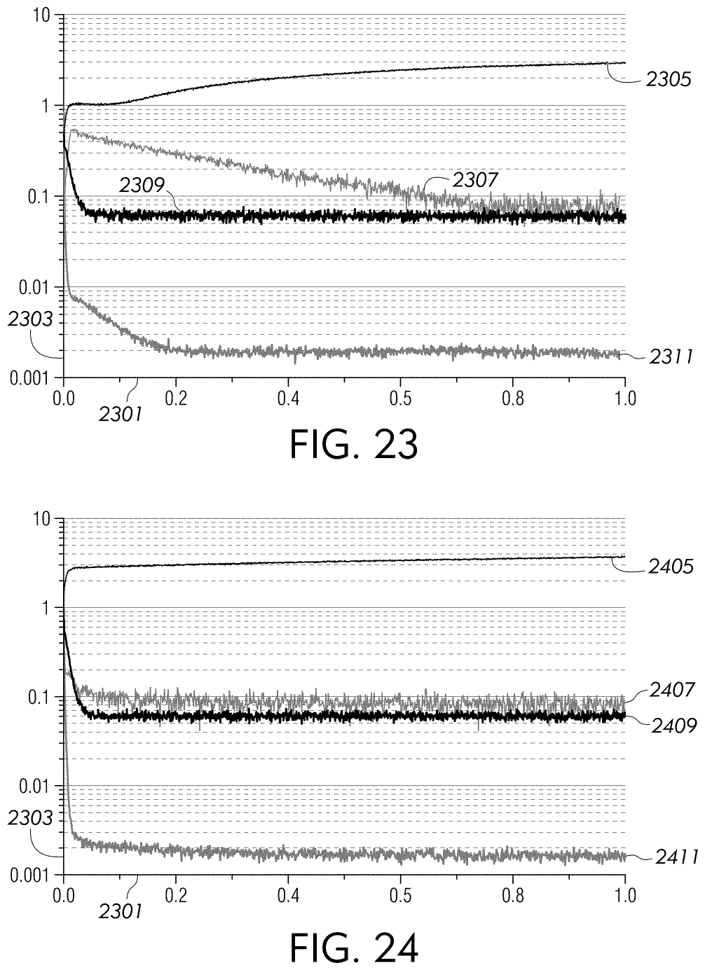

The results of analyzing Examples BBB, EEE, CCC and NNN were analyzed using secondary ion mass spectrometry (SIMS) are presented in FIGS. 23-26, respectively. In FIGS. 23-26, the horizontal axis 2301 (i.e., x-axis) is a depth from the first major surface of the glass-based substrate in micrometers, and the vertical axis 2303 (i.e., y-axis) is a detected amount on a log axis. For Na₂O and CaO, the vertical axis 2303 corresponds to mole % while the vertical axis 2303 corresponds to atom % for H (hydrogen) and F (fluorine). Curves 2305, 2405, 2505, and 2605 correspond to Na₂O. Curves 2307, 2407, 2507, and 2607 correspond to H. Curves 2309, 2409, 2509, and 2609 correspond to CaO. Curves 2311, 2411, 2511, and 2611 correspond to F.

In FIG. 23, for Example BBB, curve 2305 shows that Na₂O is depleted at the surface as a result of the chemical strengthening process, where the sodium ions were exchanged with potassium ions. Consequently, curve 2309 shows that CaO is enriched at the surface. Curve 2307 shows that H is elevated (greater than about 0.09 atom % H) out to about 0.6 μm or more from the surface while curve 2311 shows that F is elevated (greater than about 0.002 atom % F) out to about 0.2 μm from the surface.

In FIG. 24, for Example EEE, curve 2405 shows that Na₂O is less depleted than for curve 2305, which corresponds to the removal of 860 nm from the first major surface by the HF/HNO₃ treatment. However, curve 2409 still resembles curves 2309, suggesting that the concentration of CaO is not affected by the HF/HNO₃ treatment. Curves 2407 and 2411 are elevated (greater than about 0.1 atom % H, greater than about 0.002 atom % F) for less than about 0.1 μm, which again corresponds to the removal of 860 nm from the first major surface by the HF/HNO₃ treatment. However, as discussed above, Example EEE did not increase the pen drop height relative to Example BBB.

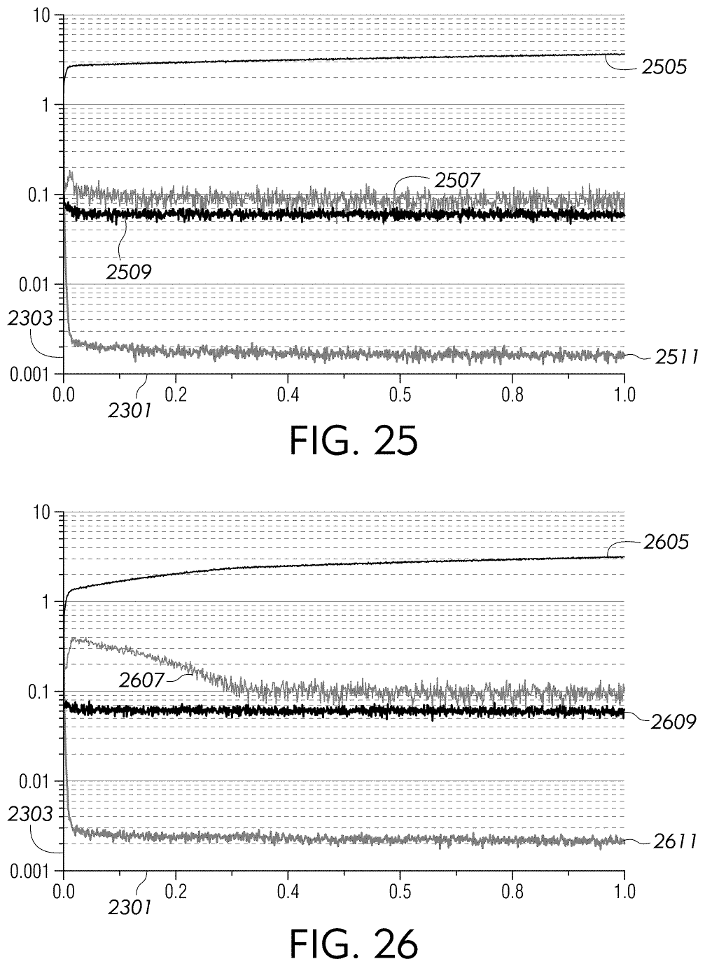

In FIG. 25, for Example CCC, curve 2505 resembles curve 2405. Curve 2505 shows that Na₂O is less depleted than for curve 2305, which corresponds to the removal of 770 nm from the first major surface by the H₂SiF₆ treatment. Curve 2509 is less elevated near the surface than curves 2309 and 2409. Curve 2511 shows that F is less elevated near the surface than curves 2311 and 2411. Curve 2507 shows that H is elevated (greater than about 0.09 atom % H) for less than 0.1 μm from the surface, which is comparable to curve 2407. As discussed above, Example CCC increased the pen drop height relative to Examples BBB and EEE. Without wishing to be bound by theory, it is expected that removing a hydronium-enriched layer (elevated H concentration) from the surface would remove flaws and increase pen drop performance. Based on this theory, it is unexpected that, relative to Example BBB, Example EEE would have a lower pen drop height while Example CCC would have a higher pen drop height even though both Examples CCC and EEE removed similar amounts of the H (hydronium) enriched surface layer, as shown in curves 2411 and 2511.

In FIG. 26, for Example NNN, curve 2605 shows that Na₂O is depleted for about 0.3 μm to about 0.4 μm from the first major surface. Comparing curves 2305 and 2605, curve 2605 resembles curve 2305 shifted to the left by about 0.15 μm, which corresponds to the 150 nm removed by Example NNN. Curve 2609 is less elevated near the surface than curves 2309 and 2409. Curve 2609 is comparable to curve 2509. It is unexpected that the concentration of CaO is substantially constant for Example NNN given that the concentration of CaO was elevated near the surface for Examples BBB and CCC. Curve 2611 shows that F is less elevated near the surface than curves 2311 and 2411. Again, it is unexpected that curve 2611 is as flat as it is since it is flatter than even curve 2311 shifted left by 0.15 μm. Curve 2607 shows that H is elevated (greater than about 0.1 atom % H) for about 0.3 μm from the surface. Again, it is unexpected that curve 2607 is elevated for less than 0.45 μm, which would be expected by shifting curve 2307 left by 0.15 μm. However, H is elevated for a longer distance from the first major surface in curve 2607 than in curves 2407 and 2507. As discussed above, Example DDD (similar to Example NNN) comprises a pen drop height greater than any of Example BBB, EEE, or CCC. Consequently, it is surprising that Examples DDD (similar to Example NNN) would have a greater pen drop height than Examples CCC (H₂SiF₆) and EEE (HF/HNO₃) given that H is elevated for longer for Example NNN than Examples CCC and EEE.

For Tables 10-14, the glass-based substrate comprised Composition 1 and a thickness of 30 μm. Tables 10-12 present pen drop results for different treatment times using either 0.5 M, 1.0 M, or 1.5 M H₂SiF₆ at 40° C., respectively. Table 13 presents pen drop results for different treatment times with an acidic solution comprising 0.58 M HF and 0.8 M HNO₃ at 24° C. Table 14 presents pen drop results for different treatment times with an alkaline solution comprising 45 wt % KOH at 90° C.

In Table 10, all of the treatments (time >0 seconds) increased the pen drop height by more than 200% (3.5 cm increase; 218% increase for 78 second treatment). In Table 10, the pen drop height for 36 seconds through 160 seconds is substantially the same. The pen drop height for the 202 second treatment was the greatest in Table 10.

TABLE 10
Pen Drop Results for 0.5M H₂SiF₆ Treatments at 40° C.

| Treatment | Thickness | Pen Drop |
|---|---|---|
| Time (sec) | Removed (nm) | Height (cm) |
| 0 | 0 | 1.6 |
| 36 | 202 | 5.3 |
| 78 | 387 | 5.1 |
| 119 | 479 | 5.4 |
| 160 | 626 | 5.2 |
| 202 | 756 | 6.0 |

TABLE 11
Pen Drop Results for 1.0M H₂SiF₆ Treatments at 40° C.

| Treatment | Thickness | Pen Drop |
|---|---|---|
| Time (sec) | Removed (nm) | Height (cm) |
| 0 | 0 | 1.6 |
| 5 | 109 | 4.7 |
| 28 | 353 | 5.8 |
| 51 | 614 | 7.0 |
| 74 | 740 | 5.8 |
| 98 | 916 | 4.1 |

TABLE 12
Pen Drop Results for 1.5M H₂SiF₆ Treatments at 40° C.

| Treatment | Thickness | Pen Drop |
|---|---|---|
| Time (sec) | Removed (nm) | Height (cm) |
| 0 | 0 | 1.6 |
| 11 | 319 | 6.1 |
| 27 | 597 | 6.2 |
| 44 | 807 | 6.9 |
| 60 | 941 | 8.0 |

In Table 11, all of the treatments (time >0 seconds) increased the pen drop height by more than 150% (2.5 cm increase; 156% increase for 98 second treatment. Unlike in Table 10, the pen drop heights in Table 11 increase as treatment time increases up to 51 seconds but then decreases for longer treatment times. In Table 11, treatment times from about 25 seconds to about 80 seconds (28 seconds, 51 seconds, and 74 seconds) comprised pen drop heights greater than 5 cm (5.8 cm), corresponding to an increase in pen drop height of at least 4.2 cm (262% increase). In Table 11, the 51 second treatment produced the greatest pen drop height of 7.0 cm (5.4 cm increase; 337% increase). It is unexpected that pen drop height decreases for treatments with 1.0 M H₂SiF₆ for times greater than 51 seconds.

In Table 12, all of the treatments (time >0 seconds) increased the pen drop height by more than 200% (4.5 cm increase; 281% increase for 11 second treatment).Comparing Tables 10 and 12, the pen drop heights in Table 12 for treatments >0 seconds are greater than all the pen drop values in Table 10. In Table 12 for treatments >0 seconds, the pen drop height increases as the treatment time increases with the 60 second treatment having the greatest pen drop height in Table 12 (6.4 cm increase; 400% increase).

Comparing Tables 10-12, the pen drop heights each table exhibited a different trend. As discussed above, the performance of the 51 second treatment with 1.0 M H₂SiF₆ is unexpected relative to other 1.0 M H₂SiF₆ treatments. Further, it is unexpected that the trend observed in Table 11 is not seen in Tables 10 or 12, where the trends are essentially monotonic.

In Table 13, all of the treatments (time >0 seconds) increased the pen drop height by more than 100% (2.2 cm increase; 137% increase). Treatment times of 23 seconds, 89 seconds, and 154 seconds exhibited large variations with standard deviations of more than 1.3 cm (greater than 25% of the reported value) with a maximum standard deviation of 2.0 cm for 23 seconds (greater than 50% of the reported value).

TABLE 13
Pen Drop Results for HF/HNO₃ Treatments at 24° C.

| Treatment | Thickness | Pen Drop |
|---|---|---|
| Time (sec) | Removed (nm) | Height (cm) |
| 0 | 0 | 1.6 |
| 23 | 185 | 3.8 |
| 56 | 403 | 4.7 |
| 89 | 530 | 4.0 |
| 122 | 748 | 4.8 |
| 154 | 925 | 4.3 |

TABLE 14
Pen Drop Results for 45 wt % KOH Treatments at 90° C.

| Treatment | Thickness | Pen Drop |
|---|---|---|
| Time (min) | Removed (nm) | Height (cm) |
| 0 | 0 | 1.6 |
| 10 | 74 | 6.3 |
| 20 | 120 | 7.3 |
| 30 | 167 | 7.4 |
| 45 | 236 | 8.7 |
| 60 | 305 | 8.5 |
| 75 | 375 | 7.8 |
| 90 | 444 | 5.6 |

In Table 14, all of the treatments (time >0 seconds) increased the pen drop height by at least 250% (4 cm increase; 250% increase for 90 minutes). As with Table 11, the pen drop height initially increases with increasing treatment time before decreasing as the treatment time is further increased. In Table 14, treatment times from about 15 minutes to about 80 minutes (20 minutes, 30 minutes, 45 minutes, 60 minutes, and 75 minutes) provided pen drop heights greater than 7.0 cm (5.4 cm increase; 337% increase), which is greater than any of the treatments reported in Tables 10-11 or 13. Further, it is unexpected that the treatments in Table 14 can provide such increases in pen drop height while removing less than 500 nm (e.g., less than 400 nm) from the first major surface. Moreover, treatment times of 45 minutes and 60 minutes provide a pen drop height greater than 8.0 cm (6.9 cm increase; 431% increase). It is unexpected that a maximum increase in pen drop height would be at an intermediate treatment time (45-60 minutes) of the treatments reported in Table 14. Without wishing to be bound by theory, it is expected that pen drop heights would increase until a thickness equal to the region of the H-enriched layer (hydronium-enriched layer) in FIG. 23 is removed, which makes the trend of Table 14 unexpected.

The above observations can be combined to provide methods of forming a foldable apparatus that comprises contacting an existing first major surface of a glass-based substrate to remove an outer compressive layer of a compressive stress region to form a new first major surface. Removing the outer compressive layer can provide increased impact resistance and/or puncture resistance while simultaneously facilitating good folding performance, for example, by removing surface defects in the existing first major surface of the glass-based substrate. Also, providing a glass-based substrate can provide good dimensional stability, reduced incidence of mechanical instabilities, and/or good impact and puncture resistance. For example, methods of the aspects of the disclosure can increase a pen drop height that the glass-based substrate can withstand (e.g., from about 20% to about 150%). Methods of the aspects of the disclosure can improve properties of the glass-based substrate by removing the outer compressive layer without substantially reducing a substrate thickness of the glass-based substrate (e.g., removing from about 0.05 micrometers or 0.1 micrometers to about 5 micrometers, removing from about 0.1 micrometers to about 0.4 micrometers, removing from about 0.05 micrometers to about 0.2 micrometers). In aspects, the entire existing first major surface can be contacted with the solution and the depth of the outer compressive layer can be substantially uniform across the existing first major surface. Removal of a substantially uniform outer compressive layer while minimizing a treatment time can be facilitated through the choice of solution composition and concentrations therein.

Methods of the aspects of the disclosure can use a solution that does not involve HF in substantial amounts, which can reduce materials handling costs both during treatment and for disposal of the solution. Likewise, some solutions can be substantially fluoride-free. The solution can be easily applied and then removed (e.g., rinsed away), for example, when the solution is substantially free of rheology modifiers. Methods of the aspects of the disclose can comprise the glass-based substrate comprising the new first major surface in a foldable apparatus. For example, the new first major surface can be opposite a display device (e.g., facing a user). For example, a release liner, a display device, and/or a coating can be disposed over (e.g., attached using an adhesive, directly contacting) the new first major surface of the glass-based substrate. In aspects, methods can comprise no further treatment between the contacting and disposing a release liner, a display device, and/or a coating over the glass-based substrate, which can minimize complexity of the processing and associated costs. Providing an acidic solution or an alkaline solution can substantially evenly remove a layer from the surface of the foldable substrate. Providing a fluoride-containing solution can produce consistent but low concentrations of HF in solution that can remove a surface of the foldable substrate without the issues (e.g., toxicity, materials handling, material disposal) associated with directly using HF. Providing H₂SiF₆-containing solution can both remove a layer from a surface of the foldable substrate and, in combination with B(OH)₃, can simultaneously deposit (e.g., redeposit) a silica (SiO₂) layer on the surface, which can fill defects (e.g., cracks) extending deeper into the foldable substrate than the height of the layer removed.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error, and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed is:

1. A method of forming a foldable apparatus comprising:
providing a glass-based substrate comprising a first compressive stress region extending to an existing first depth of compression from an existing first major surface of the glass-based substrate, the glass-based substrate comprising a first thickness defined between the existing first major surface and an existing second major surface;
contacting the existing first major surface with an alkaline solution comprising a first temperature for a period of time to remove an outer compressive layer of the first compressive stress region to form a new first major surface, the outer compressive layer comprising a thickness ranging from about 0.05 micrometers to about 5 micrometers, the first temperature is in a range from about 60° C. to about 120° C., and the alkaline solution comprises about 10 weight % (wt %) or more of a hydroxide-containing base; and
one or more of:
attaching an adhesive layer to the new first major surface and disposing a release liner over the adhesive layer;
attaching a display device to the new first major surface; or
disposing a coating over the new first major surface,
wherein, after the contacting the existing first major surface with the alkaline solution, the first compressive stress region extends to a new first depth of compression from the new first major surface.

2. The method of claim 1, wherein the new first major surface is not further treated between the contacting the existing first major surface with the alkaline solution and the attaching the adhesive layer to the new first major surface.

3. The method of claim 1, wherein the new first major surface is not further treated between the contacting the existing first major surface with the alkaline solution and the attaching the display device to the new first major surface.

4. The method of claim 1, wherein the new first major surface is not further treated between the contacting the existing first major surface with the alkaline solution and the disposing the coating over the new first major surface.

5. The method of claim 1, wherein providing the glass-based substrate comprises chemically strengthening the glass-based substrate with one or more alkali metal ions to form the first compressive stress region.

6. The method of claim 5, wherein the existing first major surface is not further treated between the chemically strengthening and the contacting the existing first major surface with the alkaline solution.

7. The method of claim 1, wherein the hydroxide-containing base comprises one or more of sodium hydroxide, potassium hydroxide, and/or ammonium hydroxide.

8. The method of claim 1, wherein the alkaline solution comprises from about 20 wt % to about 50 wt % of the hydroxide-containing base.

9. The method of claim 1, wherein the alkaline solution comprises a pH of about 14 or more.

10. The method of claim 1, wherein the alkaline solution comprises a concentration in a range from about 3.5 molar to about 9 molar.

11. The method of claim 1, wherein the alkaline solution is fluoride-free.

12. The method of claim 1, wherein the first temperature is in a range from about 70° C. to about 95° C.

13. The method of claim 1, wherein the period of time is in a range from about 10 minutes to about 120 minutes.

14. The method of claim 13, wherein the period of time is in a range from about 75 minutes to about 115 minutes.

15. The method of claim 1, wherein the thickness of the outer compressive layer removed by the contacting the existing first major surface with the alkaline solution is in a range from about 0.05 micrometers to about 0.2 micrometers.

16. The method of claim 1, wherein the thickness of the outer compressive layer removed by the contacting the existing first major surface with the alkaline solution is in a range from about 0.1 micrometers to about 0.4 micrometers.

17. The method of claim 1, wherein a first pen drop threshold height of the glass-based substrate after the contacting the existing first major surface with the alkaline solution is from about 20% to about 150% more than a second pen drop threshold height of the glass-based substrate prior to the contacting the existing first major surface with the alkaline solution.

18. The method of claim 1, wherein the new first depth of compression is less than the existing first depth of compression by from about 0.01 micrometers to about 0.20 micrometers.

19. The method of claim 1, wherein a new first depth of layer of the one or more alkali metal ions associated with the first compressive stress region extending to the new first depth of compression is less than an existing first depth of layer of one or more alkali metal ions associated with the first compressive stress region extending to the existing first depth of compression by from about 0.01 micrometers to about 0.10 micrometers.

20. The method of claim 1, wherein the first compressive stress region comprises an existing maximum compressive stress before the contacting, the first compressive stress region comprises a new maximum compressive stress after the contacting, and new maximum compressive stress is less than the existing maximum compressive stress by about 40 MegaPascals or less.
